(19) United States
(12) Patent Application Publication
(10) Pub. No.: US 2023/0008117 A1
(43) Pub. Date: Jan. 12, 2023

(54) LIGHT EMITTING DIODE

(71) Applicant: Samsung Display Co., Ltd., Yongin-si (KR)

(72) Inventors: TAEIL KIM, Hwaseong-si (KR); SUN YOUNG PAK, Suwon-si (KR); JUNHA PARK, Gwacheon-si (KR); JANG YEOL BAEK, Yongin-si (KR); Kyoung SUNWOO, Hwaseong-si (KR); MUN-KI SIM, Seoul (KR); CHANSEOK OH, Seoul (KR); MINJUNG JUNG, Gangwon-do (KR)

(21) Appl. No.: 17/652,016

(22) Filed: Feb. 22, 2022

(30) Foreign Application Priority Data
Jun. 1, 2021 (KR) 10-2021-0070602

(51) Int. Cl. H01L 51/00; C07F 5/02; C09K 11/06

(52) U.S. Cl. CPC H01L 51/008; C07F 5/027; C09K 11/06; H01L 51/5012

(57) ABSTRACT

A light emitting diode of an embodiment includes a first electrode, a second electrode, and at least one functional layer between the first electrode and the second electrode, wherein the at least one functional layer includes at least one selected from among a polycyclic compound represented by Formula 1 and a compound represented by Formula E-1.

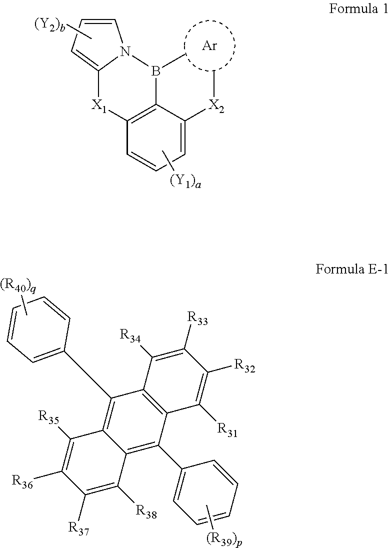

### CROSS-REFERENCE TO RELATED APPLICATION

This application claims priority to and the benefit of Korean Patent Application No. 10-2021-0070602, filed on Jun. 1, 2021, the entire contents of which are hereby incorporated by reference.

### BACKGROUND

Embodiments of the present disclosure herein relate to a light emitting diode, and, for example, to a light emitting diode including a novel polycyclic compound.

Recently, the development of an organic electroluminescence display device as an image display device is being actively conducted. The organic electroluminescence display device is a display device of a self-luminescent type in which holes and electrons respectively injected from a first electrode and a second electrode recombine in an emission layer so that a light emitting material in the emission layer emits light to achieve a display.

In the application of a light emitting diode to a display device, the increase of efficiency is sought after, and development of materials for a light emitting diode, stably achieving desirable qualities is being continuously pursued.

### SUMMARY

Embodiments of the present disclosure provide a light emitting diode showing high efficiency and long-life characteristics.

An embodiment of the present disclosure provides a light emitting diode including: a first electrode; a second electrode on the first electrode; and at least one functional layer between the first electrode and the second electrode, wherein the at least one functional layer includes at least one among a polycyclic compound represented by Formula 1 and a compound represented by Formula E-1.

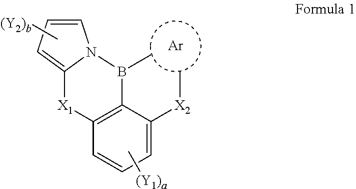

In Formula 1, Ar is a substituted or unsubstituted aromatic ring, X₁ and X₂ are each independently CR₁R₂, NR₃, O, S, or Se, Y₁, Y₂, and R₁ to R₃ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring, and “a” and “b” are each independently an integer of 0 to 3.

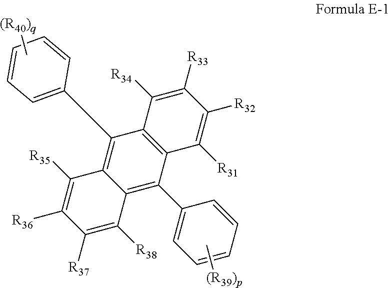

In Formula E-1, R₃₁ to R₄₀ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring, and “p” and “q” are each independently an integer of 0 to 5.

In an embodiment, the at least one functional layer may include an emission layer, a hole transport region between the first electrode and the emission layer, and an electron transport region between the emission layer and the second electrode, and the emission layer may include the polycyclic compound represented by Formula 1.

In an embodiment, the emission layer may include a dopant and a host, and the dopant may include the polycyclic compound represented by Formula 1.

In an embodiment, the emission layer may emit blue light.

In an embodiment, the emission layer may emit thermally activated delayed fluorescence.

In an embodiment, Ar may be a substituted or unsubstituted aromatic heterocycle.

In an embodiment, Ar may be a substituted or unsubstituted pentagonal ring.

In an embodiment, the polycyclic compound represented by Formula 1 may be represented by Formula 2-1 or Formula 2-2.

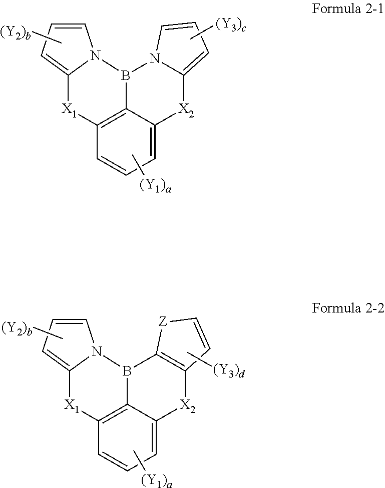

In Formula 2-1 and Formula 2-2, Z is CR₄R₅, NR₆, O, S, or Se, Y₃, and R₄ to R₆ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring, “c” is an integer of 0 to 3, “d” is an integer of 0 to 2, and X₁, X₂, Y₁, Y₂, “a”, and “b” are the same as defined with respect to Formula 1.

In an embodiment, “a”, “b”, and “c” may be each independently 0 or 1.

In an embodiment, the polycyclic compound represented by Formula 2-1 may be represented by Formula 3-1 or Formula 3-2.

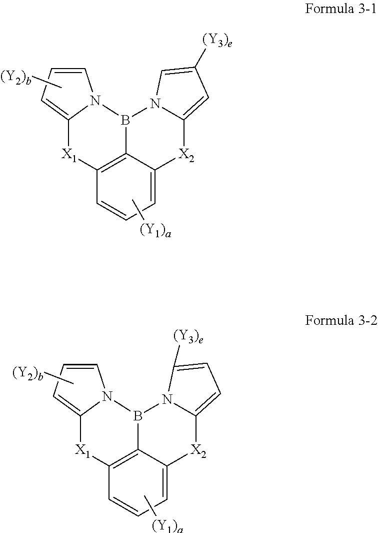

In Formula 3-1 and Formula 3-2, “e” is 0 or 1, and X₁, X₂, Y₁ to Y₃, “a”, and “b” are the same as defined with respect to Formula 1 and Formula 2-1.

In an embodiment, Y₁ to Y₃ may be each independently a hydrogen atom, a deuterium atom, a substituted or unsubstituted amine group, a substituted or unsubstituted alkyl group of 1 to 30 carbon atoms, a substituted or unsubstituted aryl group of 6 to 50 ring-forming carbon atoms, or a substituted or unsubstituted heteroaryl group of 2 to 50 ring-forming carbon atoms.

In an embodiment, the polycyclic compound represented by Formula 1 may be represented by Formula 4-1 or Formula 4-2.

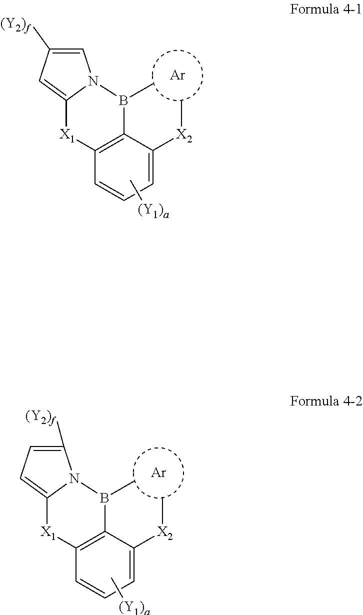

In Formula 4-1 and Formula 4-2, “f” is 0 or 1, and X₁, X₂, Y₁, Y₂, and “a” are the same as defined with respect to Formula 1.

In an embodiment, X₁ and X₂ may be each independently NR₃, O, S, or Se.

In an embodiment, the polycyclic compound represented by Formula 1 may include any one selected from among compounds shown in Compound Group 1.

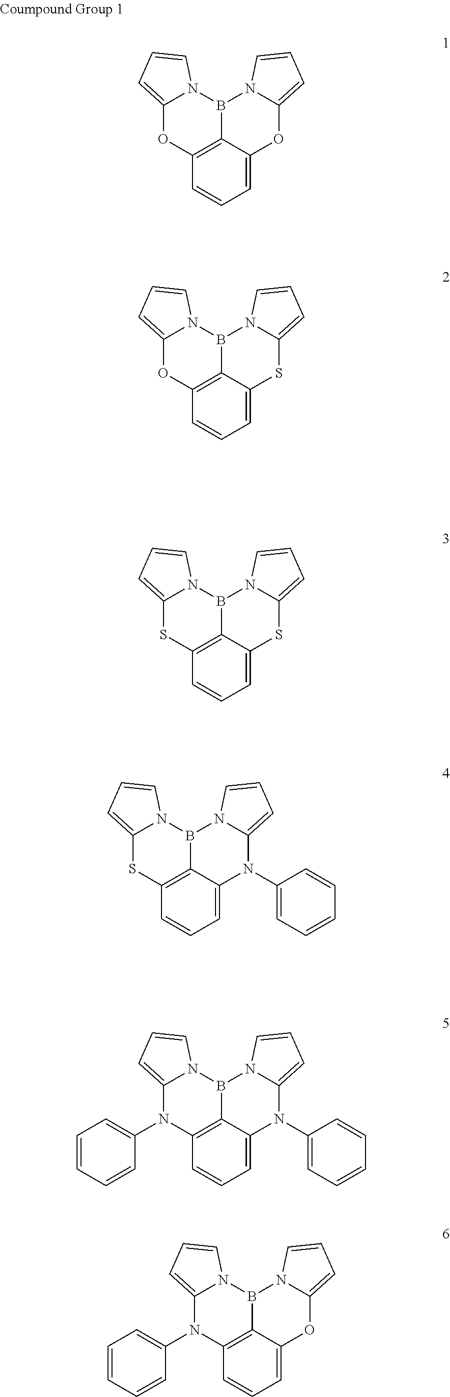 [SMILES: c1cc2c3c(c1)Oc1cccn1B3n1cccc1O2 ; c1cc2c3c(c1)Sc1cccn1B3n1cccc1O2 ; c1cc2c3c(c1)Sc1cccn1B3n1cccc1S2 ; c1ccc(N2c3cccc4c3B(n3cccc3S4)n3cccc32)cc1 ; c1ccc(N2c3cccc4c3B(n3cccc32)n2cccc2N4c2ccccc2)cc1 ; c1ccc(N2c3cccc4c3B(n3cccc3O4)n3cccc32)cc1]

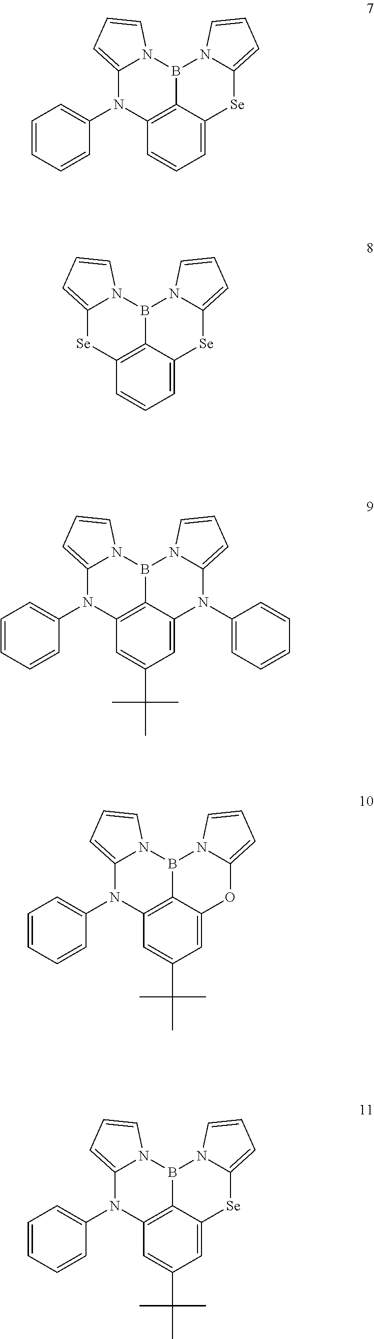 [SMILES: c1ccc(N2c3cccc4c3B(n3cccc3[Se]4)n3cccc32)cc1 ; c1cc2c3c(c1)[Se]c1cccn1B3n1cccc1[Se]2 ; CC(C)(C)c1cc2c3c(c1)N(c1ccccc1)c1cccn1B3n1cccc1N2c1ccccc1 ; CC(C)(C)c1cc2c3c(c1)N(c1ccccc1)c1cccn1B3n1cccc1O2 ; CC(C)(C)c1cc2c3c(c1)N(c1ccccc1)c1cccn1B3n1cccc1[Se]2]

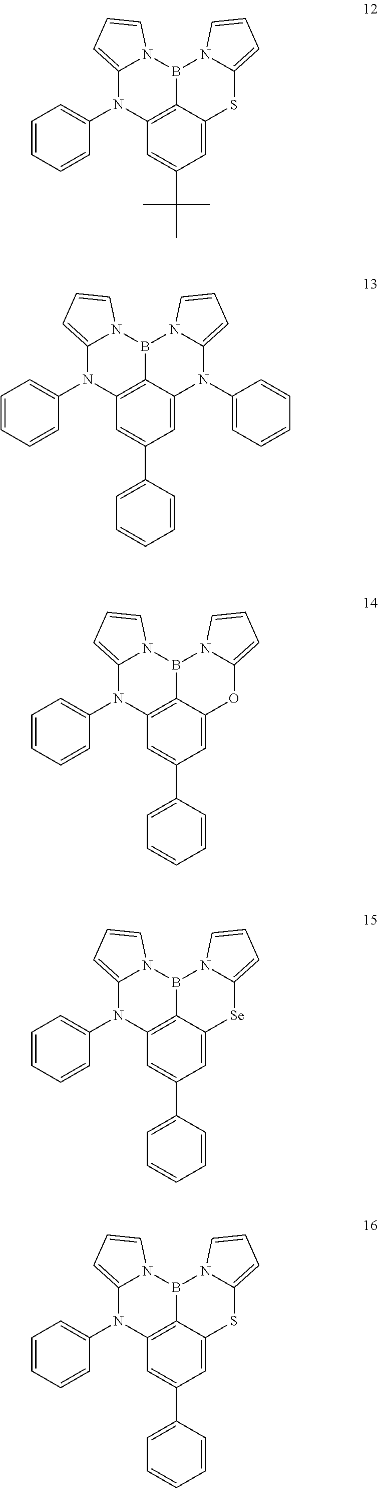 [SMILES: CC(C)(C)c1cc2c3c(c1)N(c1ccccc1)c1cccn1B3n1cccc1S2 ; c1ccc(-c2cc3c4c(c2)N(c2ccccc2)c2cccn2B4n2cccc2N3c2ccccc2)cc1 ; c1ccc(-c2cc3c4c(c2)N(c2ccccc2)c2cccn2B4n2cccc2O3)cc1 ; c1ccc(-c2cc3c4c(c2)N(c2ccccc2)c2cccn2B4n2cccc2[Se]3)cc1 ; c1ccc(-c2cc3c4c(c2)N(c2ccccc2)c2cccn2B4n2cccc2S3)cc1]

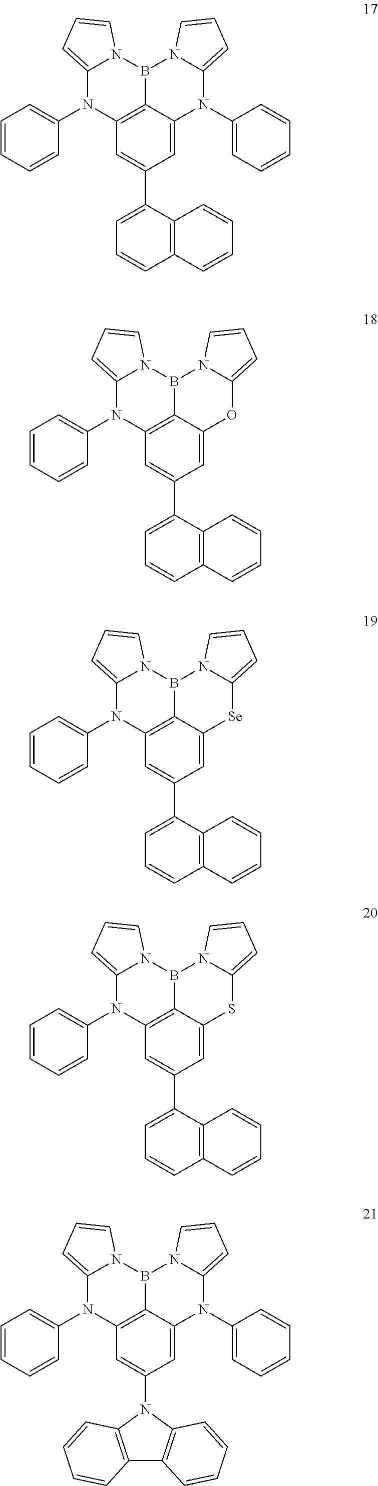

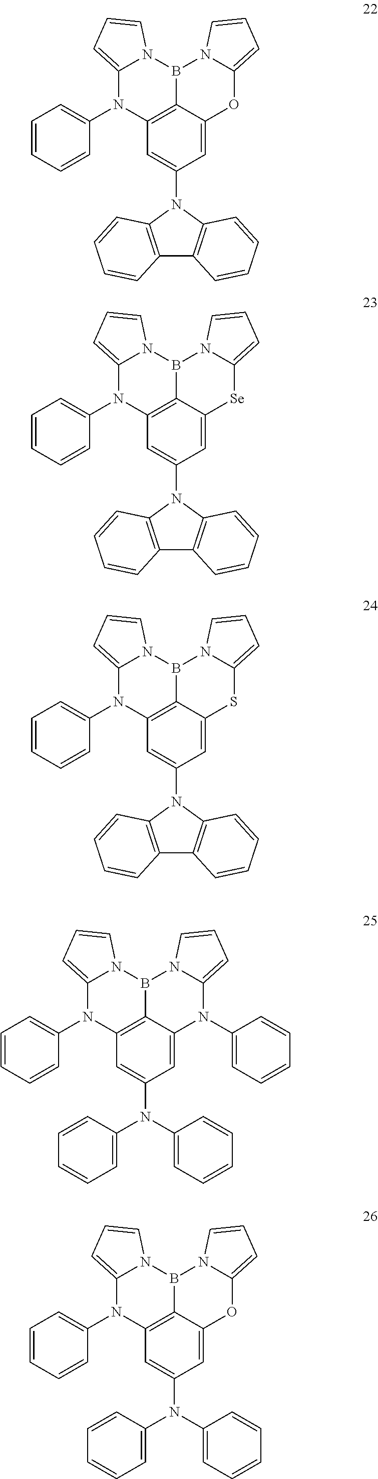

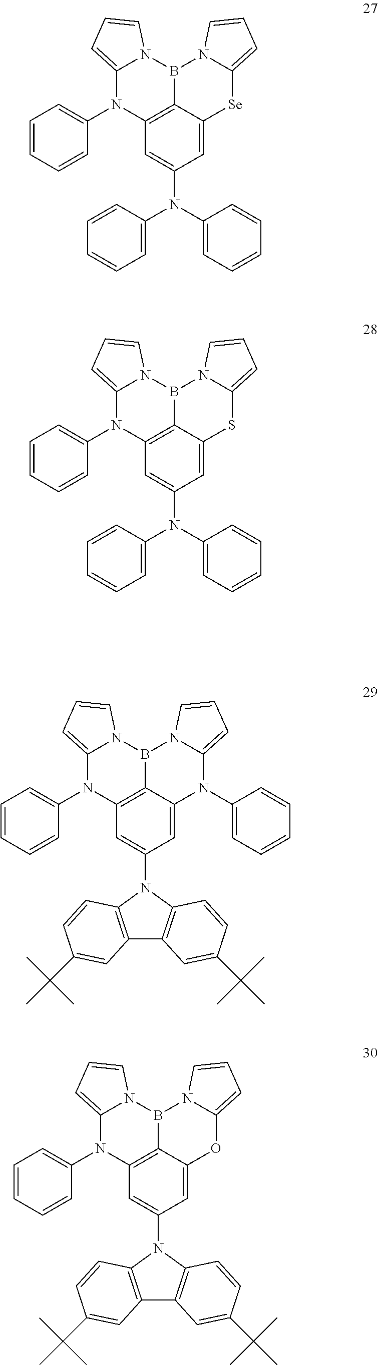 [SMILES: c1ccc(N(c2ccccc2)c2cc3c4c(c2)N(c2ccccc2)c2cccn2B4n2cccc2[Se]3)cc1 ; c1ccc(N(c2ccccc2)c2cc3c4c(c2)N(c2ccccc2)c2cccn2B4n2cccc2S3)cc1 ; CC(C)(C)c1ccc2c(c1)c1cc(C(C)(C)C)ccc1n2-c1cc2c3c(c1)N(c1ccccc1)c1cccn1B3n1cccc1N2c1ccccc1 ; CC(C)(C)c1ccc2c(c1)c1cc(C(C)(C)C)ccc1n2-c1cc2c3c(c1)N(c1ccccc1)c1cccn1B3n1cccc1O2]

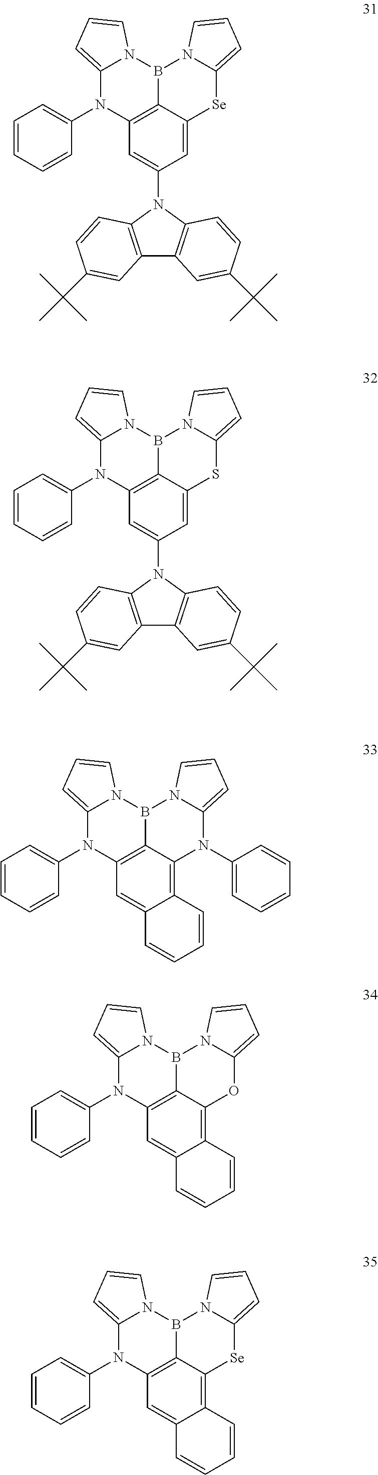 [SMILES: CC(C)(C)c1ccc2c(c1)c1cc(C(C)(C)C)ccc1n2-c1cc2c3c(c1)N(c1ccccc1)c1cccn1B3n1cccc1[Se]2 ; CC(C)(C)c1ccc2c(c1)c1cc(C(C)(C)C)ccc1n2-c1cc2c3c(c1)N(c1ccccc1)c1cccn1B3n1cccc1S2 ; c1ccc(N2c3cc4ccccc4c4c3B(n3cccc32)n2cccc2N4c2ccccc2)cc1 ; c1ccc(N2c3cc4ccccc4c4c3B(n3cccc3O4)n3cccc32)cc1 ; c1ccc(N2c3cc4ccccc4c4c3B(n3cccc3[Se]4)n3cccc32)cc1]

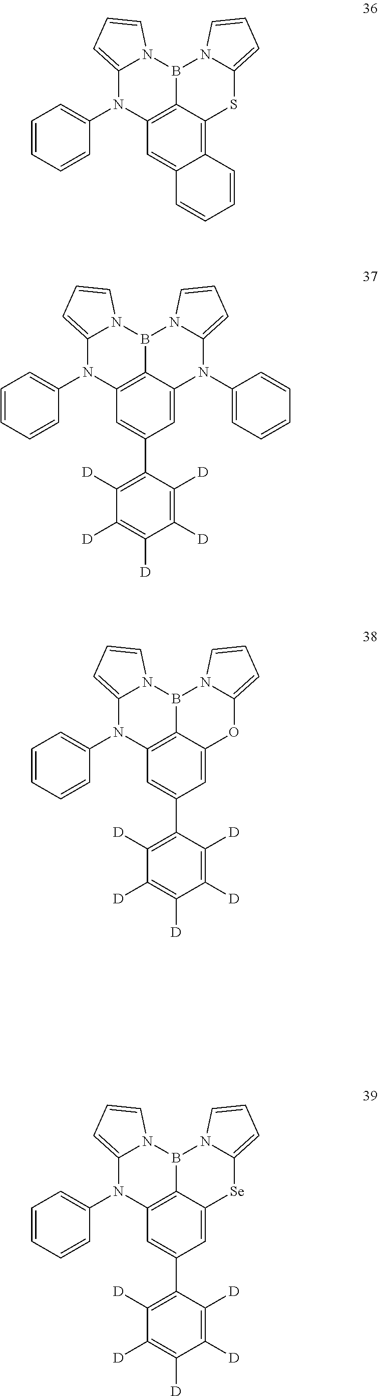 [SMILES: c1ccc(N2c3cc4ccccc4c4c3B(n3cccc3S4)n3cccc32)cc1 ; [2H]c1c([2H])c([2H])c(-c2cc3c4c(c2)N(c2ccccc2)c2cccn2B4n2cccc2N3c2ccccc2)c([2H])c1[2H] ; [2H]c1c([2H])c([2H])c(-c2cc3c4c(c2)N(c2ccccc2)c2cccn2B4n2cccc2O3)c([2H])c1[2H] ; [2H]c1c([2H])c([2H])c(-c2cc3c4c(c2)N(c2ccccc2)c2cccn2B4n2cccc2[Se]3)c([2H])c1[2H]]

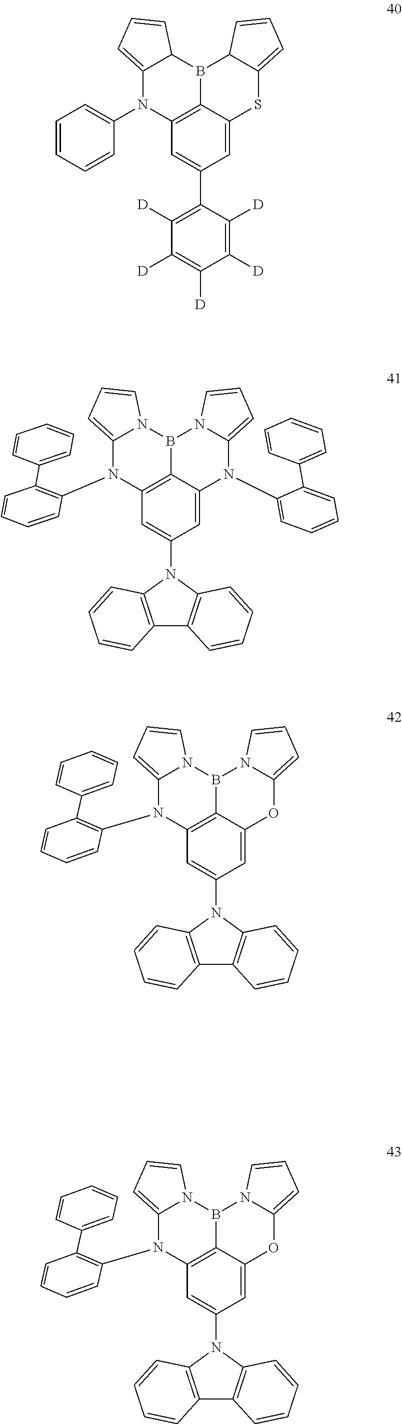 [SMILES: [2H]c1c([2H])c([2H])c(-c2cc3c4c(c2)N(c2ccccc2)C2=CC=CC2B4C2C=CC=C2S3)c([2H])c1[2H] ; c1ccc(-c2ccccc2N2c3cc(-n4c5ccccc5c5ccccc54)cc4c3B(n3cccc32)n2cccc2N4c2ccccc2-c2ccccc2)cc1 ; c1ccc(-c2ccccc2N2c3cc(-n4c5ccccc5c5ccccc54)cc4c3B(n3cccc3O4)n3cccc32)cc1 ; c1ccc(-c2ccccc2N2c3cc(-n4c5ccccc5c5ccccc54)cc4c3B(n3cccc3O4)n3cccc32)cc1]

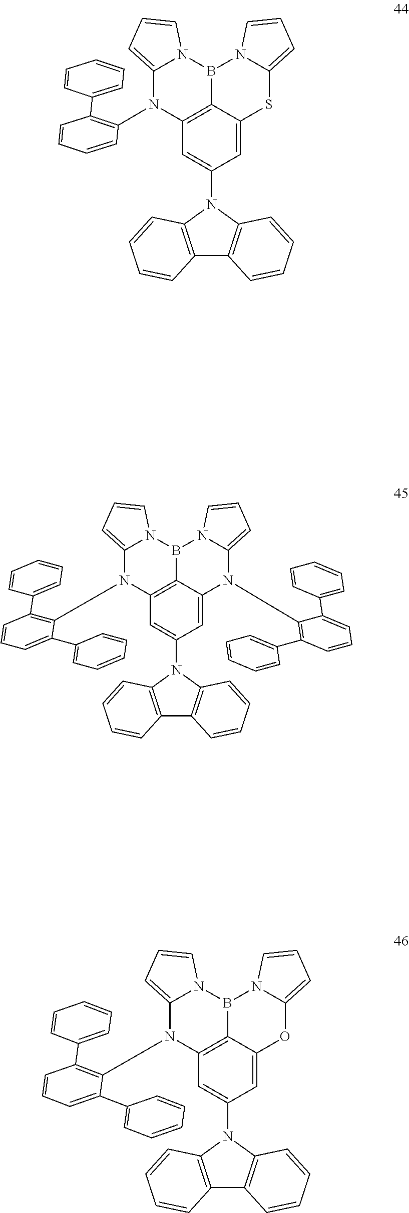 [SMILES: c1ccc(-c2ccccc2N2c3cc(-n4c5ccccc5c5ccccc54)cc4c3B(n3cccc3S4)n3cccc32)cc1 ; c1ccc(-c2cccc(-c3ccccc3)c2N2c3cc(-n4c5ccccc5c5ccccc54)cc4c3B(n3cccc32)n2cccc2N4c2c(-c3ccccc3)cccc2-c2ccccc2)cc1 ; c1ccc(-c2cccc(-c3ccccc3)c2N2c3cc(-n4c5ccccc5c5ccccc54)cc4c3B(n3cccc3O4)n3cccc32)cc1]

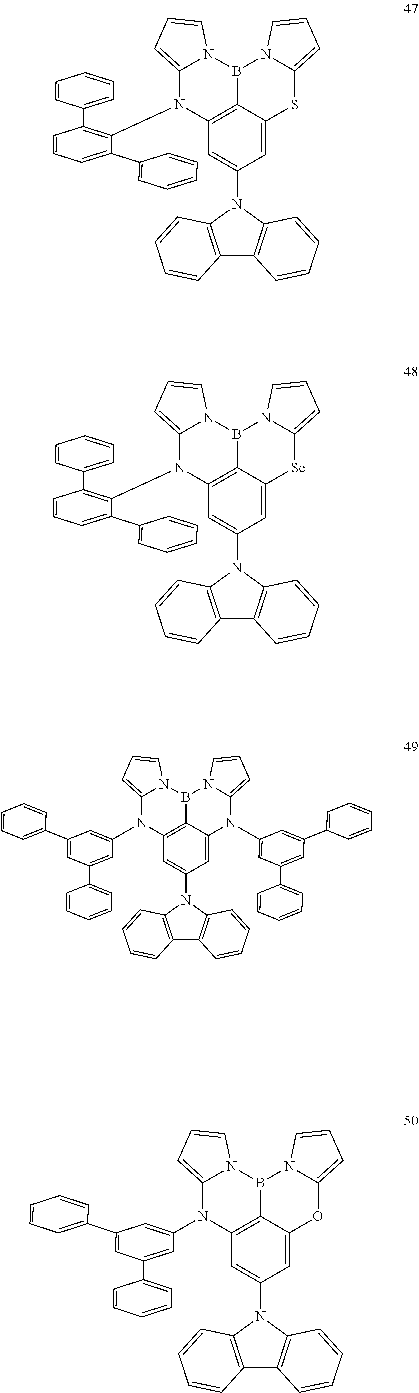 [SMILES: c1ccc(-c2cccc(-c3ccccc3)c2N2c3cc(-n4c5ccccc5c5ccccc54)cc4c3B(n3cccc3S4)n3cccc32)cc1 ; c1ccc(-c2cccc(-c3ccccc3)c2N2c3cc(-n4c5ccccc5c5ccccc54)cc4c3B(n3cccc3[Se]4)n3cccc32)cc1 ; c1ccc(-c2cc(-c3ccccc3)cc(N3c4cc(-n5c6ccccc6c6ccccc65)cc5c4B(n4cccc43)n3cccc3N5c3cc(-c4ccccc4)cc(-c4ccccc4)c3)c2)cc1 ; c1ccc(-c2cc(-c3ccccc3)cc(N3c4cc(-n5c6ccccc6c6ccccc65)cc5c4B(n4cccc4O5)n4cccc43)c2)cc1]

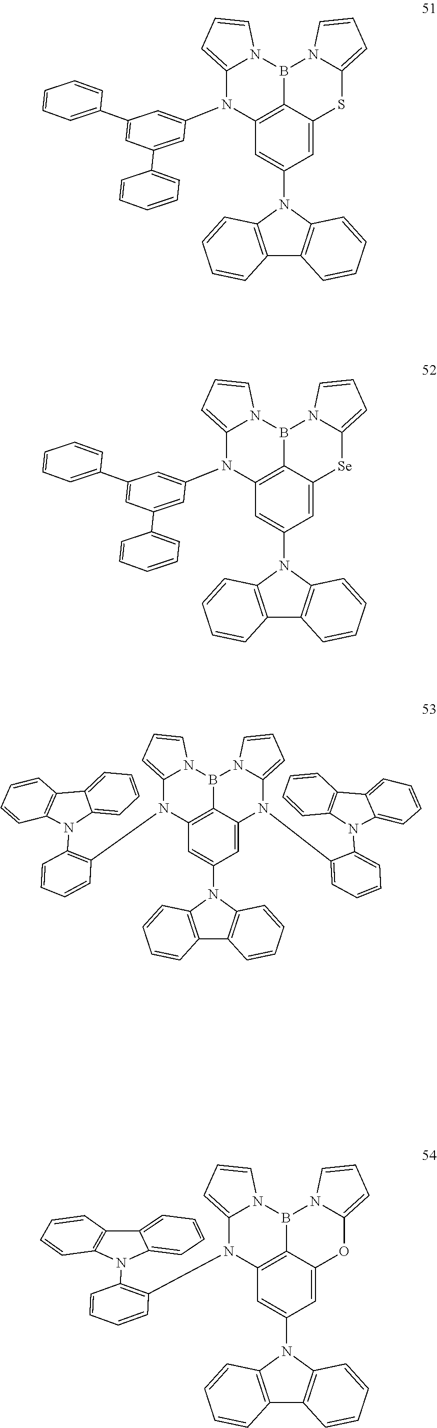 [SMILES: c1ccc(-c2cc(-c3ccccc3)cc(N3c4cc(-n5c6ccccc6c6ccccc65)cc5c4B(n4cccc4S5)n4cccc43)c2)cc1 ; c1ccc(-c2cc(-c3ccccc3)cc(N3c4cc(-n5c6ccccc6c6ccccc65)cc5c4B(n4cccc4[Se]5)n4cccc43)c2)cc1 ; c1ccc(-n2c3ccccc3c3ccccc32)c(N2c3cc(-n4c5ccccc5c5ccccc54)cc4c3B(n3cccc32)n2cccc2N4c2ccccc2-n2c3ccccc3c3ccccc32)c1 ; c1ccc(-n2c3ccccc3c3ccccc32)c(N2c3cc(-n4c5ccccc5c5ccccc54)cc4c3B(n3cccc3O4)n3cccc32)c1]

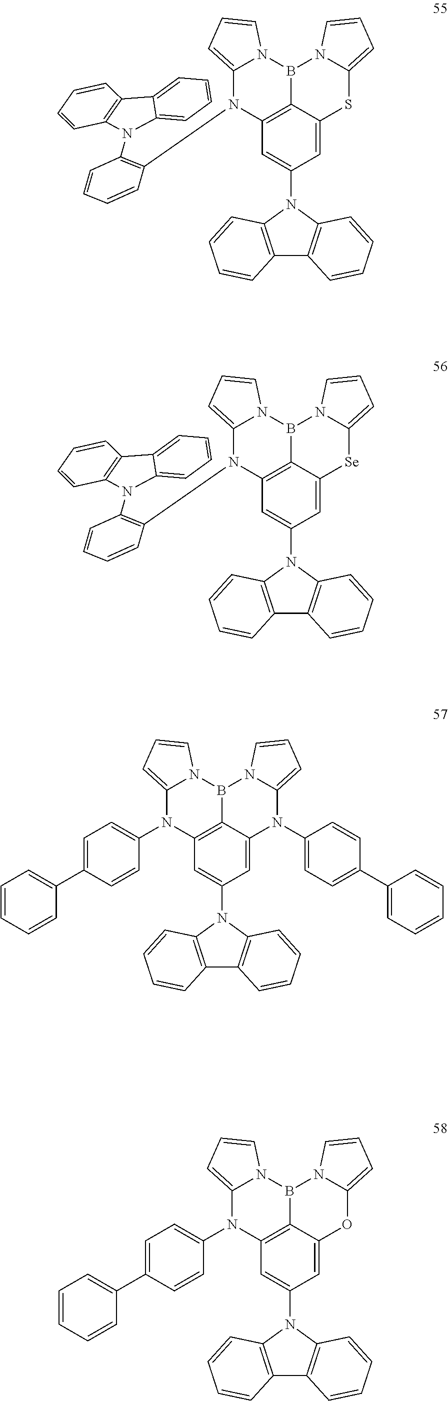 [SMILES: c1ccc(-n2c3ccccc3c3ccccc32)c(N2c3cc(-n4c5ccccc5c5ccccc54)cc4c3B(n3cccc3S4)n3cccc32)c1 ; c1ccc(-n2c3ccccc3c3ccccc32)c(N2c3cc(-n4c5ccccc5c5ccccc54)cc4c3B(n3cccc3[Se]4)n3cccc32)c1 ; c1ccc(-c2ccc(N3c4cc(-n5c6ccccc6c6ccccc65)cc5c4B(n4cccc43)n3cccc3N5c3ccc(-c4ccccc4)cc3)cc2)cc1 ; c1ccc(-c2ccc(N3c4cc(-n5c6ccccc6c6ccccc65)cc5c4B(n4cccc4O5)n4cccc43)cc2)cc1]

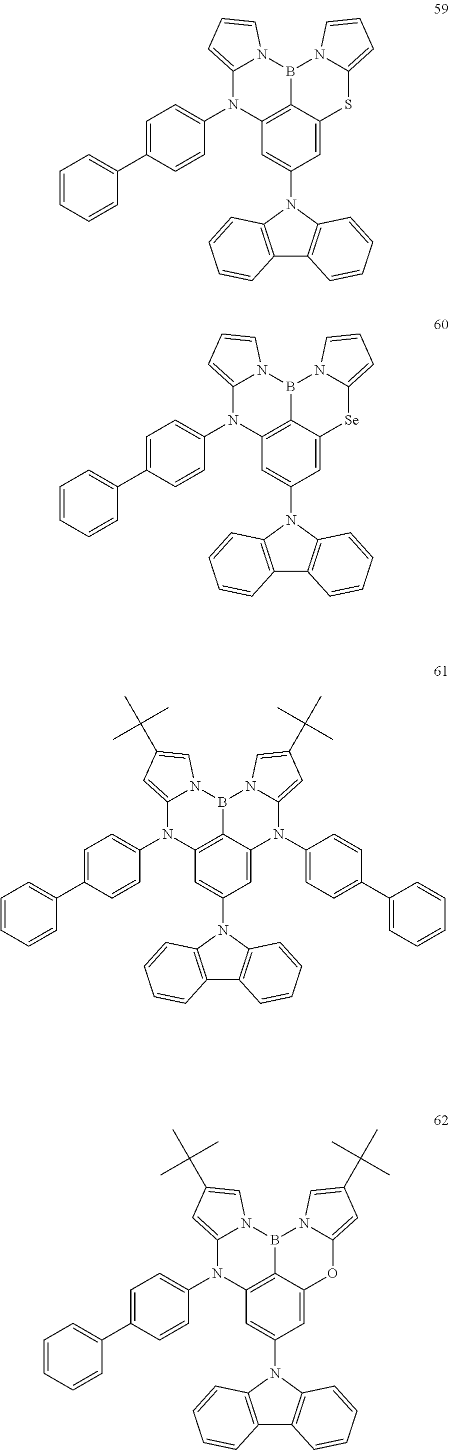 [SMILES: c1ccc(-c2ccc(N3c4cc(-n5c6ccccc6c6ccccc65)cc5c4B(n4cccc4S5)n4cccc43)cc2)cc1 ; c1ccc(-c2ccc(N3c4cc(-n5c6ccccc6c6ccccc65)cc5c4B(n4cccc4[Se]5)n4cccc43)cc2)cc1 ; CC(C)(C)c1cc2n(c1)B1c3c(cc(-n4c5ccccc5c5ccccc54)cc3N(c3ccc(-c4ccccc4)cc3)c3cc(C(C)(C)C)cn31)N2c1ccc(-c2ccccc2)cc1 ; CC(C)(C)c1cc2n(c1)B1c3c(cc(-n4c5ccccc5c5ccccc54)cc3N(c3ccc(-c4ccccc4)cc3)c3cc(C(C)(C)C)cn31)O2]

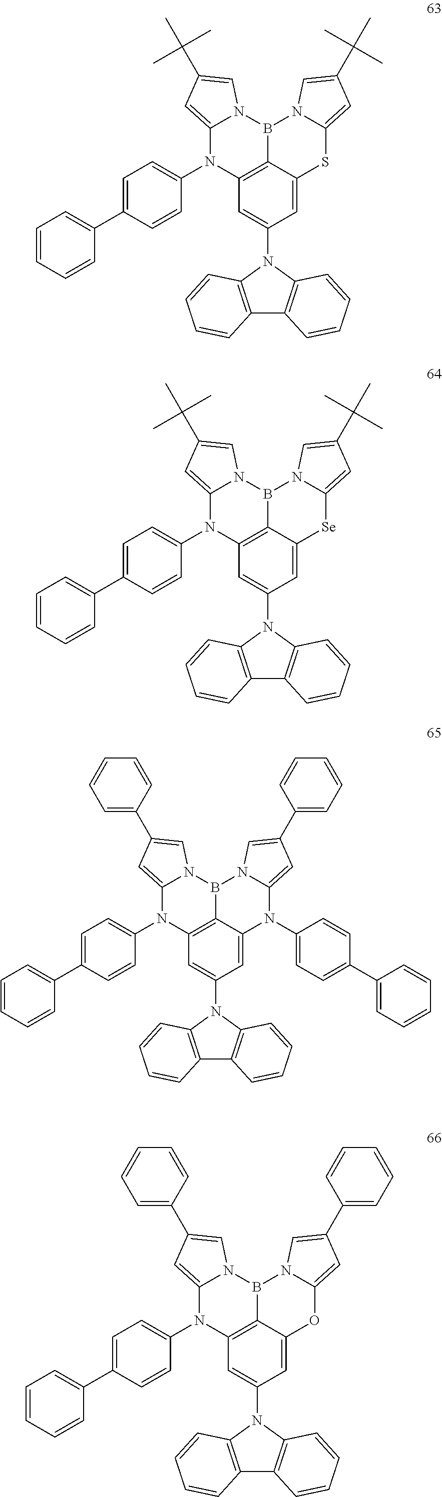 [SMILES: CC(C)(C)c1cc2n(c1)B1c3c(cc(-n4c5ccccc5c5ccccc54)cc3N(c3ccc(-c4ccccc4)cc3)c3cc(C(C)(C)C)cn31)S2 ; CC(C)(C)c1cc2n(c1)B1c3c(cc(-n4c5ccccc5c5ccccc54)cc3N(c3ccc(-c4ccccc4)cc3)c3cc(C(C)(C)C)cn31)[Se]2 ; c1ccc(-c2ccc(N3c4cc(-n5c6ccccc6c6ccccc65)cc5c4B(n4cc(-c6ccccc6)cc43)n3cc(-c4ccccc4)cc3N5c3ccc(-c4ccccc4)cc3)cc2)cc1 ; c1ccc(-c2ccc(N3c4cc(-n5c6ccccc6c6ccccc65)cc5c4B(n4cc(-c6ccccc6)cc4O5)n4cc(-c5ccccc5)cc43)cc2)cc1]

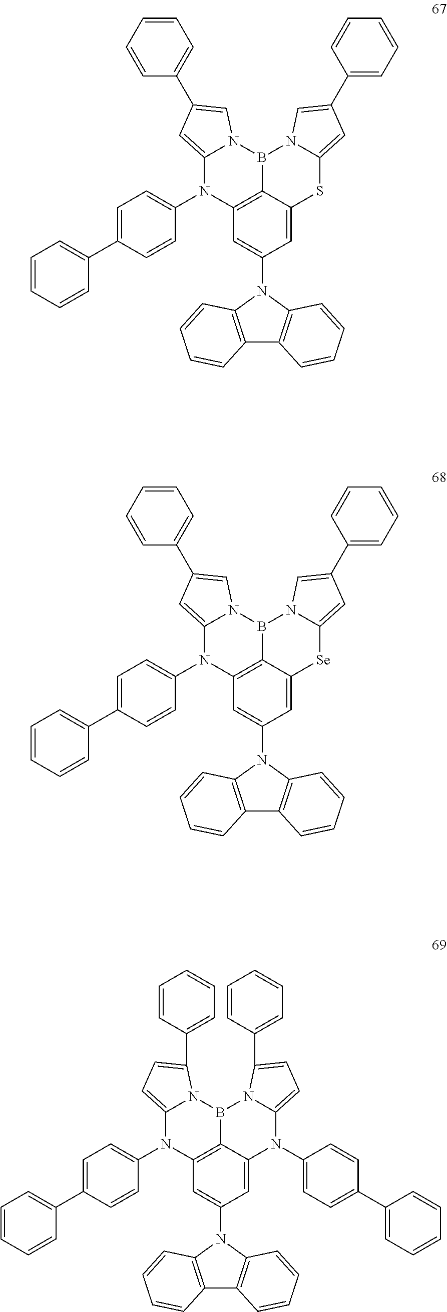 [SMILES: c1ccc(-c2ccc(N3c4cc(-n5c6ccccc6c6ccccc65)cc5c4B(n4cc(-c6ccccc6)cc4S5)n4cc(-c5ccccc5)cc43)cc2)cc1 ; c1ccc(-c2ccc(N3c4cc(-n5c6ccccc6c6ccccc65)cc5c4B(n4cc(-c6ccccc6)cc4[Se]5)n4cc(-c5ccccc5)cc43)cc2)cc1 ; c1ccc(-c2ccc(N3c4cc(-n5c6ccccc6c6ccccc65)cc5c4B(n4c(-c6ccccc6)ccc43)n3c(-c4ccccc4)ccc3N5c3ccc(-c4ccccc4)cc3)cc2)cc1]

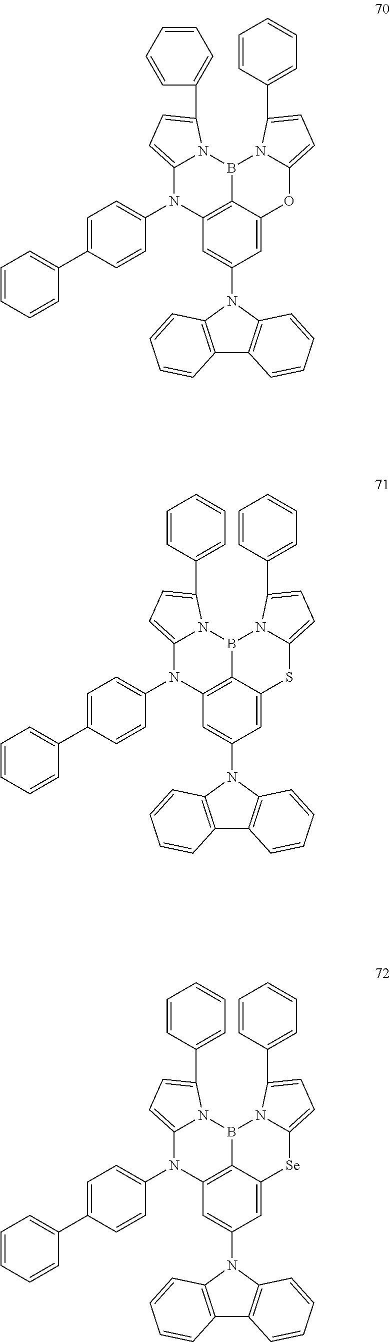 [SMILES: c1ccc(-c2ccc(N3c4cc(-n5c6ccccc6c6ccccc65)cc5c4B(n4c(ccc4-c4ccccc4)O5)n4c(-c5ccccc5)ccc43)cc2)cc1 ; c1ccc(-c2ccc(N3c4cc(-n5c6ccccc6c6ccccc65)cc5c4B(n4c(ccc4-c4ccccc4)S5)n4c(-c5ccccc5)ccc43)cc2)cc1 ; c1ccc(-c2ccc(N3c4cc(-n5c6ccccc6c6ccccc65)cc5c4B(n4c(ccc4-c4ccccc4)[Se]5)n4c(-c5ccccc5)ccc43)cc2)cc1]

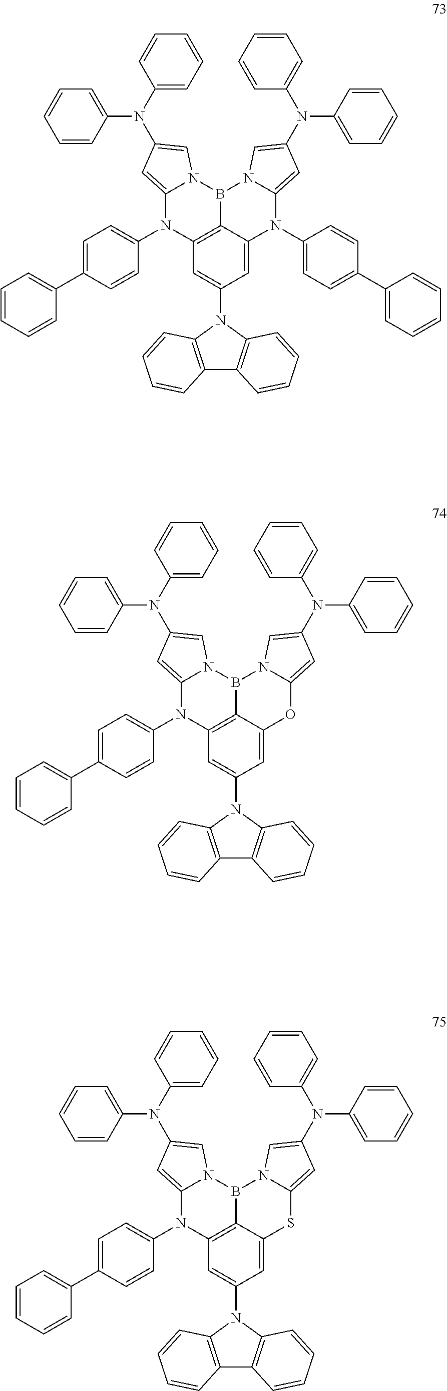 [SMILES: c1ccc(-c2ccc(N3c4cc(-n5c6ccccc6c6ccccc65)cc5c4B(n4cc(N(c6ccccc6)c6ccccc6)cc43)n3cc(N(c4ccccc4)c4ccccc4)cc3N5c3ccc(-c4ccccc4)cc3)cc2)cc1 ; c1ccc(-c2ccc(N3c4cc(-n5c6ccccc6c6ccccc65)cc5c4B(n4cc(N(c6ccccc6)c6ccccc6)cc4O5)n4cc(N(c5ccccc5)c5ccccc5)cc43)cc2)cc1 ; c1ccc(-c2ccc(N3c4cc(-n5c6ccccc6c6ccccc65)cc5c4B(n4cc(N(c6ccccc6)c6ccccc6)cc4S5)n4cc(N(c5ccccc5)c5ccccc5)cc43)cc2)cc1]

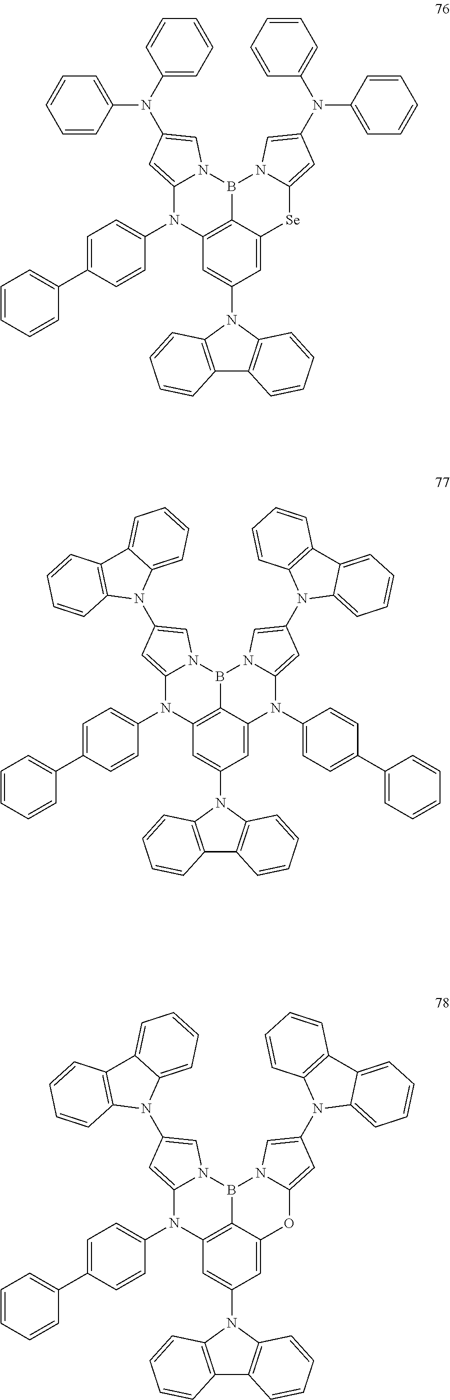 [SMILES: c1ccc(-c2ccc(N3c4cc(-n5c6ccccc6c6ccccc65)cc5c4B(n4cc(N(c6ccccc6)c6ccccc6)cc4[Se]5)n4cc(N(c5ccccc5)c5ccccc5)cc43)cc2)cc1 ; c1ccc(-c2ccc(N3c4cc(-n5c6ccccc6c6ccccc65)cc5c4B(n4cc(-n6c7ccccc7c7ccccc76)cc43)n3cc(-n4c6ccccc6c6ccccc64)cc3N5c3ccc(-c4ccccc4)cc3)cc2)cc1 ; c1ccc(-c2ccc(N3c4cc(-n5c6ccccc6c6ccccc65)cc5c4B(n4cc(-n6c7ccccc7c7ccccc76)cc4O5)n4cc(-n5c6ccccc6c6ccccc65)cc43)cc2)cc1]

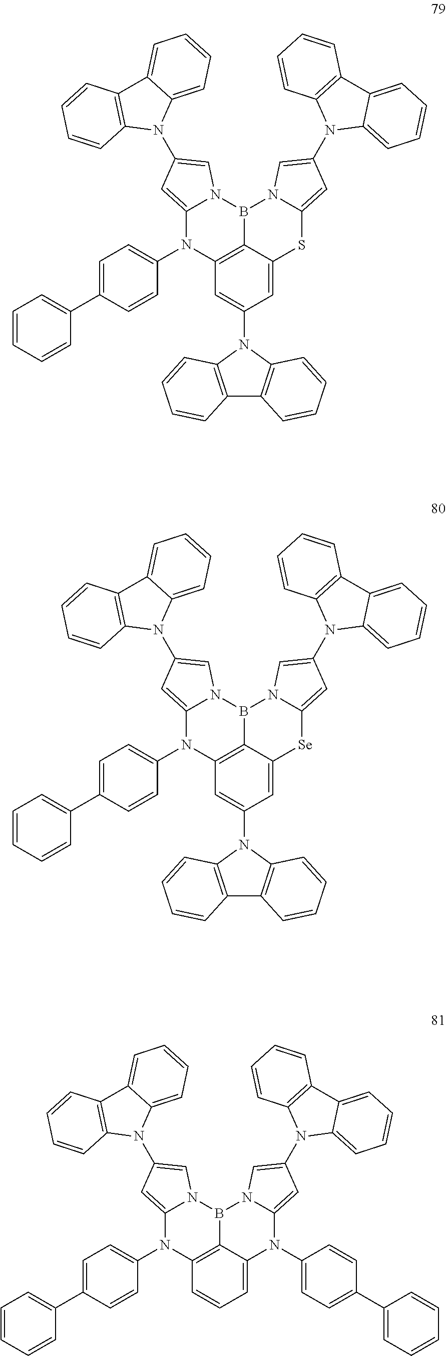 [SMILES: c1ccc(-c2ccc(N3c4cc(-n5c6ccccc6c6ccccc65)cc5c4B(n4cc(-n6c7ccccc7c7ccccc76)cc4S5)n4cc(-n5c6ccccc6c6ccccc65)cc43)cc2)cc1 ; c1ccc(-c2ccc(N3c4cc(-n5c6ccccc6c6ccccc65)cc5c4B(n4cc(-n6c7ccccc7c7ccccc76)cc4[Se]5)n4cc(-n5c6ccccc6c6ccccc65)cc43)cc2)cc1 ; c1ccc(-c2ccc(N3c4cccc5c4B(n4cc(-n6c7ccccc7c7ccccc76)cc43)n3cc(-n4c6ccccc6c6ccccc64)cc3N5c3ccc(-c4ccccc4)cc3)cc2)cc1]

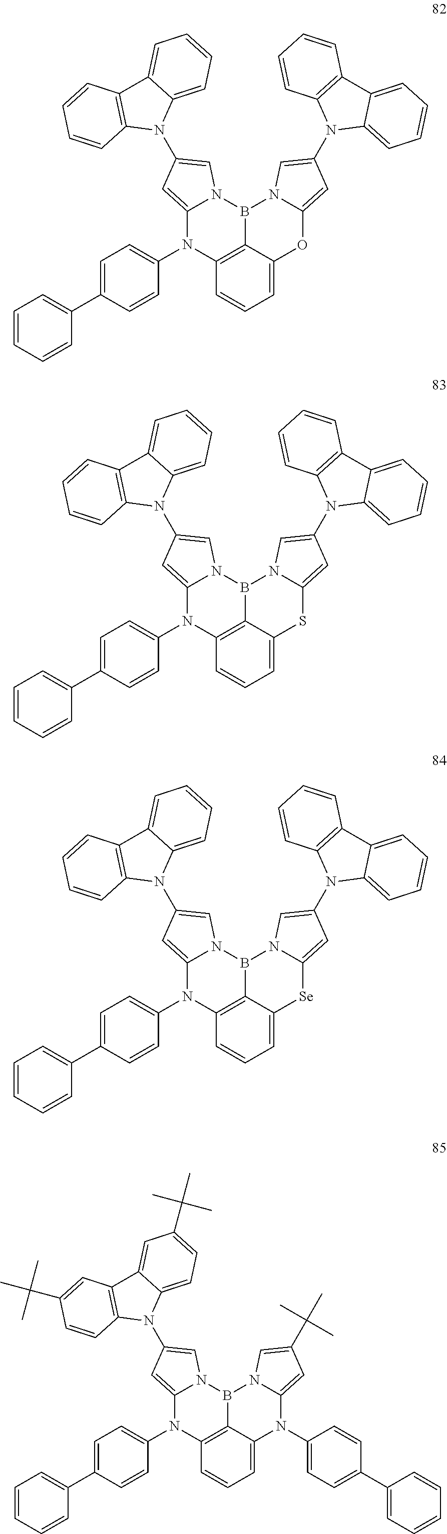 [SMILES: c1ccc(-c2ccc(N3c4cccc5c4B(n4cc(-n6c7ccccc7c7ccccc76)cc4O5)n4cc(-n5c6ccccc6c6ccccc65)cc43)cc2)cc1 ; c1ccc(-c2ccc(N3c4cccc5c4B(n4cc(-n6c7ccccc7c7ccccc76)cc4S5)n4cc(-n5c6ccccc6c6ccccc65)cc43)cc2)cc1 ; c1ccc(-c2ccc(N3c4cccc5c4B(n4cc(-n6c7ccccc7c7ccccc76)cc4[Se]5)n4cc(-n5c6ccccc6c6ccccc65)cc43)cc2)cc1 ; CC(C)(C)c1ccc2c(c1)c1cc(C(C)(C)C)ccc1n2-c1cc2n(c1)B1c3c(cccc3N(c3ccc(-c4ccccc4)cc3)c3cc(C(C)(C)C)cn31)N2c1ccc(-c2ccccc2)cc1]

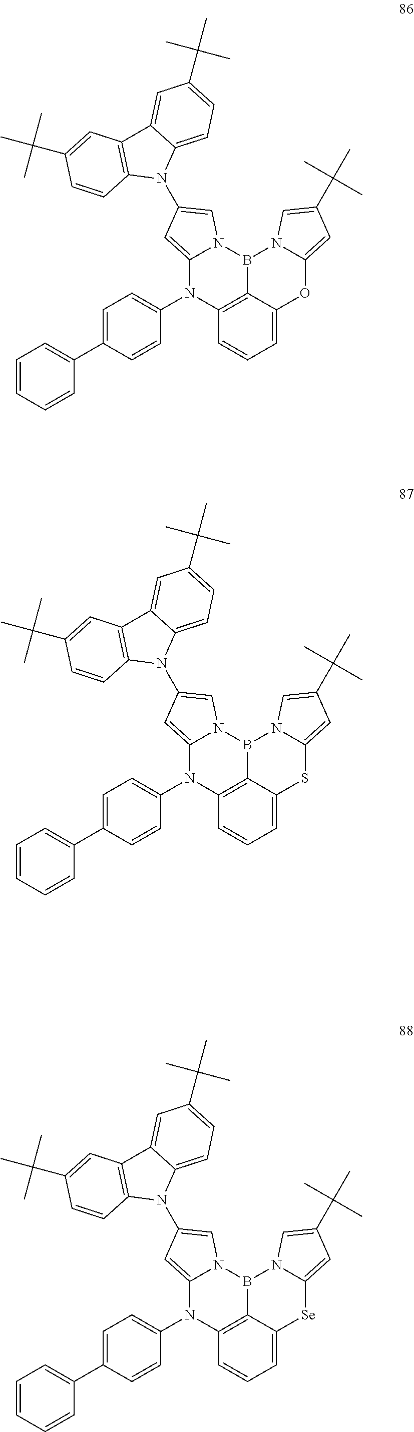

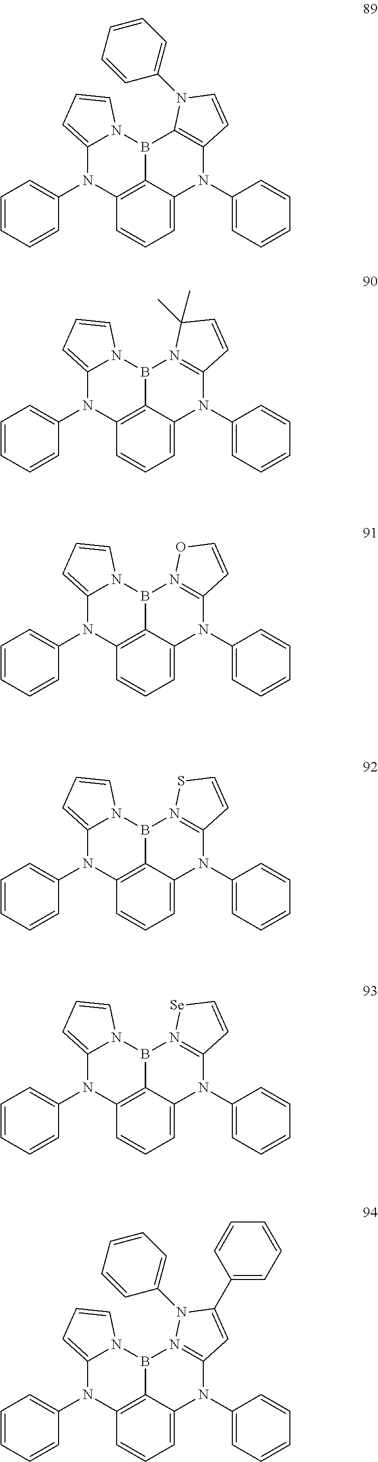

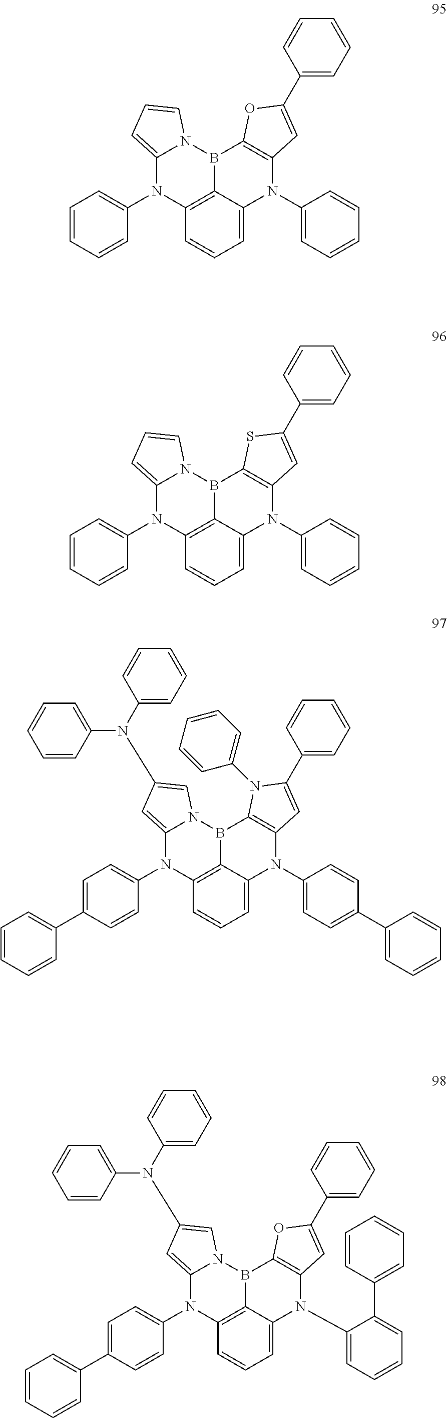 [SMILES: c1ccc(-c2cc3c(o2)B2c4c(cccc4N(c4ccccc4)c4cccn42)N3c2ccccc2)cc1 ; c1ccc(-c2cc3c(s2)B2c4c(cccc4N(c4ccccc4)c4cccn42)N3c2ccccc2)cc1 ; c1ccc(-c2ccc(N3c4cccc5c4B(c4c3cc(-c3ccccc3)n4-c3ccccc3)n3cc(N(c4ccccc4)c4ccccc4)cc3N5c3ccc(-c4ccccc4)cc3)cc2)cc1 ; c1ccc(-c2ccc(N3c4cccc5c4B(c4oc(-c6ccccc6)cc4N5c4ccccc4-c4ccccc4)n4cc(N(c5ccccc5)c5ccccc5)cc43)cc2)cc1]

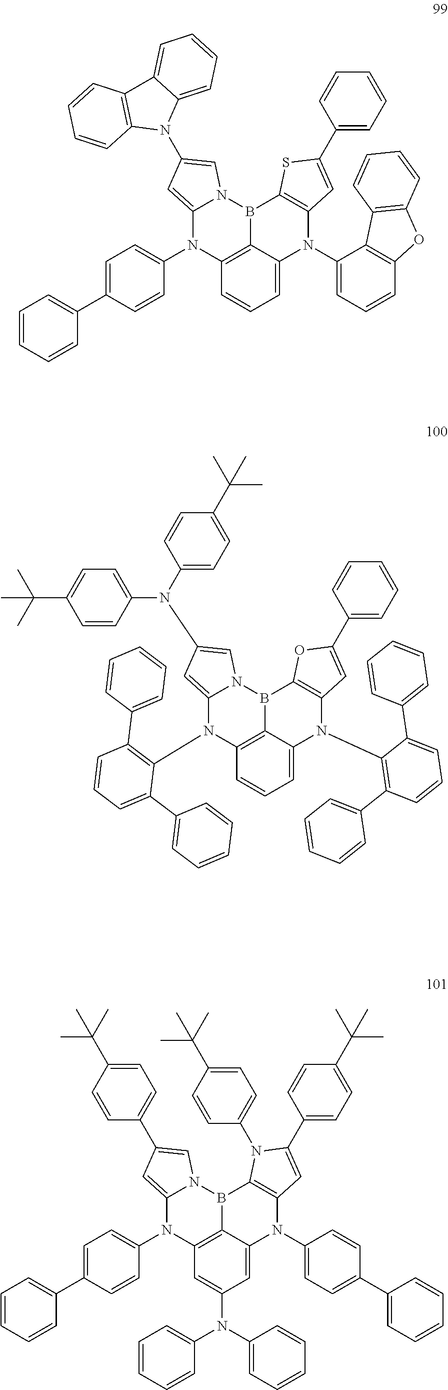 [SMILES: c1ccc(-c2ccc(N3c4cccc5c4B(c4sc(-c6ccccc6)cc4N5c4cccc5oc6ccccc6c45)n4cc(-n5c6ccccc6c6ccccc65)cc43)cc2)cc1 ; CC(C)(C)c1ccc(N(c2ccc(C(C)(C)C)cc2)c2cc3n(c2)B2c4oc(-c5ccccc5)cc4N(c4c(-c5ccccc5)cccc4-c4ccccc4)c4cccc(c42)N3c2c(-c3ccccc3)cccc2-c2ccccc2)cc1 ; CC(C)(C)c1ccc(-c2cc3n(c2)B2c4c(cc(N(c5ccccc5)c5ccccc5)cc4N3c3ccc(-c4ccccc4)cc3)N(c3ccc(-c4ccccc4)cc3)c3cc(-c4ccc(C(C)(C)C)cc4)n(-c4ccc(C(C)(C)C)cc4)c32)cc1]

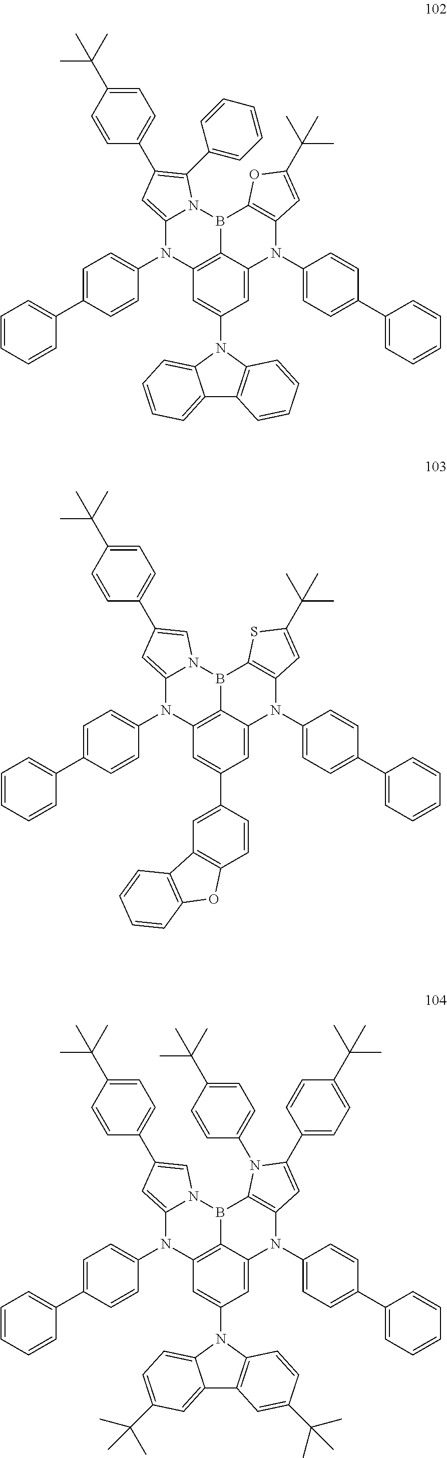 [SMILES: CC(C)(C)c1ccc(-c2cc3n(c2-c2ccccc2)B2c4oc(C(C)(C)C)cc4N(c4ccc(-c5ccccc5)cc4)c4cc(-n5c6ccccc6c6ccccc65)cc(c42)N3c2ccc(-c3ccccc3)cc2)cc1 ; CC(C)(C)c1ccc(-c2cc3n(c2)B2c4sc(C(C)(C)C)cc4N(c4ccc(-c5ccccc5)cc4)c4cc(-c5ccc6oc7ccccc7c6c5)cc(c42)N3c2ccc(-c3ccccc3)cc2)cc1 ; CC(C)(C)c1ccc(-c2cc3n(c2)B2c4c(cc(-n5c6ccc(C(C)(C)C)cc6c6cc(C(C)(C)C)ccc65)cc4N3c3ccc(-c4ccccc4)cc3)N(c3ccc(-c4ccccc4)cc3)c3cc(-c4ccc(C(C)(C)C)cc4)n(-c4ccc(C(C)(C)C)cc4)c32)cc1]

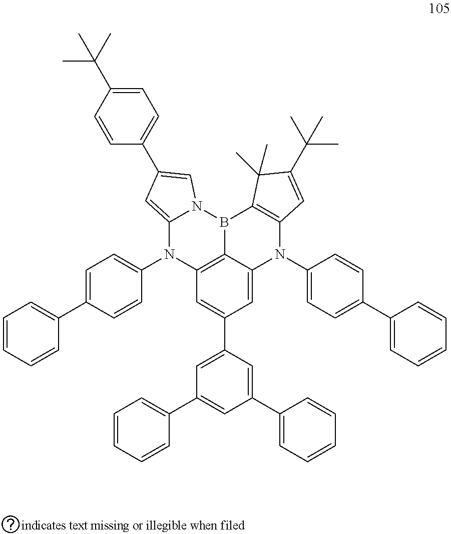 [SMILES: CC(C)(C)C1=CC2=C(B3c4c(cc(-c5cc(-c6ccccc6)cc(-c6ccccc6)c5)cc4N(c4ccc(-c5ccccc5)cc4)c4cc(-c5ccc(C(C)(C)C)cc5)cn43)N2c2ccc(-c3ccccc3)cc2)C1(C)C]

A light emitting diode of the present disclosure includes: a first electrode; a second electrode on the first electrode; and at least one functional layer between the first electrode and the second electrode, wherein the at least one functional layer includes at least one among a compound represented by Formula E-2b and a polycyclic compound represented by Formula 1.

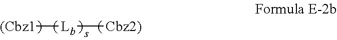

In Formula E-2b, Cbz1 and Cbz2 are each independently a substituted or unsubstituted carbazole group, L_{b} is a direct linkage, a substituted or unsubstituted arylene group of 6 to 30 ring-forming carbon atoms, or a substituted or unsubstituted heteroarylene group of 2 to 30 ring-forming carbon atoms, and “s” is an integer of 0 to 10.

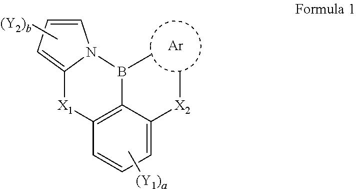

In Formula 1, Ar is a substituted or unsubstituted aromatic ring, X₁ and X₂ are each independently CR₁R₂, NR₃, O, S, or Se, Y₁ and Y₂ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring, “a” and “b” are each independently an integer of 0 to 3, and R₁ to R₃ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring.

In an embodiment, the at least one functional layer may further include a compound represented by Formula M-b.

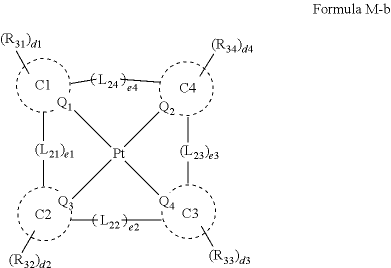

In Formula M-b, Q₁ to Q₄ are each independently C or N, C1 to C4 are each independently a substituted or unsubstituted hydrocarbon ring of 5 to 30 ring-forming carbon atoms, or a substituted or unsubstituted heterocycle of 2 to 30 ring-forming carbon atoms, L₂₁ to L₂₄ are each independently a direct linkage,

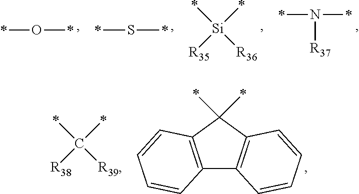

a substituted or unsubstituted divalent alkyl group of 1 to 30 carbon atoms, a substituted or unsubstituted arylene group of 6 to 50 ring-forming carbon atoms, or a substituted or unsubstituted heteroarylene group of 2 to 50 ring-forming carbon atoms, e1 to e4 are each independently 0 or 1, R₃₁ to R₃₉ are each independently a hydrogen atom, a deuterium atom, a halogen atom, a cyano group, a substituted or unsubstituted amine group, a substituted or unsubstituted alkyl group of 1 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring, and d1 to d4 are each independently an integer of 0 to 4.

### BRIEF DESCRIPTION OF THE DRAWINGS

The accompanying drawings are included to provide a further understanding of the subject matter of the present disclosure and are incorporated in and constitute a part of this specification. The drawings illustrate embodiments of the present disclosure and, together with the description, serve to explain principles of the present disclosure. In the drawings:

FIG. 1 is a plan view showing a display apparatus of an embodiment;

FIG. 2 is a cross-sectional view of a display apparatus according to an embodiment;

FIG. 3 is a cross-sectional view schematically showing a light emitting diode according to an embodiment;

FIG. 4 is a cross-sectional view schematically showing a light emitting diode according to an embodiment;

FIG. 5 is a cross-sectional view schematically showing a light emitting diode according to an embodiment;

FIG. 6 is a cross-sectional view schematically showing a light emitting diode according to an embodiment;

FIG. 7 is a cross-sectional view of a display apparatus according to an embodiment; and

FIG. 8 is a cross-sectional view of a display apparatus according to an embodiment.

### DETAILED DESCRIPTION

The subject matter of the present disclosure may have various modifications and may be embodied in different forms, and example embodiments will be explained in more detail with reference to the accompanying drawings. The subject matter of the present disclosure may, however, be embodied in different forms and should not be construed as being limited to the embodiments set forth herein. Rather, all modifications, equivalents, substituents, and substitutions which are included in the spirit and technical scope of the present disclosure should be included in the present disclosure.

Like reference numerals refer to like elements throughout. In the drawings, the dimensions of structures may be exaggerated for clarity of illustration. It will be understood that, although the terms first, second, etc. may be used herein to describe various elements, these elements should not be limited by these terms. These terms are only used to distinguish one element from another element. Thus, a first element could be termed a second element without departing from the spirit or scope of the present disclosure. Similarly, a second element could be termed a first element. As used herein, the singular forms are intended to include the plural forms as well, unless the context clearly indicates otherwise.

In the description, it will be further understood that the terms “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the description, when a layer, a film, a region, a plate, etc. is referred to as being “on” or “above” another part, it can be “directly on” the other part, or intervening layers may also be present. On the contrary, when a layer, a film, a region, a plate, etc. is referred to as being “under” or “below” another part, it can be “directly under” the other part, or intervening layers may also be present. Also, when an element is referred to as being “on” another element, it can be under the other element.

In the description, the term “substituted or unsubstituted” corresponds to an atom, a group, or a compound substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the foregoing substituents may be substituted or unsubstituted. For example, a biphenyl group may be interpreted as an aryl group or a phenyl group substituted with a phenyl group.

In the description, the term “forming a ring via the combination with an adjacent group” may mean forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In addition, the ring formed via the combination with an adjacent group may be combined with another ring to form a spiro structure.

In the description, the term “adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentane, two ethyl groups may be interpreted as “adjacent groups” to each other. In addition, in 4,5-dimethylphenanthrene, two methyl groups may be interpreted as “adjacent groups” to each other.

In the description, a ring may be a fused ring consisting of an aliphatic ring having a carbon number of 3 to 60 or an aromatic ring of a carbon number of 6 to 60, or a combination thereof, and include a saturated or unsaturated ring. And an aromatic ring may be an aromatic hydrocarbon ring of carbon atoms 6 to 60 or an aromatic heterocycle of carbon atoms 2 to 60, or a combination thereof, and include a saturated or unsaturated ring.

In the description, a halogen atom may be a fluorine atom, a chlorine atom, a bromine atom or an iodine atom.

In the description, an alkyl group may be a linear, branched, or cyclic type (e.g., a linear, branched, or cyclic alkyl group). The carbon number of the alkyl group may be, for example, 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-heneicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, the alkyl group may be a linear, or branched type (e.g., a linear, branched, or cyclic alkyl group). The carbon number of the alkyl group may be, for example, 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-heneicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, a cycloalkyl group may mean a cyclic alkyl group. The carbon number of the cycloalkyl group may be, for example, 3 to 50, 3 to 30, 3 to 20, or 3 to 10. Examples of the cycloalkyl group include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., without limitation.

In the description, an alkenyl group means a hydrocarbon group including one or more carbon-carbon double bonds at a main chain (e.g., in the middle) or at a terminus (e.g., the terminal end) of an alkyl group having a carbon number of 2 or more. The alkenyl group may have a linear chain or a branched chain. The carbon number is not specifically limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, etc., without limitation.

In the description, an alkynyl group means a hydrocarbon group including one or more carbon-carbon triple bonds at a main chain (e.g., in the middle) or at a terminus (e.g., the terminal end) of an alkyl group having a carbon number of 2 or more. The alkynyl group may be a linear chain or a branched chain. The carbon number is not specifically limited, but may be 2 to 30, 2 to 20, or 2 to 10. Examples of the alkynyl group include an ethynyl group, a propynyl group, etc., without limitation.

In the description, a hydrocarbon ring group means an optional functional group or substituent derived from an aliphatic hydrocarbon ring. The hydrocarbon ring group may be a saturated hydrocarbon ring group of 5 to 20 ring-forming carbon atoms.

In the description, an aryl group means an optional functional group or substituent derived from an aromatic hydrocarbon ring. The aryl group may be a monocyclic aryl group or a polycyclic aryl group. The carbon number for forming rings in the aryl group may be, for example, 6 to 50, 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the description, a fluorenyl group may be substituted, and two substituents may be combined with each other to form a spiro structure. Examples of a substituted fluorenyl group are as follows, but embodiments of the present disclosure are not limited thereto.

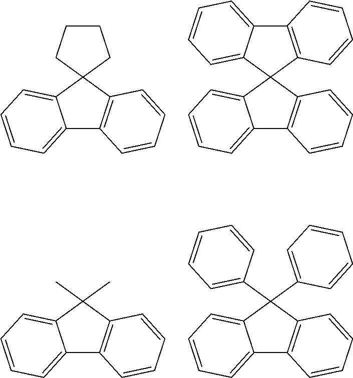

In the description, a heterocyclic group means an optional functional group or substituent derived from a ring including one or more among B, O, N, P, Si, S and Se as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle. If the heterocyclic group includes two or more heteroatoms, two or more heteroatoms may be the same or different. The heterocyclic group may be a monocyclic heterocyclic group or a polycyclic heterocyclic group, and has the concept including a heteroaryl group. The carbon number for forming rings of the heterocyclic group may be, for example, 2 to 50, 2 to 30, 2 to 20, or 2 to 10.

In the description, an aliphatic heterocyclic group may include one or more among B, O, N, P, Si, S and Se as heteroatoms. The number of ring-forming carbon atoms of the aliphatic heterocyclic group may be, for example, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the description, a heteroaryl group may include one or more among B, O, N, P, Si, S and Se as heteroatoms. If the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be, for example, 2 to 30, 2 to 20, or 2 to 10. Examples of the heteroaryl group may include thiophene, furan, pyrrole, imidazole, triazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the description, the explanation on the aryl group may be applied to an arylene group except that the arylene group is a divalent group. The explanation on the heteroaryl group may be applied to a heteroarylene group except that the heteroarylene group is a divalent group.

In the description, a silyl group includes an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the description, the carbon number of an amino group is not specifically limited, but may be 1 to 30. The amino group may include an alkyl amino group, an aryl amino group, or a heteroaryl amino group. Examples of the amino group include a methylamino group, a dimethylamino group, a phenylamino group, a diphenylamino group, a naphthylamino group, a 9-methyl-anthracenylamino group, etc., without limitation.

In the description, the carbon number of a carbonyl group is not specifically limited, but the carbon number may be 1 to 40, 1 to 30, or 1 to 20. For example, the carbonyl group may have the structures below, but is not limited thereto.

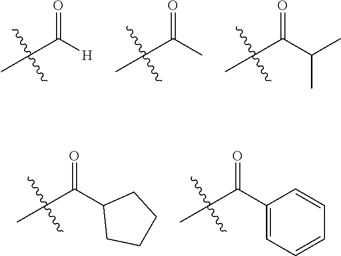

In the description, the carbon number of a sulfinyl group and sulfonyl group is not specifically limited, but may be 1 to 30. The sulfinyl group may include an alkyl sulfinyl group and an aryl sulfinyl group. The sulfonyl group may include an alkyl sulfonyl group and an aryl sulfonyl group.

In the description, a thio group may include an alkyl thio group and an aryl thio group. The thio group may mean the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the description, an oxy group may mean the above-defined alkyl group or aryl group which is combined with an oxygen atom. The oxy group may include an alkoxy group and/or an aryl oxy group. The alkoxy group may have a linear, branched or cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, embodiments of the present disclosure are not limited thereto.

In the description, a boron group may mean the above-defined alkyl group or aryl group which is combined with a boron atom. The boron group may include an alkyl boron group and/or an aryl boron group. Examples of the boron group include a dimethylboron group, a diethylboron group, a t-butylmethylboron group, a diphenylboron group, a phenylboron group, etc., without limitation.

In the description, the carbon number of an amine group is not specifically limited, but may be 1 to 30. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, etc., without limitation.

In the description, the alkyl group in the alkoxy group, the alkylthio group, alkylsulfonyl group, alkylaryl group, alkylamino group, alkylboron group, alkyl silyl group, and alkyl amine group may be the same as the examples of the above-described alkyl group.

In the description, the aryl group in the aryloxy group, arylthio group, arylsulfonyl group, aryl amino group, arylboron group, aryl silyl group and aryl amine group may be the same as the examples of the above-described aryl group.

In the description, a direct linkage may mean a single bond.

In the present description,

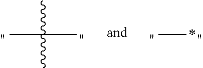

mean positions to be connected.

Hereinafter, embodiments of the present disclosure will be further explained referring to the drawings.

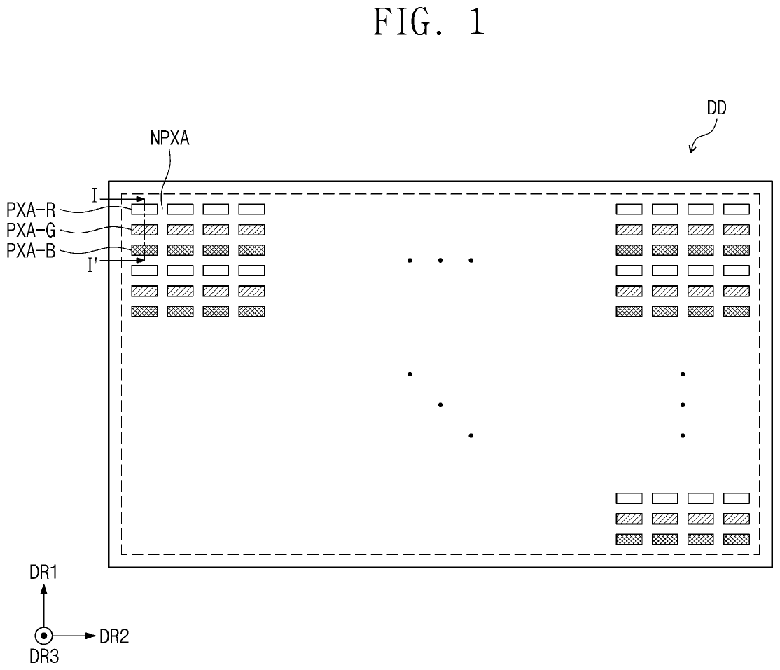

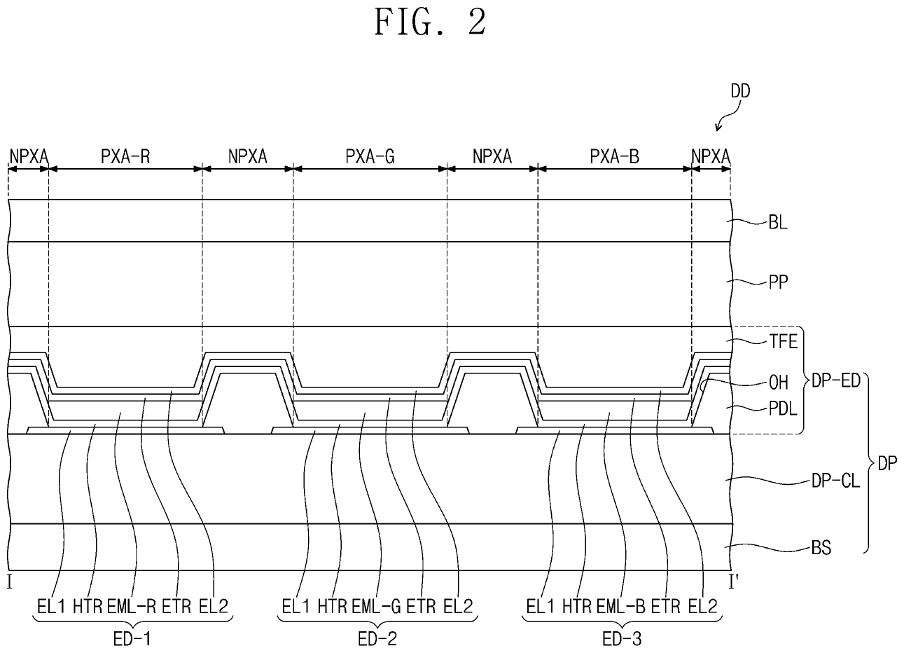

FIG. 1 is a plan view showing an embodiment of a display apparatus DD. FIG. 2 is a cross-sectional view of a display apparatus DD of an embodiment. FIG. 2 is a cross-sectional view showing a part corresponding to line I-I′ in FIG. 1.

The display apparatus DD may include a display panel DP and an optical layer PP on the display panel DP. The display panel DP includes light emitting diodes ED-1, ED-2 and ED-3. The display apparatus DD may include a plurality of light emitting diodes ED-1, ED-2 and ED-3. The optical layer PP may be on the display panel DP and control reflected light by external light at the display panel DP. The optical layer PP may include, for example, a polarization layer and/or a color filter layer. Different from the drawings, the optical layer PP may be omitted in the display apparatus DD of an embodiment.

A base substrate BL may be on the optical layer PP. The base substrate BL may be a member providing a base surface where the optical layer PP is located. The base substrate BL may be a glass substrate, a metal substrate, a plastic substrate, etc. However, an embodiment of the present disclosure is not limited thereto, and the base substrate BL may be an inorganic layer, an organic layer, and/or a composite material layer. In addition, different from the drawings, the base substrate BL may be omitted in an embodiment.

The display apparatus DD according to an embodiment may further include a filling layer. The filling layer may be between a display device layer DP-ED and a base substrate BL. The filling layer may be an organic layer. The filling layer may include at least one selected from among an acrylic-based resin, a silicon-based resin, and an epoxy-based resin.

The display panel DP may include a base layer BS, a circuit layer DP-CL provided on the base layer BS and a display device layer DP-ED. The display device layer DP-ED may include a pixel definition layer PDL, light emitting diodes ED-1, ED-2 and ED-3 between the pixel definition layer PDL, and an encapsulating layer TFE on the light emitting diodes ED-1, ED-2, and ED-3.

The base layer BS may be a member providing a base surface where the display device layer DP-ED is located. The base layer BS may be a glass substrate, a metal substrate, a plastic substrate, etc. However, embodiments of the present disclosure are not limited thereto, and the base layer BS may be an inorganic layer, an organic layer, and/or a composite material layer.

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include switching transistors and driving transistors for driving the light emitting diodes ED-1, ED-2, and ED-3 of the display device layer DP-ED.

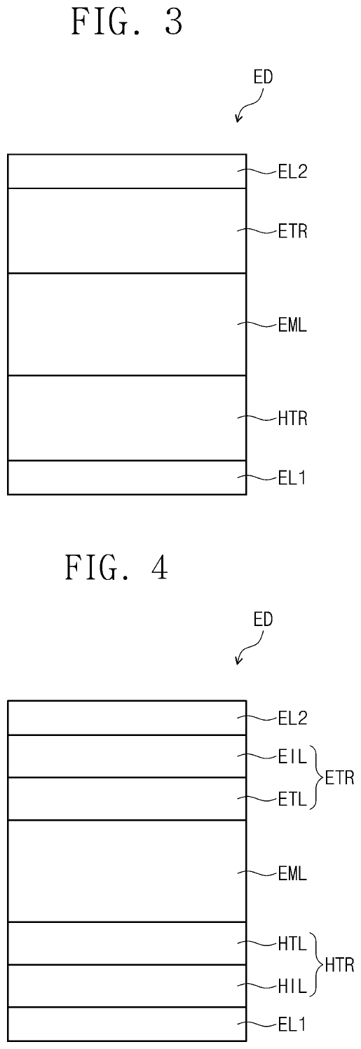

Each of the light emitting diodes ED-1, ED-2, and ED-3 may have the structures of light emitting diodes ED of embodiments according to FIG. 3 to FIG. 6, which will be further explained herein below. Each of the light emitting diodes ED-1, ED-2, and ED-3 may include a first electrode EL1, a hole transport region HTR, emission layers EML-R, EML-G, and EML-B, an electron transport region ETR, and a second electrode EL2.

In FIG. 2, shown is an embodiment where the emission layers EML-R, EML-G, and EML-B of light emitting diodes ED-1, ED-2, and ED-3, which are in opening portions OH defined in a pixel definition layer PDL, are located, and a hole transport region HTR, an electron transport region ETR and a second electrode EL2 are provided as common layers in all light emitting diodes ED-1, ED-2, and ED-3. However, embodiments of the present disclosure are not limited thereto. Different from FIG. 2, in an embodiment, the hole transport region HTR and the electron transport region ETR may be patterned and provided in the opening portions OH defined in the pixel definition layer PDL. For example, in an embodiment, the hole transport region HTR, the emission layers EML-R, EML-G and EML-B, and the electron transport region ETR of the light emitting diodes ED-1, ED-2, and ED-3 may be provided by patterning with an ink jet printing method.

An encapsulating layer TFE may cover the light emitting diodes ED-1, ED-2, and ED-3. The encapsulating layer TFE may encapsulate the elements (such as the light emitting diodes ED-1, ED-2, and ED-3) of the display device layer DP-ED. The encapsulating layer TFE may be a thin film encapsulating layer. The encapsulating layer TFE may be one layer or a stacked layer of a plurality of layers. The encapsulating layer TFE includes at least one insulating layer. The encapsulating layer TFE according to an embodiment may include at least one inorganic layer (hereinafter, an encapsulating inorganic layer). In addition, the encapsulating layer TFE according to an embodiment may include at least one organic layer (hereinafter, an encapsulating organic layer) and at least one encapsulating inorganic layer.

The encapsulating inorganic layer protects the display device layer DP-ED from moisture/oxygen, and the encapsulating organic layer protects the display device layer DP-ED from foreign materials such as dust particles. The encapsulating inorganic layer may include silicon nitride, silicon oxy nitride, silicon oxide, titanium oxide, and/or aluminum oxide, without specific limitation. The encapsulating organic layer may include an acrylic-based compound, an epoxy-based compound, etc. The encapsulating organic layer may include a photopolymerizable organic material, without specific limitation.

The encapsulating layer TFE may be on the second electrode EL2 and may be provided while filling the opening portion OH.

Referring to FIG. 1 and FIG. 2, the display apparatus DD may include a non-luminous area NPXA and luminous areas PXA-R, PXA-G, and PXA-B. The luminous areas PXA-R, PXA-G, and PXA-B may be areas that emit light produced from the light emitting diodes ED-1, ED-2, and ED-3, respectively. The luminous areas PXA-R, PXA-G, and PXA-B may be separated (e.g., spaced apart) from each other on a plane.

The luminous areas PXA-R, PXA-G, and PXA-B may be areas separated by the pixel definition layer PDL. The non-luminous areas NPXA may be areas between neighboring luminous areas PXA-R, PXA-G, and PXA-B and may be areas corresponding to the pixel definition layer PDL. In the present disclosure, each of the luminous areas PXA-R, PXA-G, and PXA-B may correspond to each pixel. The pixel definition layer PDL may divide the light emitting diodes ED-1, ED-2, and ED-3. The emission layers EML-R, EML-G, and EML-B of the light emitting diodes ED-1, ED-2, and ED-3 may be located and divided in the opening portions OH defined in the pixel definition layer PDL.

The luminous areas PXA-R, PXA-G, and PXA-B may be divided into a plurality of groups according to the color of light produced from the light emitting diodes ED-1, ED-2, and ED-3. In the display apparatus DD of an embodiment, shown in FIG. 1 and FIG. 2, three luminous areas PXA-R, PXA-G, and PXA-B that emit red light, green light, and blue light, respectively, are illustrated as an embodiment. For example, the display apparatus DD of an embodiment may include a red luminous area PXA-R, a green luminous area PXA-G, and a blue luminous area PXA-B, which are separated (e.g., spaced apart) from each other.

In the display apparatus DD according to an embodiment, a plurality of light emitting diodes ED-1, ED-2, and ED-3 may respectively emit light having different wavelength regions. For example, in an embodiment, the display apparatus DD may include a first light emitting diode ED-1 that emits red light, a second light emitting diode ED-2 that emits green light, and a third light emitting diode ED-3 that emits blue light. In some embodiments, the red luminous area PXA-R, the green luminous area PXA-G, and the blue luminous area PXA-B of the display apparatus DD may correspond to the first light emitting diode ED-1, the second light emitting diode ED-2, and the third light emitting diode ED-3, respectively.

However, embodiments of the present disclosure is not limited thereto, and the first to third light emitting diodes ED-1, ED-2, and ED-3 may emit light in the same (e.g., substantially the same) wavelength region, or at least one thereof may emit light in a different wavelength region. For example, all the first to third light emitting diodes ED-1, ED-2, and ED-3 may emit blue light.

The luminous areas PXA-R, PXA-G, and PXA-B in the display apparatus DD according to an embodiment may be arranged in a stripe shape. Referring to FIG. 1, a plurality of red luminous areas PXA-R, a plurality of green luminous areas PXA-G, and a plurality of blue luminous areas PXA-B may be arranged along a second directional axis DR2. In addition, the red luminous area PXA-R, the green luminous area PXA-G, and the blue luminous area PXA-B may be arranged by turns along a first directional axis DR1.

In FIG. 1 and FIG. 2, the areas of the luminous areas PXA-R, PXA-G, and PXA-B are shown to be the same, but embodiments of the present disclosure are not limited thereto. The areas of the luminous areas PXA-R, PXA-G, and PXA-B may be different from each other according to the wavelength region of light emitted. The areas of the luminous areas PXA-R, PXA-G, and PXA-B may mean areas on a plane defined by the first directional axis DR1 and the second directional axis DR2.

The arrangement type of the luminous areas PXA-R, PXA-G and PXA-B is not limited to the configuration shown in FIG. 1, and the arrangement order of the red luminous areas PXA-R, the green luminous areas PXA-G, and the blue luminous areas PXA-B may be provided in various suitable combinations according to the properties of display quality desired for the display apparatus DD. For example, the arrangement type of the luminous areas PXA-R, PXA-G and PXA-B may be a PENTILE® arrangement type (e.g., an RGBG matrix, RGBG structure, or RGBG matrix structure), or a diamond arrangement type. PENTILE® is a duly registered trademark of Samsung Display Co., Ltd.

In addition, the areas of the luminous areas PXA-R, PXA-G, and PXA-B may be different from each other. For example, in an embodiment, the area of the green luminous area PXA-G may be smaller than the area of the blue luminous area PXA-B, but embodiments of the present disclosure are not limited thereto.

Hereinafter, FIG. 3 to FIG. 6 are cross-sectional views schematically showing light emitting diodes ED according to embodiments. The light emitting diode ED according to an embodiment may include a first electrode EL1, a hole transport region HTR, an emission layer EML, an electron transport region ETR, and a second electrode EL2 stacked in the stated order.

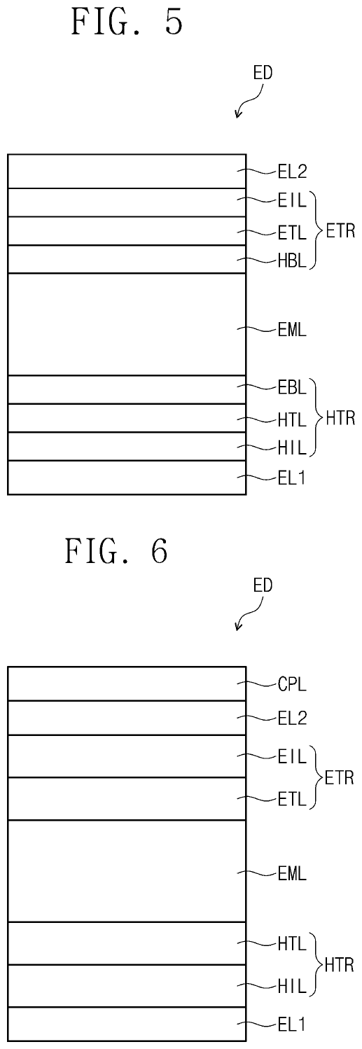

When compared with FIG. 3, FIG. 4 shows the cross-sectional view of a light emitting diode ED of an embodiment, wherein a hole transport region HTR includes a hole injection layer HIL and a hole transport layer HTL, and an electron transport region ETR includes an electron injection layer EIL and an electron transport layer ETL. In addition, when compared with FIG. 3, FIG. 5 shows the cross-sectional view of a light emitting diode ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 4, FIG. 6 shows the cross-sectional view of a light emitting diode ED of an embodiment, including a capping layer CPL on the second electrode EL2.

The first electrode EL1 has conductivity (e.g., electrical conductivity). The first electrode EL1 may be formed using a metal material, a metal alloy, and/or a conductive compound. The first electrode EL1 may be an anode or a cathode. However, embodiments of the present disclosure are not limited thereto. In addition, the first electrode EL1 may be a pixel electrode. The first electrode EL1 may be a transmissive electrode, a transflective electrode, or a reflective electrode. If the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, compounds thereof, and/or mixtures thereof (for example, a mixture of Ag and Mg). In some embodiments, the first electrode EL1 may have a structure including a plurality of layers including a reflective layer or a transflective layer formed using the above materials, and a transmissive conductive layer formed using ITO, IZO, ZnO, and/or ITZO. For example, the first electrode EL1 may include a three-layer structure of ITO/Ag/ITO. However, embodiments of the present disclosure are not limited thereto. The first electrode EL1 may include the above-described metal materials, combinations of two or more metal materials selected from the above-described metal materials, and/or oxides of the above-described metal materials. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one selected from a hole injection layer HIL, a hole transport layer HTL, a buffer layer, an emission auxiliary layer, and an electron blocking layer EBL. The thickness of the hole transport region HTR may be from about 50 Å to about 15,000 Å.

The hole transport region HTR may have a single layer formed using a single material, a single layer formed using a plurality of different materials, or a multilayer structure including a plurality of layers formed using a plurality of different materials.

For example, the hole transport region HTR may have the structure of a single layer of a hole injection layer HIL or a hole transport layer HTL, and may have a structure of a single layer formed using a hole injection material and a hole transport material. In some embodiments, the hole transport region HTR may have a structure of a single layer formed using a plurality of different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, without limitation.

The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1 below.

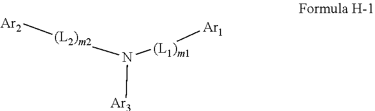

In Formula H-1 above, L₁ and L₂ may be each independently a direct linkage, a substituted or unsubstituted arylene group of 6 to 30 ring-forming carbon atoms, or a substituted or unsubstituted heteroarylene group of 2 to 30 ring-forming carbon atoms. “m1” and “m2” may be each independently an integer of 0 to 10. If “m1” or “m2” is an integer of 2 or more, a plurality of L₁ and L₂ may be each independently a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. In addition, in Formula H-1, Ar₃ may be a substituted or unsubstituted aryl group of 6 to 30 ring-forming carbon atoms.

The compound represented by Formula H-1 may be a monoamine compound. In some embodiments, the compound represented by Formula H-1 may be a diamine compound in which at least one among Ar₁ to Ar₃ includes an amine group as a substituent. In addition, the compound represented by Formula H-1 may be a carbazole-based compound in which at least one among Ar₁ to Ar₃ includes a substituted or unsubstituted carbazole group, and/or a fluorene-based compound in which at least one among Ar₁ to Ar₃ includes a substituted or unsubstituted fluorene group.

The compound represented by Formula H-1 may be represented by any one selected from among the compounds in Compound Group H below. However, the compounds shown in Compound Group H are only illustrations, and the compound represented by Formula H-1 is not limited to the compounds represented in Compound Group H below.

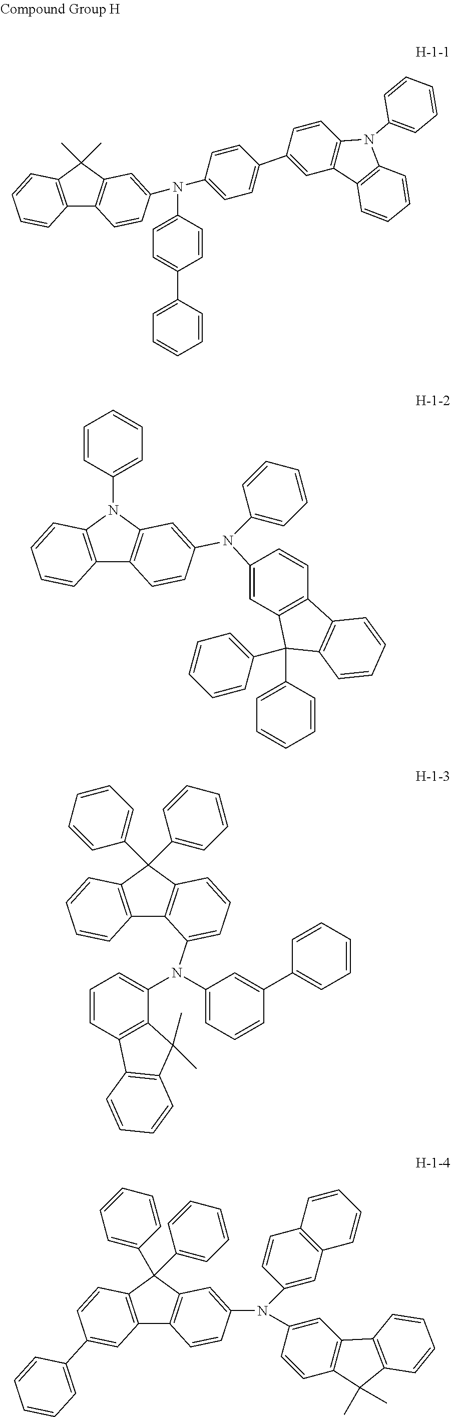 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

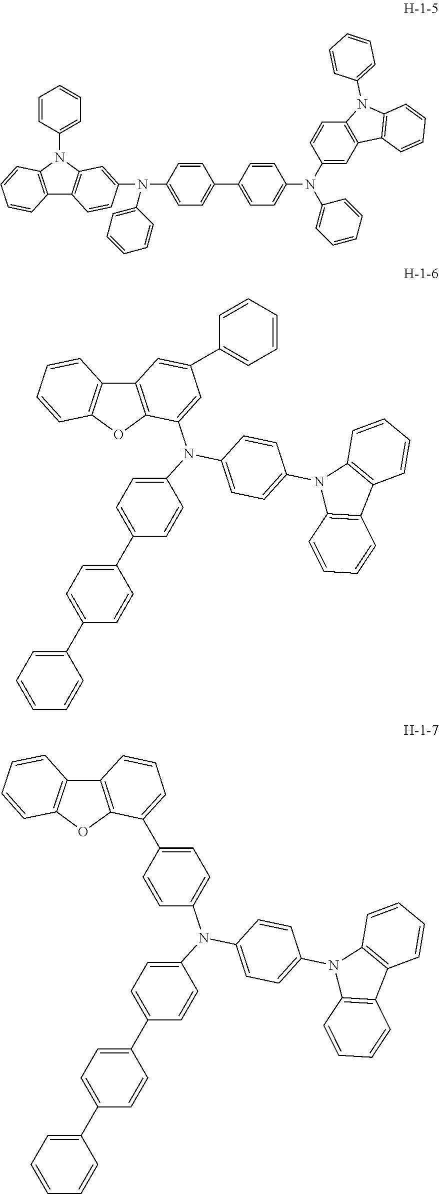 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

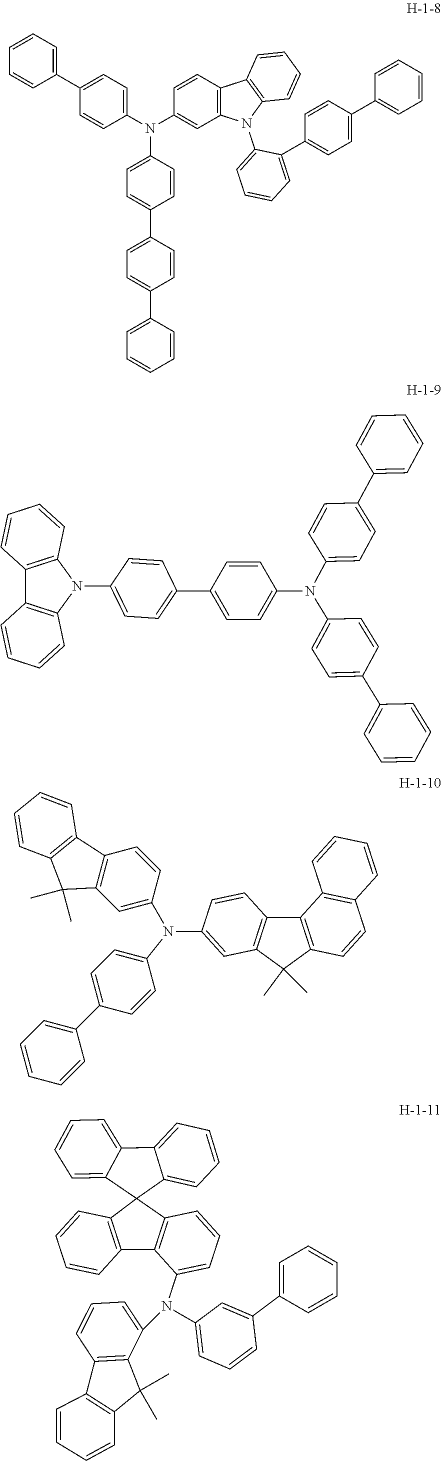

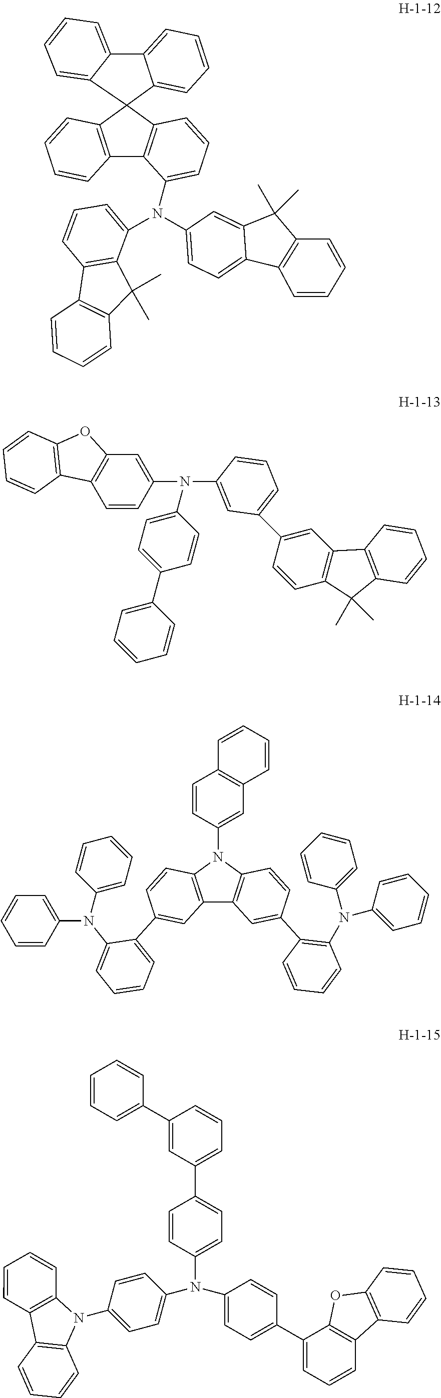 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

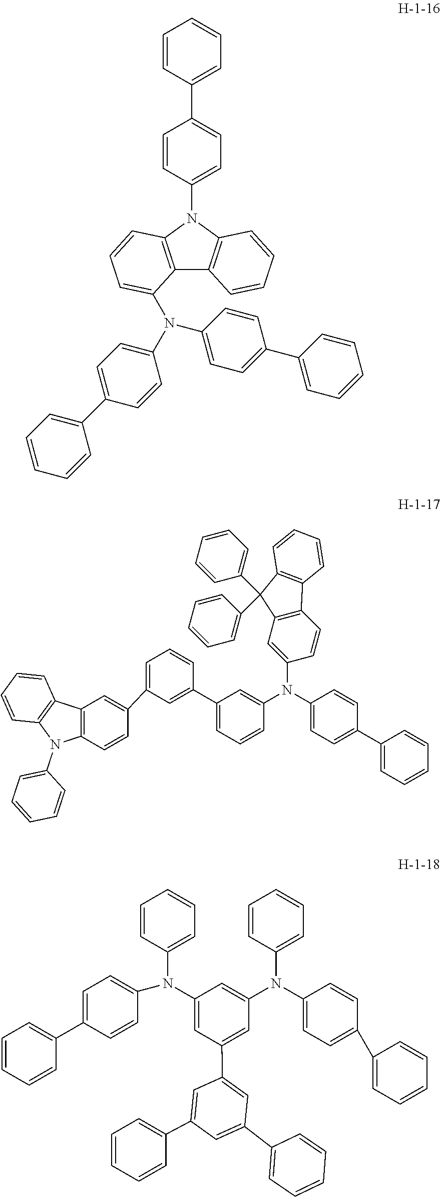 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

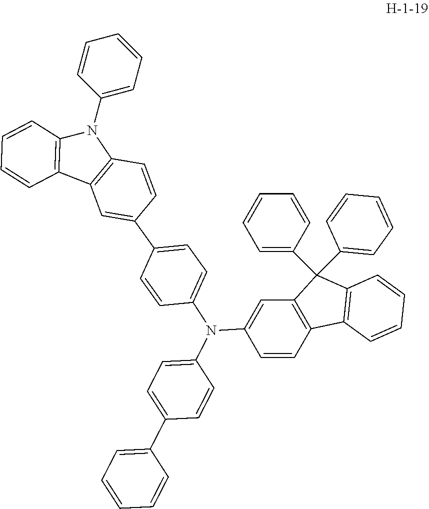 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methyl phenyl) phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h] quinoxaline-2,3,67,10,11-hexacarbonitrile (HAT-CN).

The hole transport region HTR may include carbazole derivatives such as N-phenyl carbazole and polyvinyl carbazole, fluorene-based derivatives, N,N′-bis(3-methyl phenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methyl phenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), etc.

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region HTR in at least one selected from among the hole injection layer HIL, hole transport layer HTL, and electron blocking layer EBL.

The thickness of the hole transport region HTR may be from about 100 Å to about 10,000 Å, for example, from about 100 Å to about 5,000 Å. In embodiments where the hole transport region HTR includes a hole injection layer HIL, the thickness of the hole injection layer HIL may be, for example, from about 30 Å to about 1,000 Å. In embodiments where the hole transport region HTR includes a hole transport layer HTL, the thickness of the hole transport layer HTL may be from about 30 Å to about 1,000 Å. For example, in embodiments where the hole transport region HTR includes an electron blocking layer EBL, the thickness of the electron blocking layer EBL may be from about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without a substantial increase of a driving voltage.

The hole transport region HTR may further include a charge generating material to increase conductivity (e.g., electrical conductivity) in addition to the above-described materials. The charge generating material may be dispersed uniformly or non-uniformly in the hole transport region HTR. The charge generating material may be, for example, a p-dopant. The p-dopant may include at least one selected from metal halide compounds, quinone derivatives, metal oxides, and cyano group-containing compounds, without limitation. For example, the p-dopant may include metal halide compounds such as CuI and/or RbI, quinone derivatives such as tetracyanoquinodimethane (TCNQ) and/or 2,3,5,6-tetrafluoro-7,7′,8,8′-tetracyanoquinodimethane (F4-TCNQ), metal oxides such as tungsten oxide and/or molybdenum oxide, cyano group-containing compounds such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one selected from among a buffer layer and an electron blocking layer EBL in addition to the hole injection layer HIL and the hole transport layer HTL. The buffer layer may compensate for a resonance distance according to the wavelength of light emitted from an emission layer EML and may increase emission efficiency. As materials included in the buffer layer, materials which may be included in the hole transport region HTR may be used. The electron blocking layer EBL is a layer that blocks or reduces the injection of electrons from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed using a single material, a single layer formed using a plurality of different materials, or a multilayer structure having a plurality of layers formed using a plurality of different materials.

The emission layer EML of the light emitting diode ED of an embodiment may include a polycyclic compound represented by Formula 1.

For example, the emission layer EML of the light emitting diode ED of an embodiment may include at least one selected from among a polycyclic compound represented by Formula 1 and a compound represented by Formula E-1 which will be further explained herein below. However, embodiments of the present disclosure are not limited thereto.

For example, the emission layer EML of the light emitting diode ED of an embodiment may include at least one selected from among a polycyclic compound represented by Formula 1 and a compound represented by Formula E-2b which will be further explained herein below.

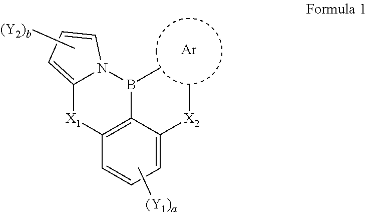

In Formula 1, Ar is a substituted or unsubstituted aromatic ring. For example, Ar may be an aromatic hydrocarbon ring, or an aromatic heterocycle.

In an embodiment, Ar may be a pentagonal ring. In some embodiments, Ar may be an aromatic pentagonal ring. For example, Ar may be a substituted or unsubstituted cyclopentadiene, a substituted or unsubstituted pyrrole, a substituted or unsubstituted furan, a substituted or unsubstituted thiophene, or a substituted or unsubstituted selenophene. However, embodiments of the present disclosure are not limited thereto. Ar is not limited to an aromatic pentagonal ring, and may be, for example, a hexagonal ring.

X₁ and X₂ are each independently CR₁R₂, NR₃, O, S, or Se. For example, X₁ and X₂ may be each independently NR₃, O, S, or Se. In an embodiment, X₁ and X₂ may be the same or different from each other.

Y₁, Y₂, and R₁ to R₃ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or may be combined with an adjacent group to form a ring.

For example, Y₁ and Y₂ may be each independently a hydrogen atom, a deuterium atom, a substituted or unsubstituted amine group, a substituted or unsubstituted alkyl group of 1 to 30 carbon atoms, a substituted or unsubstituted aryl group of 6 to 50 ring-forming carbon atoms, or a substituted or unsubstituted heteroaryl group of 2 to 50 ring-forming carbon atoms, or may be combined with an adjacent group to form a ring. In some embodiments, Y₁ and Y₂ may be each independently a hydrogen atom, a t-butyl group, a substituted or unsubstituted diphenylamine group, a substituted or unsubstituted phenyl group, a substituted or unsubstituted biphenyl group, a substituted or unsubstituted terphenyl group, or a substituted or unsubstituted carbazole group, or may be combined with an adjacent group to form a benzene ring.

For example, R₃ may be a substituted or unsubstituted aryl group of 6 to 50 ring-forming carbon atoms. However, embodiments of the present disclosure are not limited thereto.

“a” and “b” are each independently an integer of 0 to 3. For example, “a” and “b” may be each independently 0 or 1. A case where “a” is 0 may be the same as a case where “a” is 1, and Y₁ is a hydrogen atom. A case where “b” is 0 may be the same as a case where “b” is 1, and Y₂ is a hydrogen atom. Hereinafter, the same explanation may be applied for “c”, “d”, “e”, and “f”, which will be further explained herein below.

The polycyclic compound represented by Formula 1 of the present disclosure includes a structure in which pyrrole is directly connected with a boron atom, and the multiple resonance of a molecule may be improved, but the present disclosure is not limited to any particular mechanism or theory. For example, the nitrogen atom of pyrrole is directly connected with the boron atom, and due to the nitrogen atom having electron donating properties, the p orbital of the boron atom may be stabilized, and the stability of a material may be improved.

The light emitting diode ED of the present disclosure includes the polycyclic compound represented by Formula 1 in an emission layer, and the emission efficiency and light emitting diode life may increase, and color purity may be improved.

In an embodiment, the polycyclic compound represented by Formula 1 may be represented by Formula 2-1 or Formula 2-2.

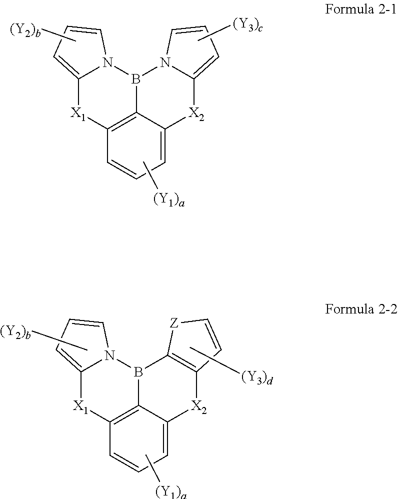

Formula 2-1 and Formula 2-2 correspond to Formula 1 where Ar is embodied.

In Formula 2-1 and Formula 2-2, Z may be CR₄R₅, NR₆, O, S, or Se. For example, Z may be NR₆, O, S, or Se.

Y₃ and R₄ to R₆ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or may be combined with an adjacent group to form a ring.

For example, Y₃ may be a hydrogen atom, a deuterium atom, a substituted or unsubstituted amine group, a substituted or unsubstituted alkyl group of 1 to 30 carbon atoms, a substituted or unsubstituted aryl group of 6 to 50 ring-forming carbon atoms, or a substituted or unsubstituted heteroaryl group of 2 to 50 ring-forming carbon atoms. In some embodiments, Y₃ may be a hydrogen atom, a t-butyl group, a substituted or unsubstituted diphenylamine group, a substituted or unsubstituted phenyl group, a substituted or unsubstituted biphenyl group, or a substituted or unsubstituted carbazole group.

“c” is an integer of 0 to 3, and, for example, “c” may be 0 or 1.

“d” may be an integer of 0 to 2, and for example, “d” may be 0.

In Formula 2-1 and Formula 2-2, X₁, X₂, Y₁, Y₂, “a”, and “b” are the same as defined with respect to Formula 1.

In an embodiment, the polycyclic compound represented by Formula 2-1 may be represented by Formula 3-1 or Formula 3-2.

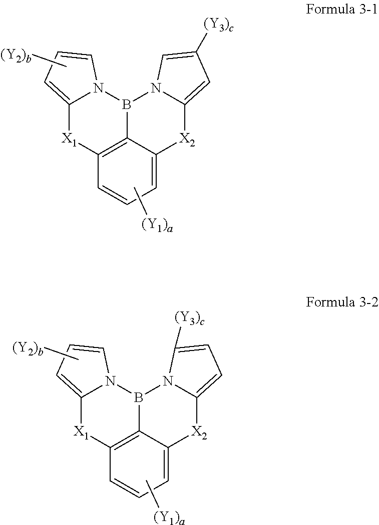

Formula 3-1 and Formula 3-2 correspond to Formula 2-1 where the position connected of Y₃ is embodied (e.g., where Y₃, if present, is connected at a particular position).

In Formula 3-1 and Formula 3-2, “e” may be 0 or 1.

X₁, X₂, Y₁ to Y₃, “a”, and “b” are the same as defined Formula 1 and Formula 2-1.

In an embodiment, the polycyclic compound represented by Formula 1 may be represented by Formula 4-1 or Formula 4-2.

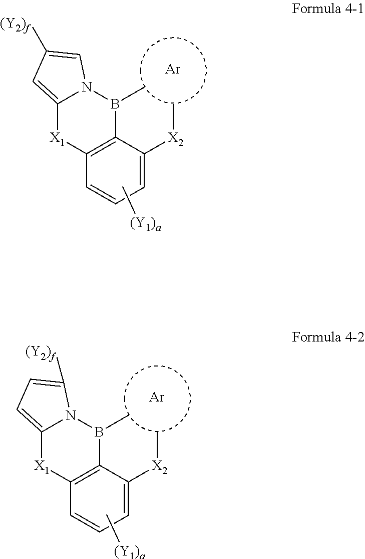

Formula 4-1 and Formula 4-2 correspond to Formula 1 where the position connected of Y₂ is embodied (e.g., where Y₂, if present, is connected at a particular position).

In Formula 4-1 and Formula 4-2, “f” may be 0 or 1.

Ar, X₁, X₂, Y₁, Y₂, and “a” are the same as defined with respect to Formula 1.

In an embodiment, the polycyclic compound represented by Formula 1 may include any one selected from among the compounds shown in Compound Group 1.

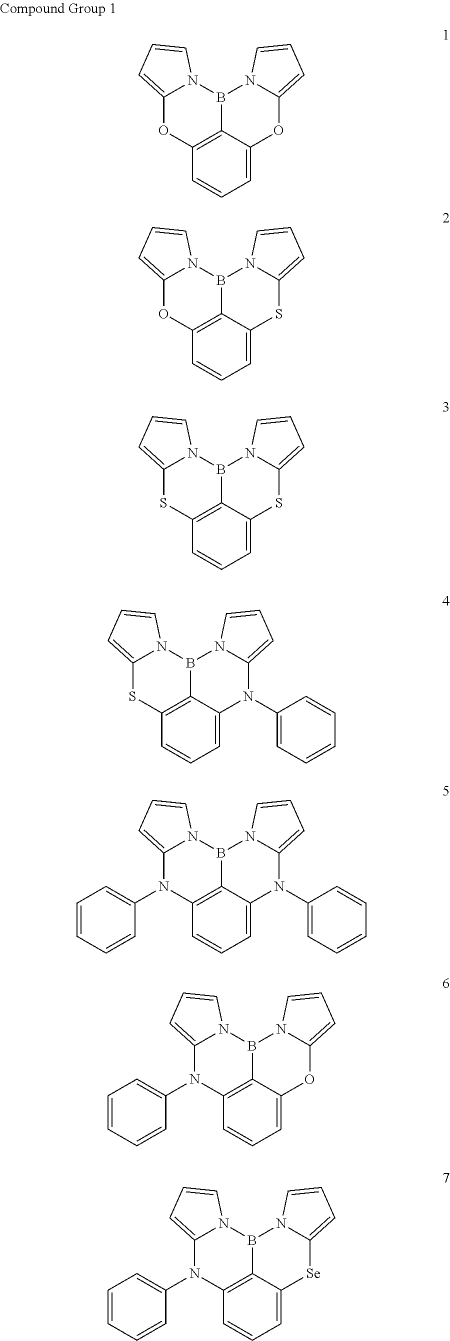

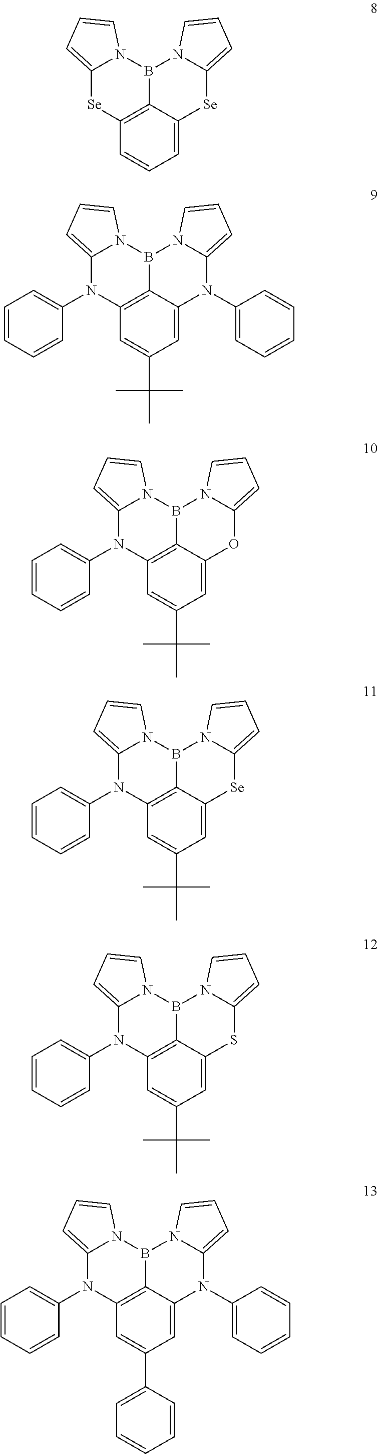

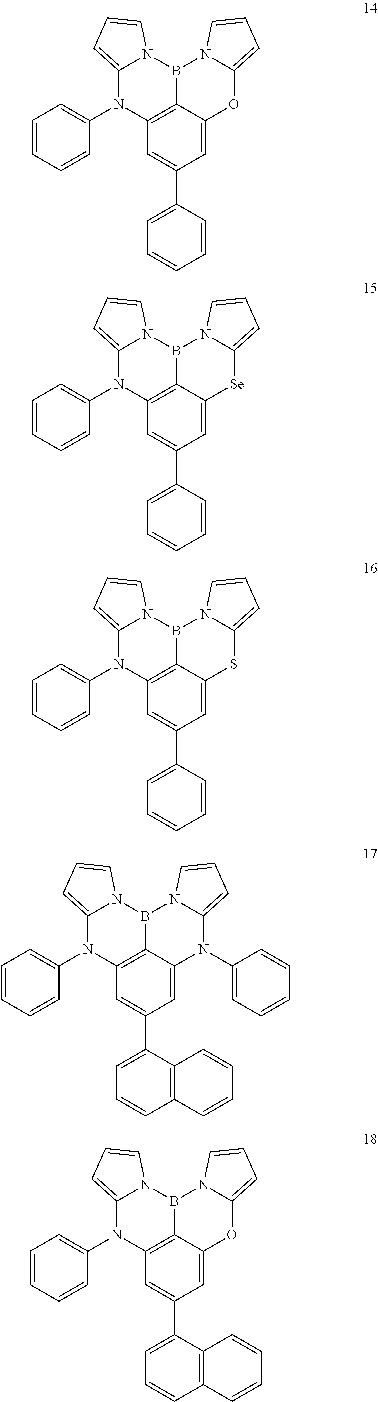

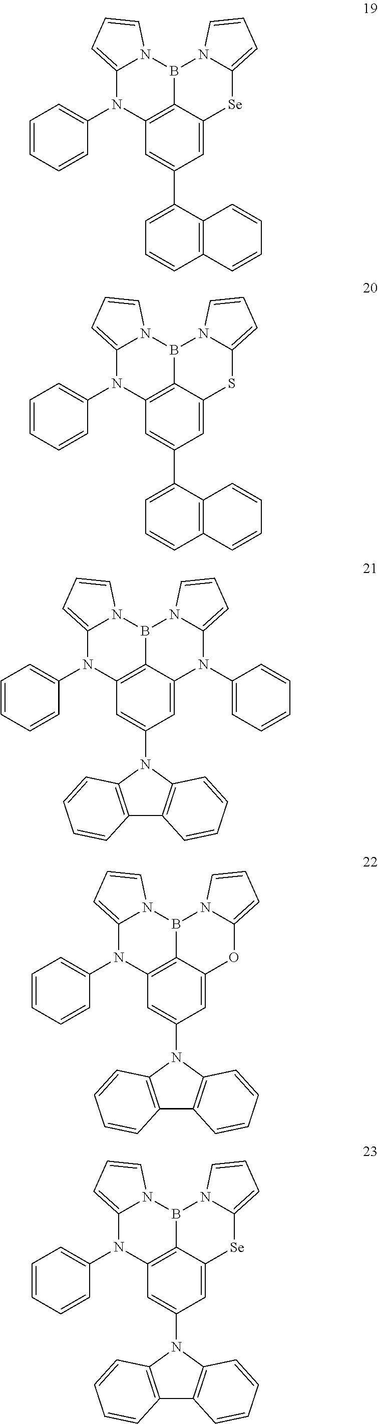

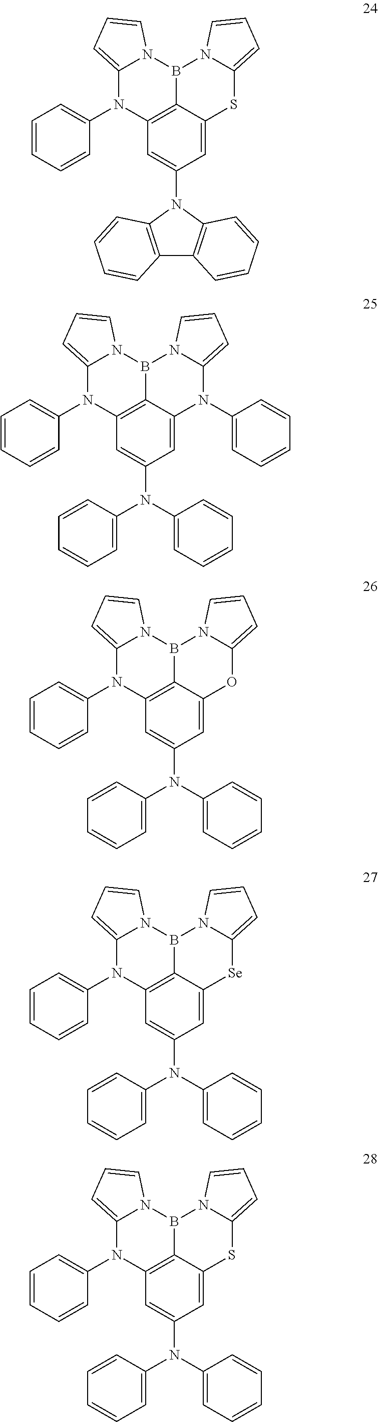

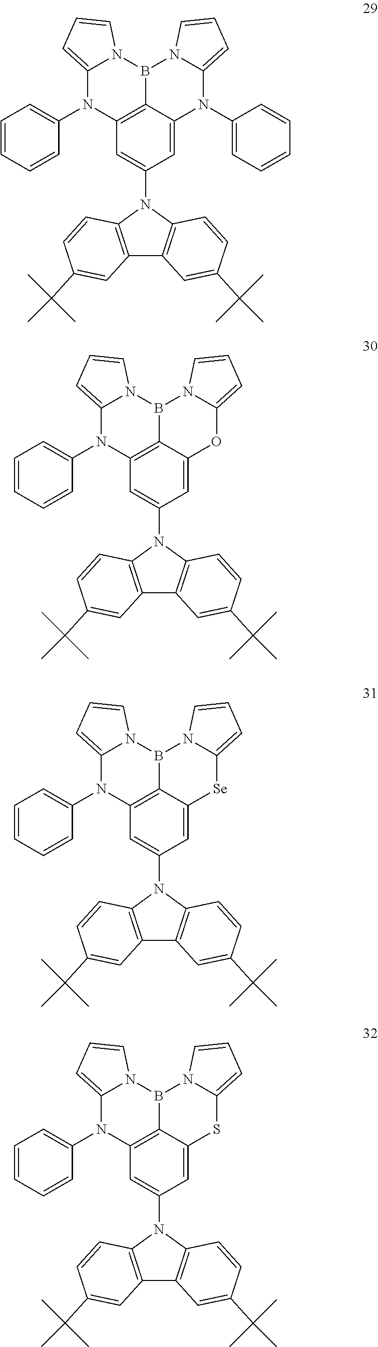

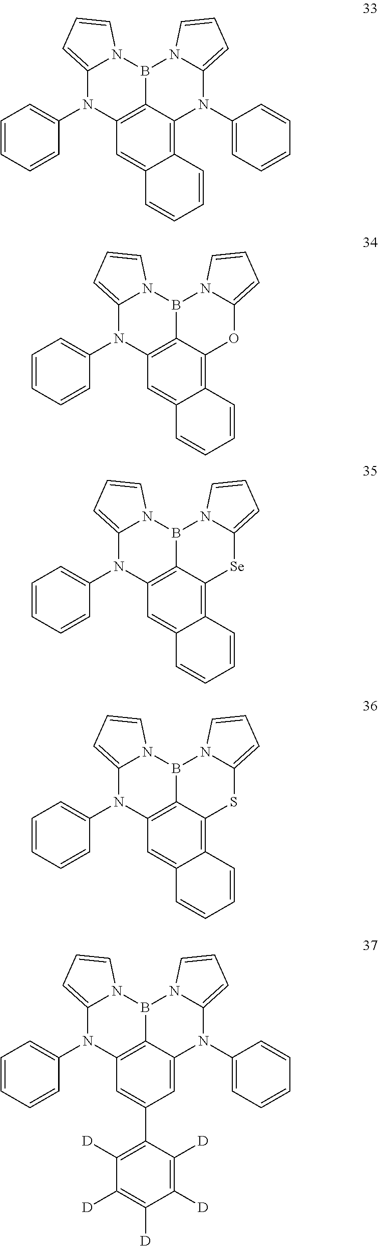

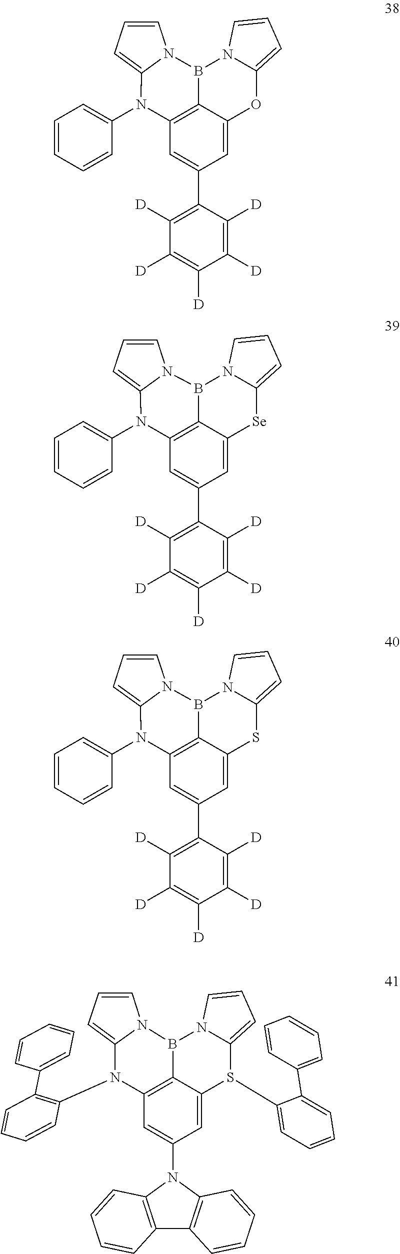

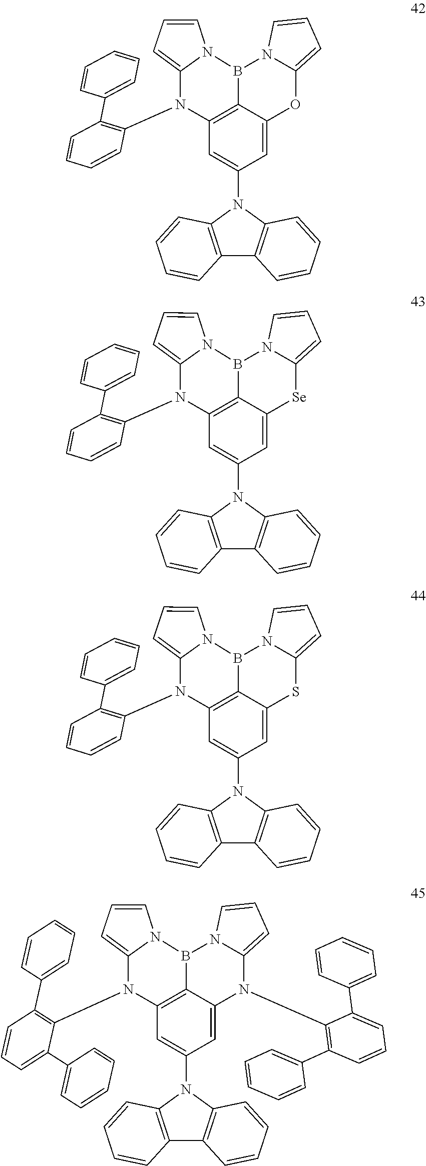

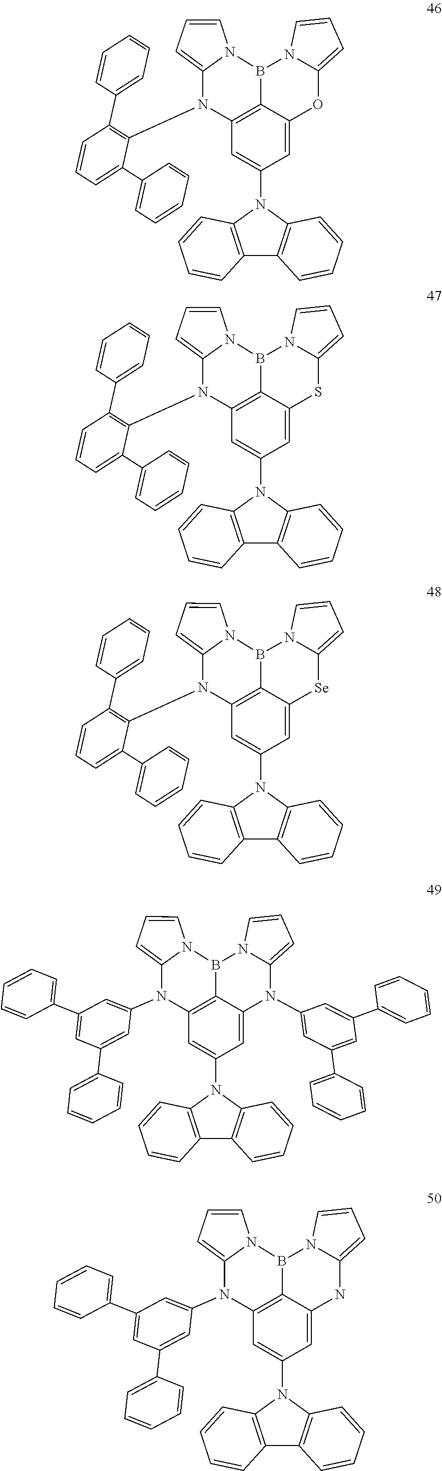

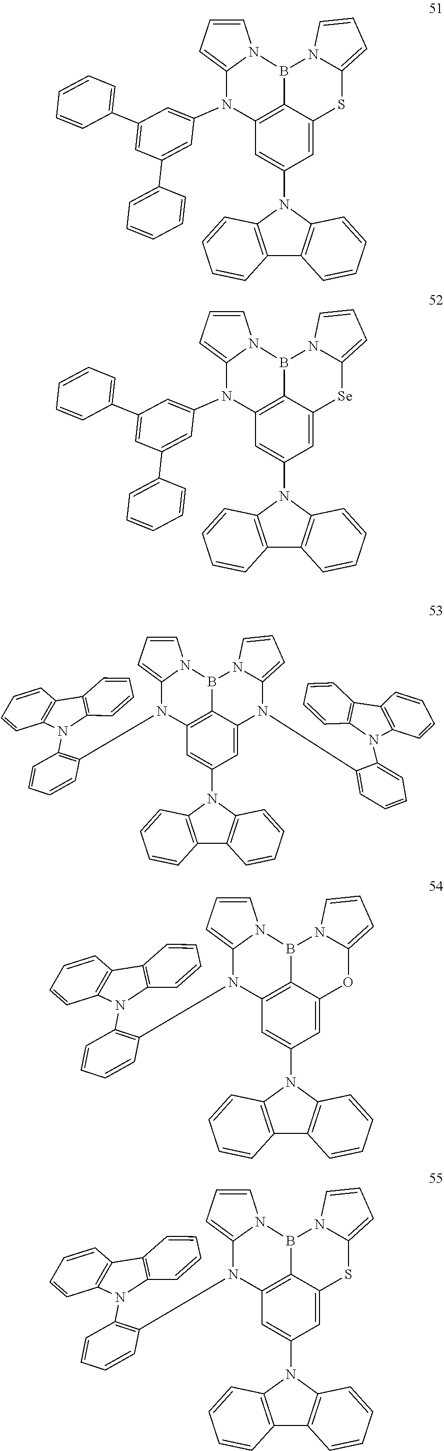

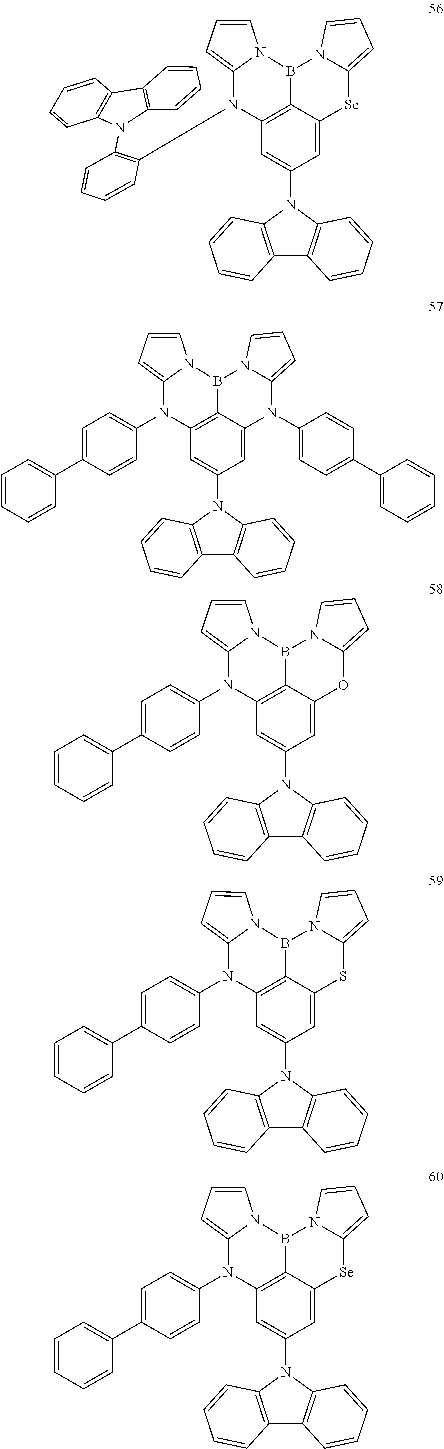

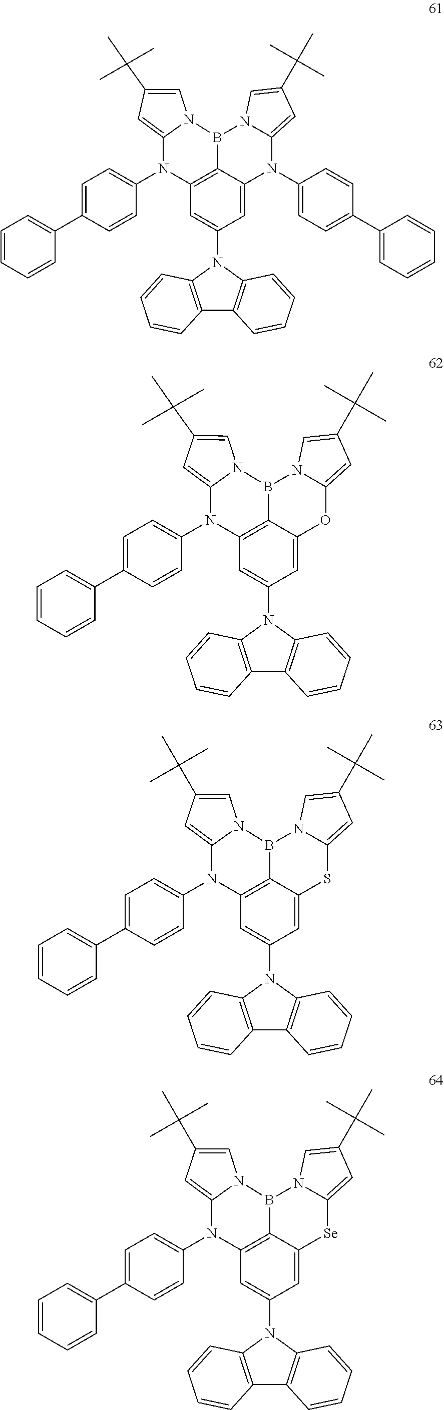 [SMILES: CC(C)(C)c1cc2n(c1)B1c3c(cc(-n4c5ccccc5c5ccccc54)cc3N(c3ccc(-c4ccccc4)cc3)c3cc(C(C)(C)C)cn31)N2c1ccc(-c2ccccc2)cc1 ; CC(C)(C)c1cc2n(c1)B1c3c(cc(-n4c5ccccc5c5ccccc54)cc3N(c3ccc(-c4ccccc4)cc3)c3cc(C(C)(C)C)cn31)O2 ; CC(C)(C)c1cc2n(c1)B1c3c(cc(-n4c5ccccc5c5ccccc54)cc3N(c3ccc(-c4ccccc4)cc3)c3cc(C(C)(C)C)cn31)S2 ; CC(C)(C)c1cc2n(c1)B1c3c(cc(-n4c5ccccc5c5ccccc54)cc3N(c3ccc(-c4ccccc4)cc3)c3cc(C(C)(C)C)cn31)[Se]2]

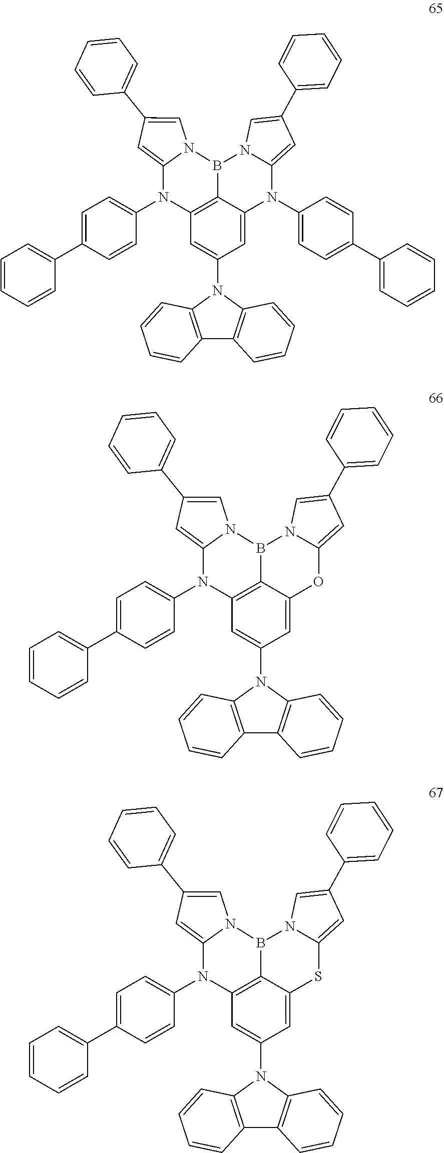 [SMILES: c1ccc(-c2ccc(N3c4cc(-n5c6ccccc6c6ccccc65)cc5c4B(n4cc(-c6ccccc6)cc43)n3cc(-c4ccccc4)cc3N5c3ccc(-c4ccccc4)cc3)cc2)cc1 ; c1ccc(-c2ccc(N3c4cc(-n5c6ccccc6c6ccccc65)cc5c4B(n4cc(-c6ccccc6)cc4O5)n4cc(-c5ccccc5)cc43)cc2)cc1 ; c1ccc(-c2ccc(N3c4cc(-n5c6ccccc6c6ccccc65)cc5c4B(n4cc(-c6ccccc6)cc4S5)n4cc(-c5ccccc5)cc43)cc2)cc1]

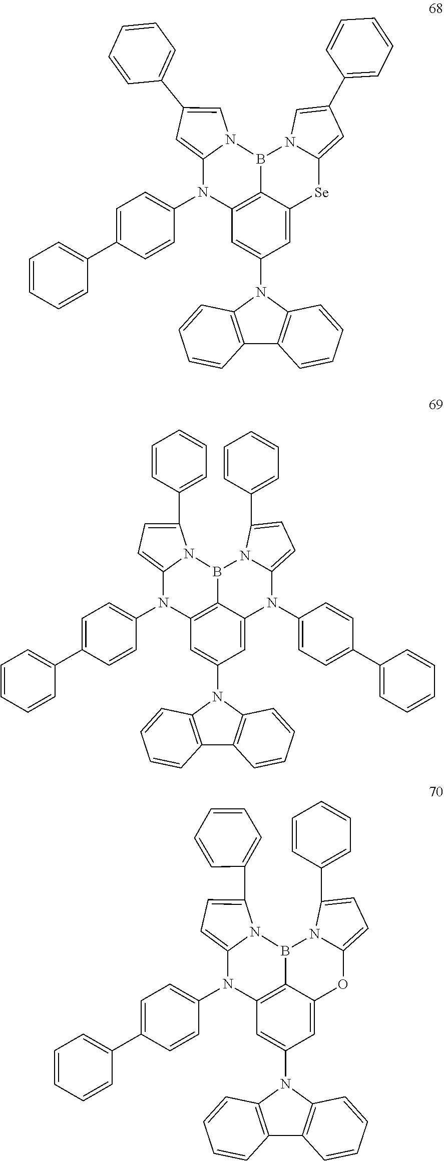

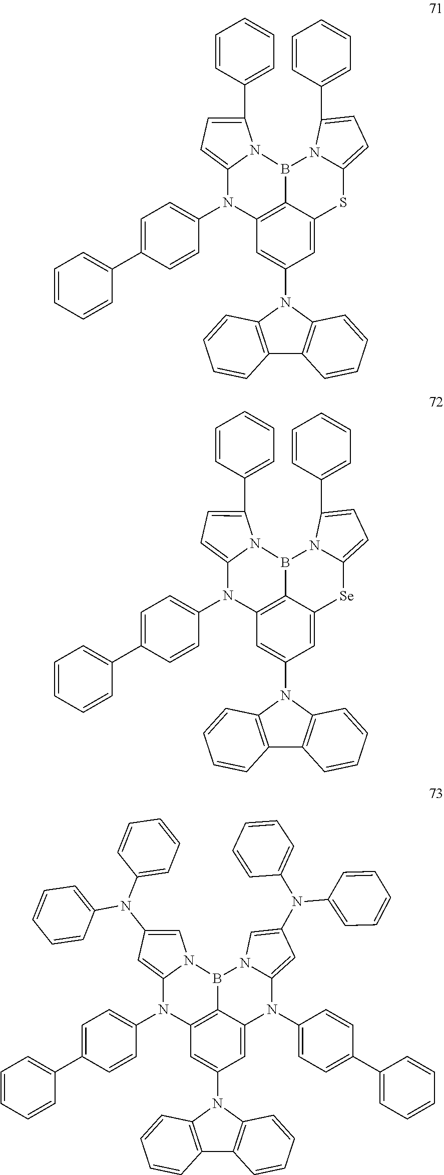

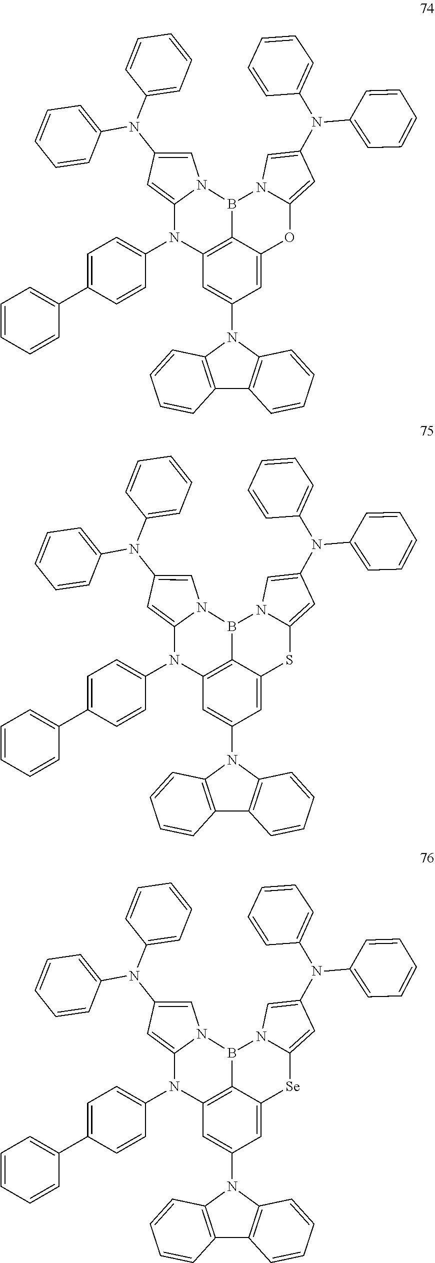 [SMILES: c1ccc(-c2ccc(N3c4cc(-n5c6ccccc6c6ccccc65)cc5c4B(n4cc(N(c6ccccc6)c6ccccc6)cc4O5)n4cc(N(c5ccccc5)c5ccccc5)cc43)cc2)cc1 ; c1ccc(-c2ccc(N3c4cc(-n5c6ccccc6c6ccccc65)cc5c4B(n4cc(N(c6ccccc6)c6ccccc6)cc4S5)n4cc(N(c5ccccc5)c5ccccc5)cc43)cc2)cc1 ; c1ccc(-c2ccc(N3c4cc(-n5c6ccccc6c6ccccc65)cc5c4B(n4cc(N(c6ccccc6)c6ccccc6)cc4[Se]5)n4cc(N(c5ccccc5)c5ccccc5)cc43)cc2)cc1]

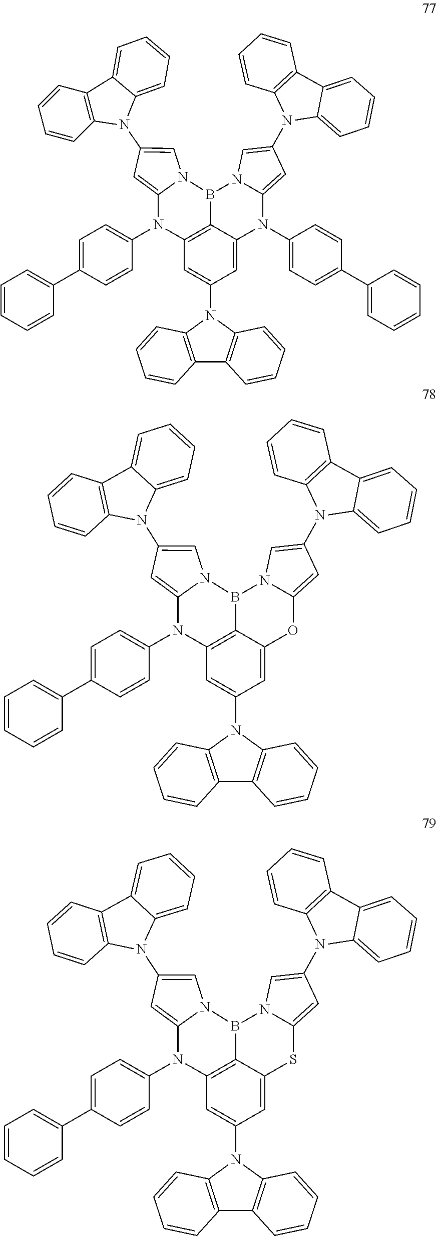

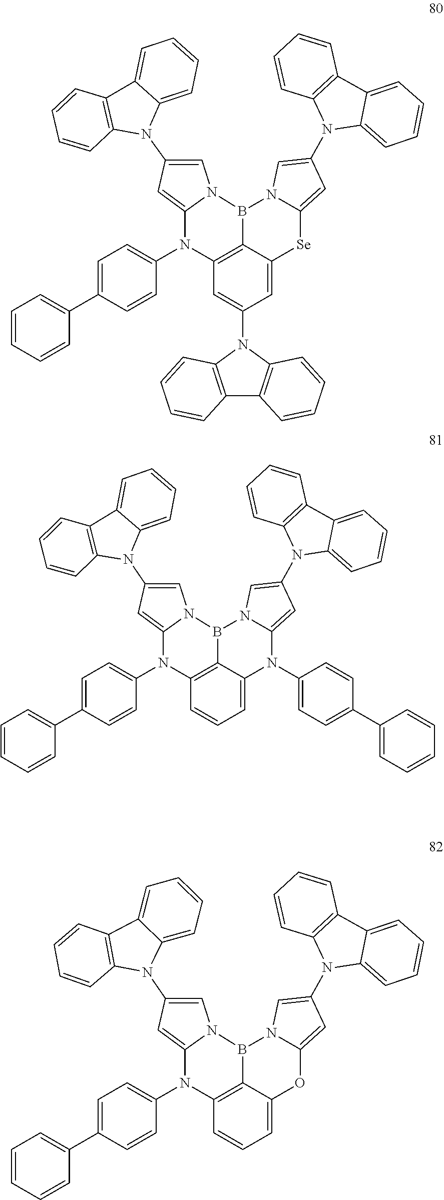

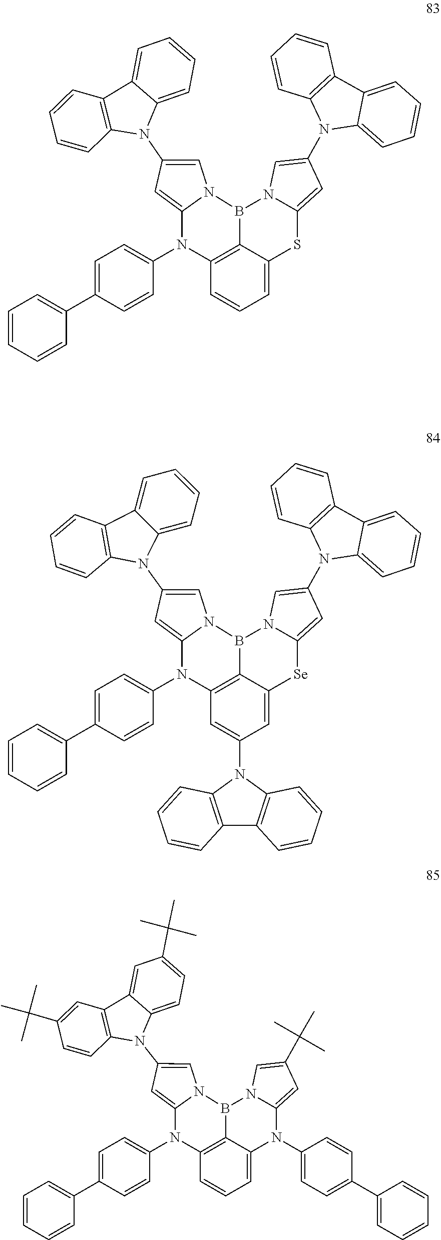 [SMILES: c1ccc(-c2ccc(N3c4cccc5c4B(n4cc(-n6c7ccccc7c7ccccc76)cc4S5)n4cc(-n5c6ccccc6c6ccccc65)cc43)cc2)cc1 ; c1ccc(-c2ccc(N3c4cc(-n5c6ccccc6c6ccccc65)cc5c4B(n4cc(-n6c7ccccc7c7ccccc76)cc4[Se]5)n4cc(-n5c6ccccc6c6ccccc65)cc43)cc2)cc1 ; CC(C)(C)c1ccc2c(c1)c1cc(C(C)(C)C)ccc1n2-c1cc2n(c1)B1c3c(cccc3N(c3ccc(-c4ccccc4)cc3)c3cc(C(C)(C)C)cn31)N2c1ccc(-c2ccccc2)cc1]

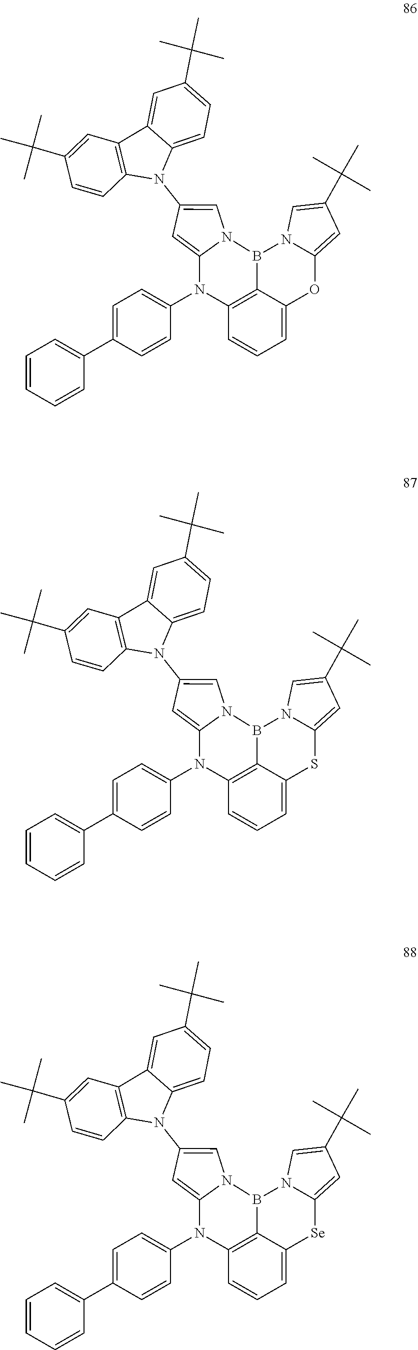

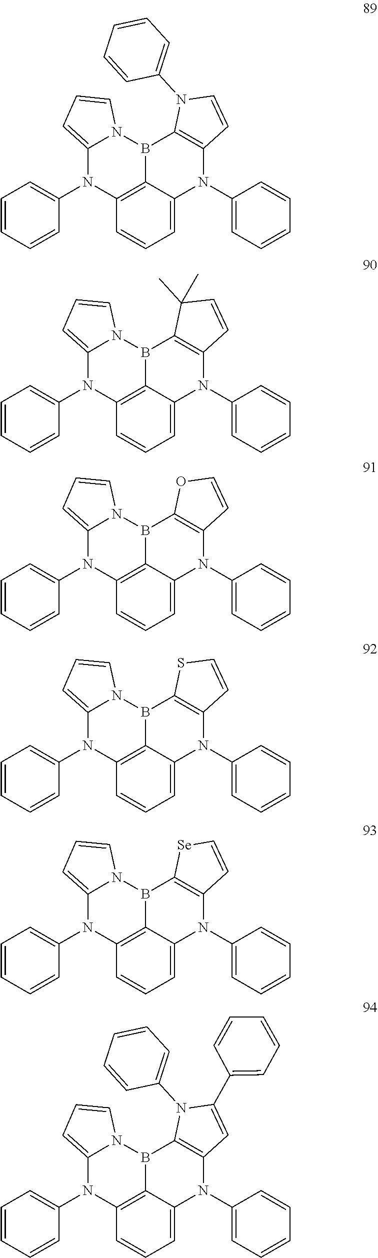

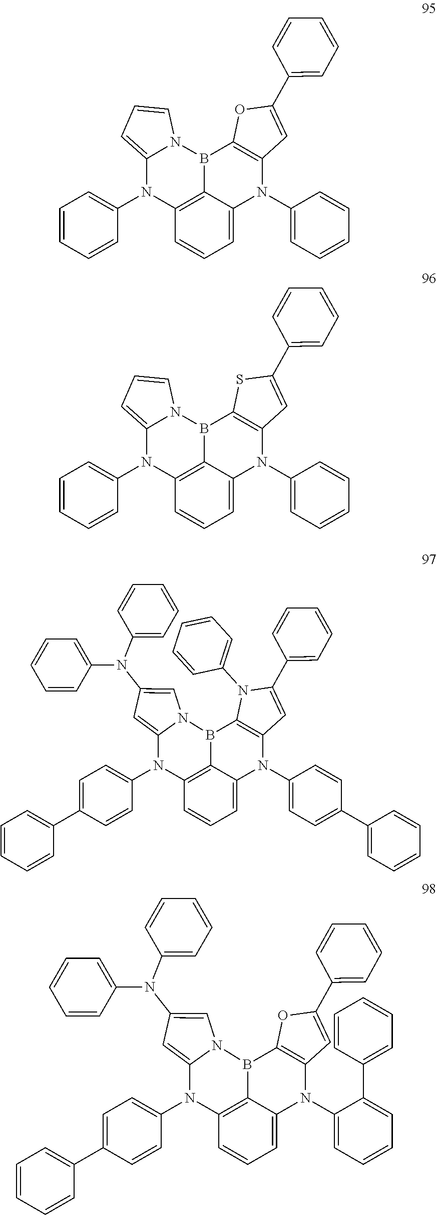

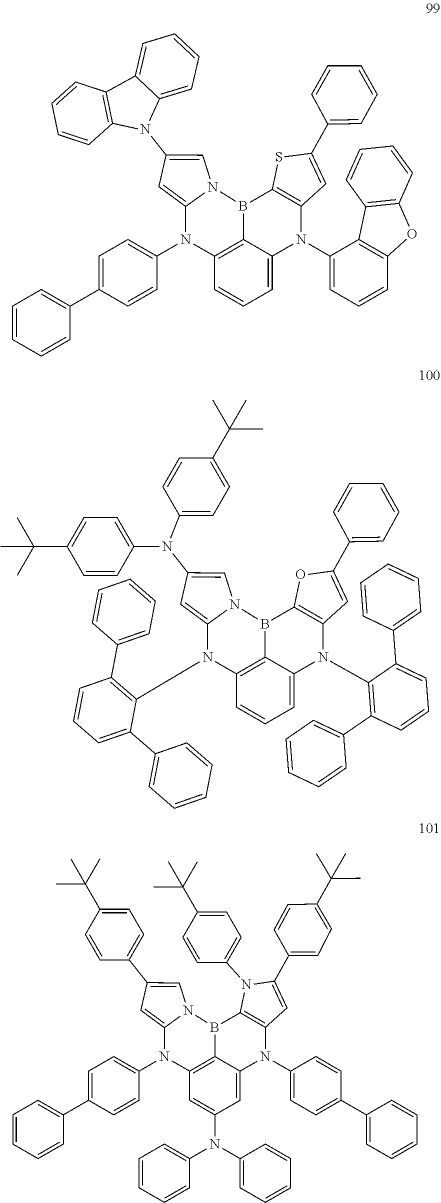 [SMILES: c1ccc(-c2ccc(N3c4cccc5c4B(c4sc(-c6ccccc6)cc4N5c4cccc5oc6ccccc6c45)n4cc(-n5c6ccccc6c6ccccc65)cc43)cc2)cc1 ; CC(C)(C)c1ccc(N(c2ccc(C(C)(C)C)cc2)c2cc3n(c2)B2c4oc(-c5ccccc5)cc4N(c4c(-c5ccccc5)cccc4-c4ccccc4)c4cccc(c42)N3c2c(-c3ccccc3)cccc2-c2ccccc2)cc1 ; CC(C)(C)c1ccc(-c2cc3n(c2)B2c4c(cc(N(c5ccccc5)c5ccccc5)cc4N3c3ccc(-c4ccccc4)cc3)N(c3ccc(-c4ccccc4)cc3)c3cc(-c4ccc(C(C)(C)C)cc4)n(-c4ccc(C(C)(C)C)cc4)c32)cc1]

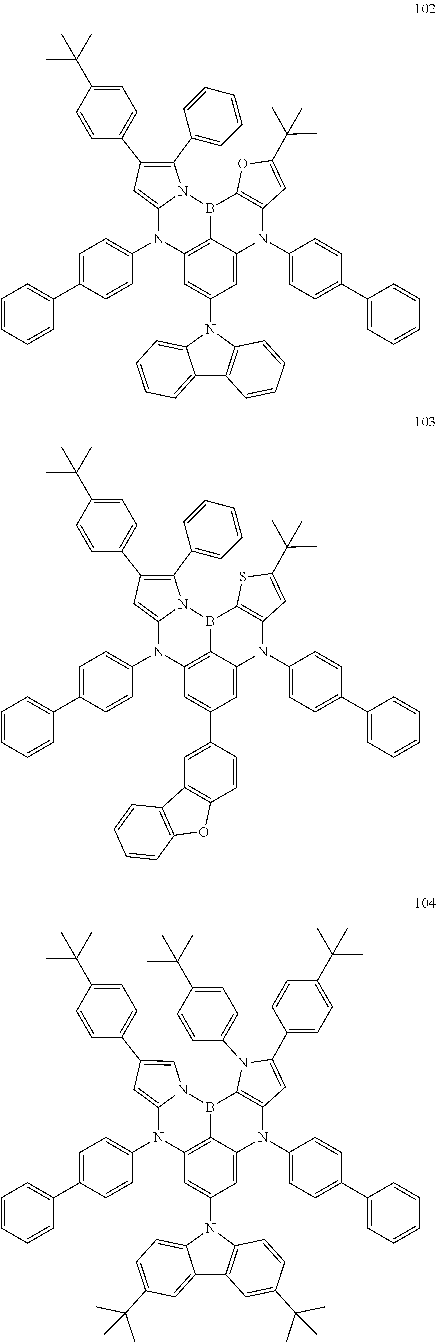 [SMILES: CC(C)(C)c1ccc(-c2cc3n(c2-c2ccccc2)B2c4oc(C(C)(C)C)cc4N(c4ccc(-c5ccccc5)cc4)c4cc(-n5c6ccccc6c6ccccc65)cc(c42)N3c2ccc(-c3ccccc3)cc2)cc1 ; CC(C)(C)c1ccc(-c2cc3n(c2-c2ccccc2)B2c4sc(C(C)(C)C)cc4N(c4ccc(-c5ccccc5)cc4)c4cc(-c5ccc6oc7ccccc7c6c5)cc(c42)N3c2ccc(-c3ccccc3)cc2)cc1 ; CC(C)(C)c1ccc(-c2cc3n(c2)B2c4c(cc(-n5c6ccc(C(C)(C)C)cc6c6cc(C(C)(C)C)ccc65)cc4N3c3ccc(-c4ccccc4)cc3)N(c3ccc(-c4ccccc4)cc3)c3cc(-c4ccc(C(C)(C)C)cc4)n(-c4ccc(C(C)(C)C)cc4)c32)cc1]

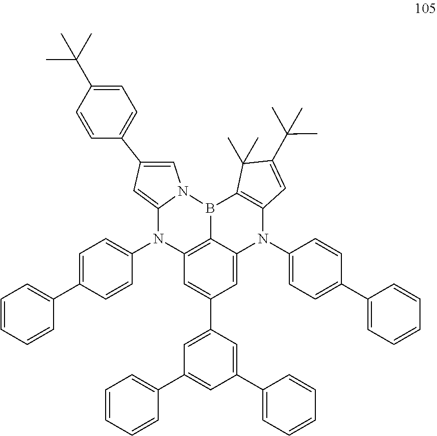 [SMILES: CC(C)(C)C1=CC2=C(B3c4c(cc(-c5cc(-c6ccccc6)cc(-c6ccccc6)c5)cc4N(c4ccc(-c5ccccc5)cc4)c4cc(-c5ccc(C(C)(C)C)cc5)cn43)N2c2ccc(-c3ccccc3)cc2)C1(C)C]

In the light emitting diode ED of an embodiment, the emission layer EML may include any suitable host material generally available in the art. For example, the emission layer EML may include anthracene derivatives, pyrene derivatives, fluoranthene derivatives, chrysene derivatives, dihydrobenzanthracene derivatives, and/or triphenylene derivatives. In some embodiments, the emission layer EML may include anthracene derivatives and/or pyrene derivatives.

In the light emitting diodes ED of embodiments, shown in FIG. 3 to FIG. 6, the emission layer EML may include a host and a dopant, and the emission layer EML may include a compound represented by Formula E-1 below. The compound represented by Formula E-1 below may be used as a fluorescence host material.

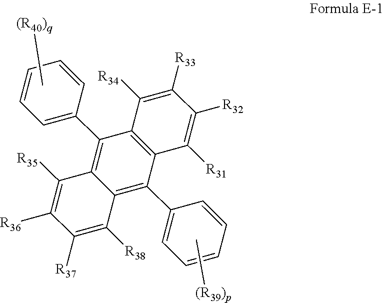

In Formula E-1, R₃₁ to R₄₀ may be each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or may be combined with an adjacent group to form a ring.

R₃₁ to R₄₀ may be combined with an adjacent group to form a saturated hydrocarbon ring, an unsaturated hydrocarbon ring, a saturated heterocycle, or an unsaturated heterocycle.

In Formula E-1, “p” and “q” may be each independently an integer of 0 to 5.

Formula E-1 may be represented by any one selected from among Compound E1 to Compound E19 below.

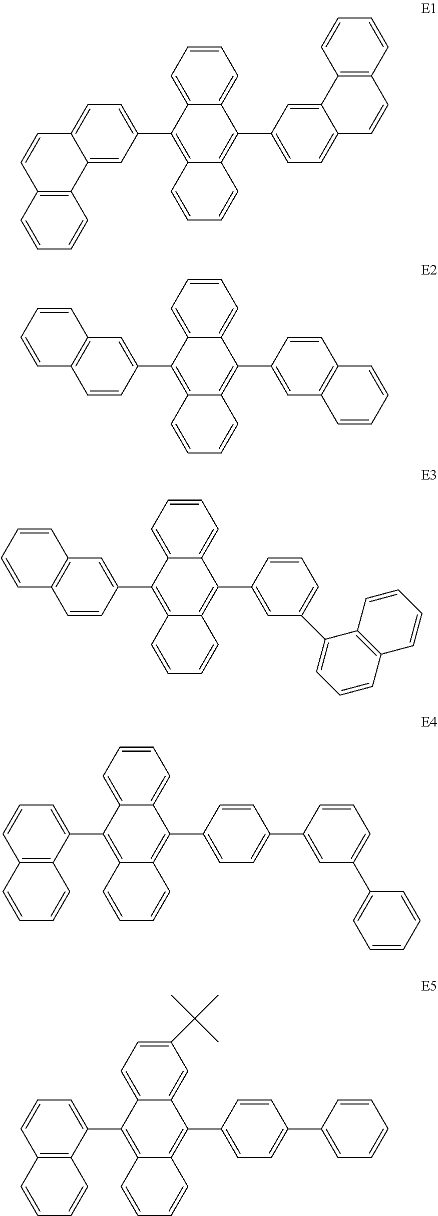

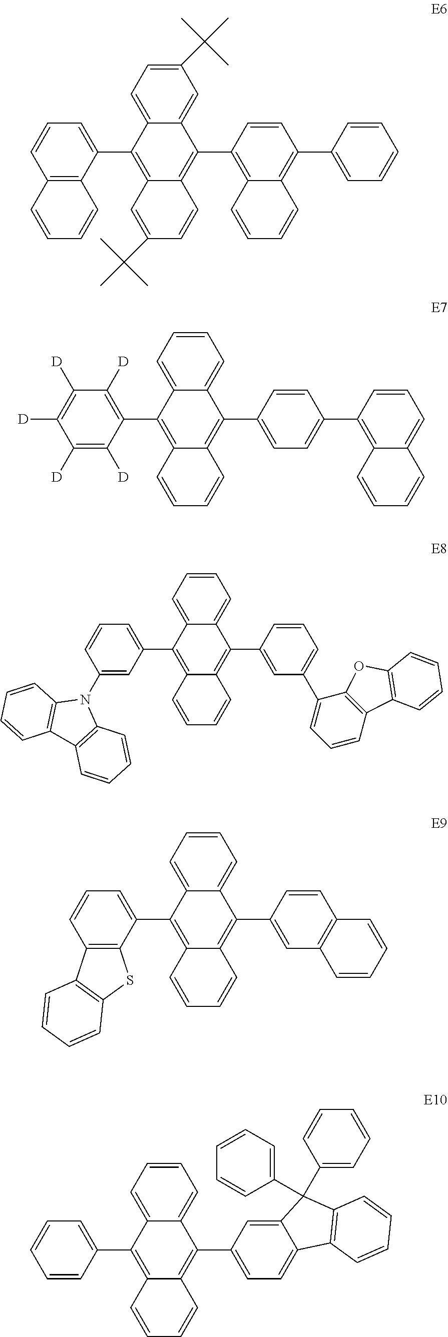

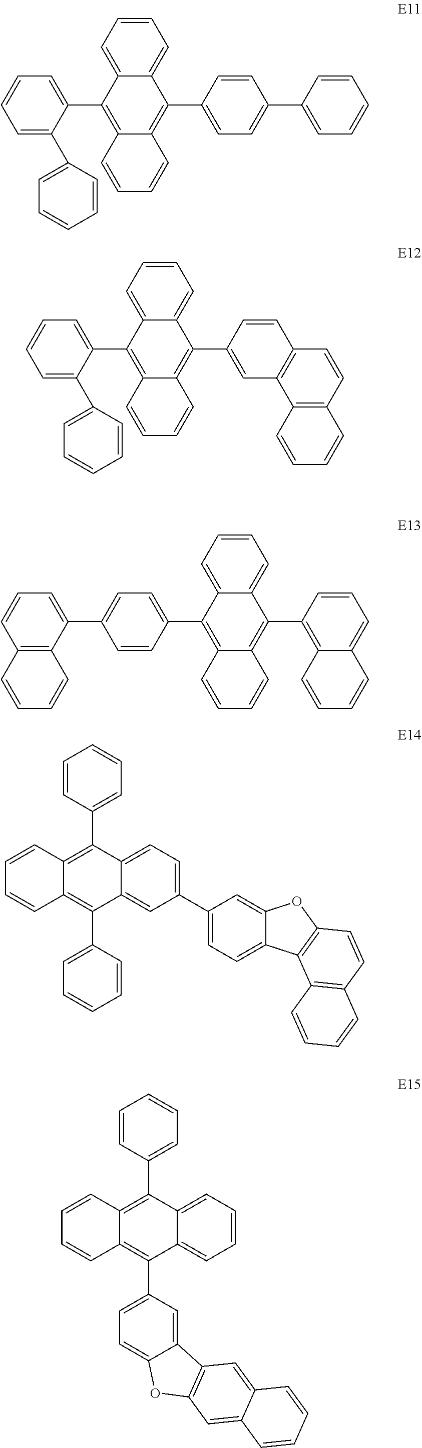

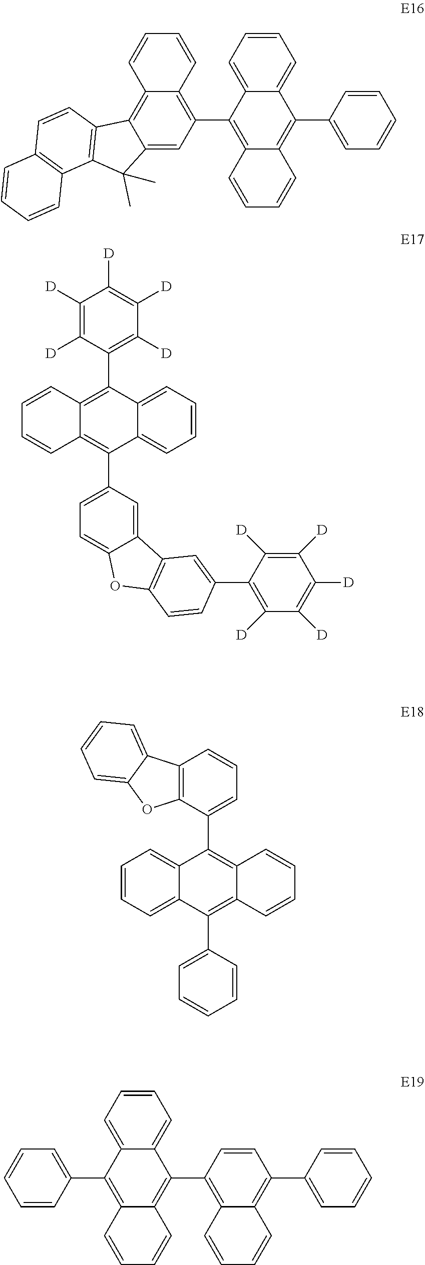

In an embodiment, the emission layer EML may include a compound represented by Formula E-2a or Formula E-2b below. The compound represented by Formula E-2a or Formula E-2b below may be used as a phosphorescence host material.

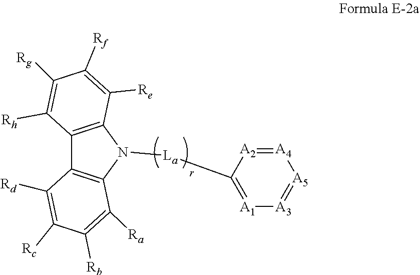

In Formula E-2a, “r” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. If “r” is an integer of 2 or more, a plurality of La may be each independently a substituted or unsubstituted arylene group of 6 to 30 ring-forming carbon atoms, or a substituted or unsubstituted heteroarylene group of 2 to 30 ring-forming carbon atoms.

In addition, in Formula E-2a, A₁ to A₅ may be each independently N or CRi. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, etc. as a ring-forming atom.

In Formula E-2a, two or three selected from A₁ to A₅ may be N, and the remainder may be CRᵢ.

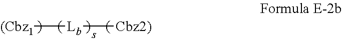

In Formula E-2b, Cbz1 and Cbz2 may be each independently a substituted or unsubstituted carbazole group. For example, Cbz1 and Cbz2 may be each independently a carbazole group substituted with an aryl group of 6 to 30 ring-forming carbon atoms, or an unsubstituted carbazole group.

L_{b} may be a direct linkage, a substituted or unsubstituted arylene group of 6 to 30 ring-forming carbon atoms, or a substituted or unsubstituted heteroarylene group of 2 to 30 ring-forming carbon atoms. “s” is an integer of 0 to 10, and if “s” is an integer of 2 or more, a plurality of L_{b} may be each independently a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2 below. However, the compounds shown in Compound Group E-2 below are only examples, and the compound represented by Formula E-2a or Formula E-2b is not limited to the compounds represented in Compound Group E-2 below.

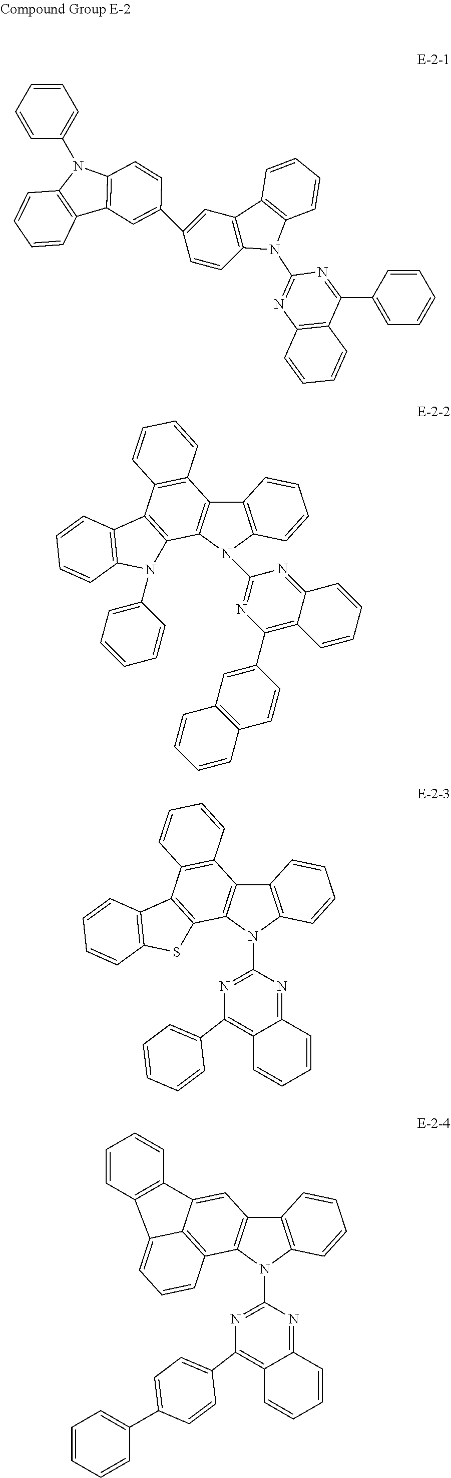

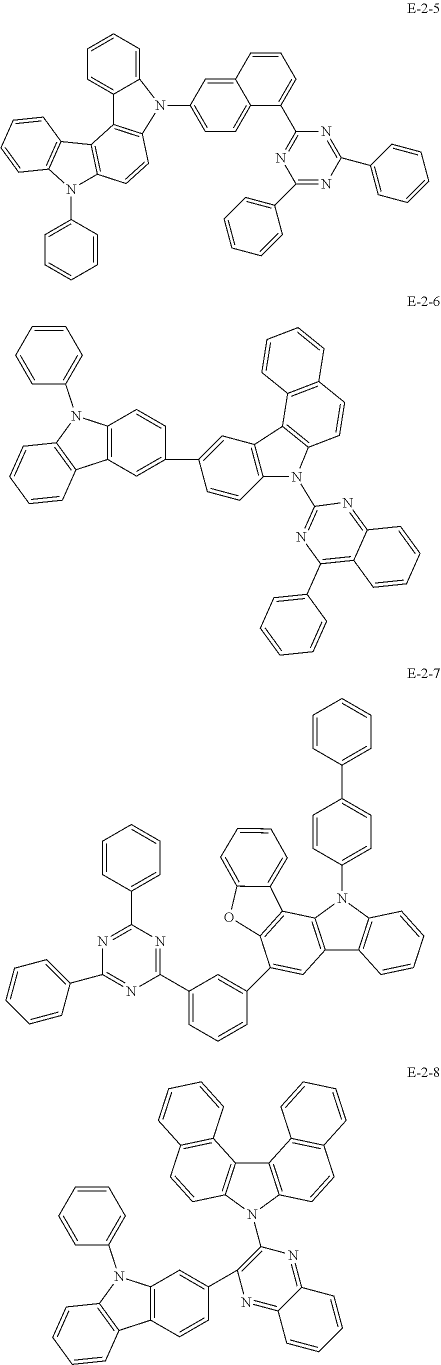

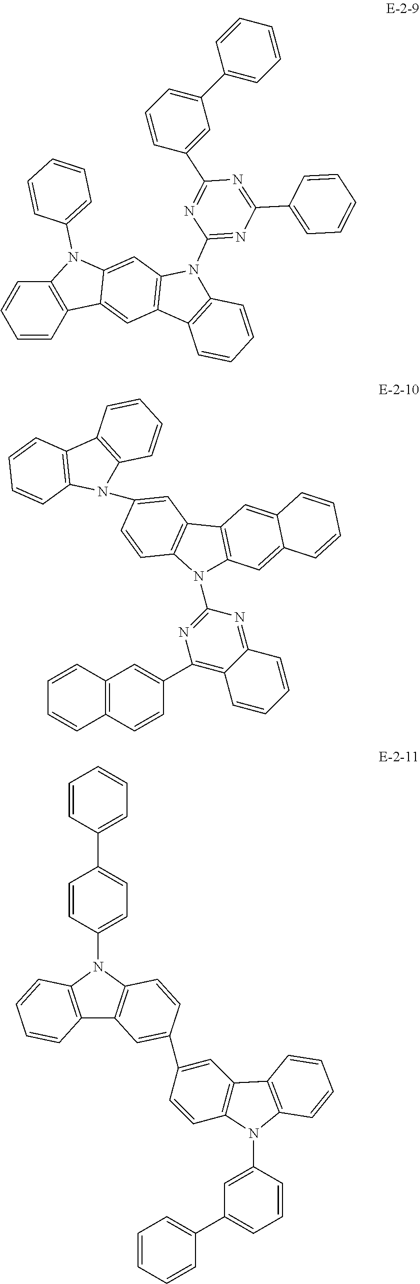

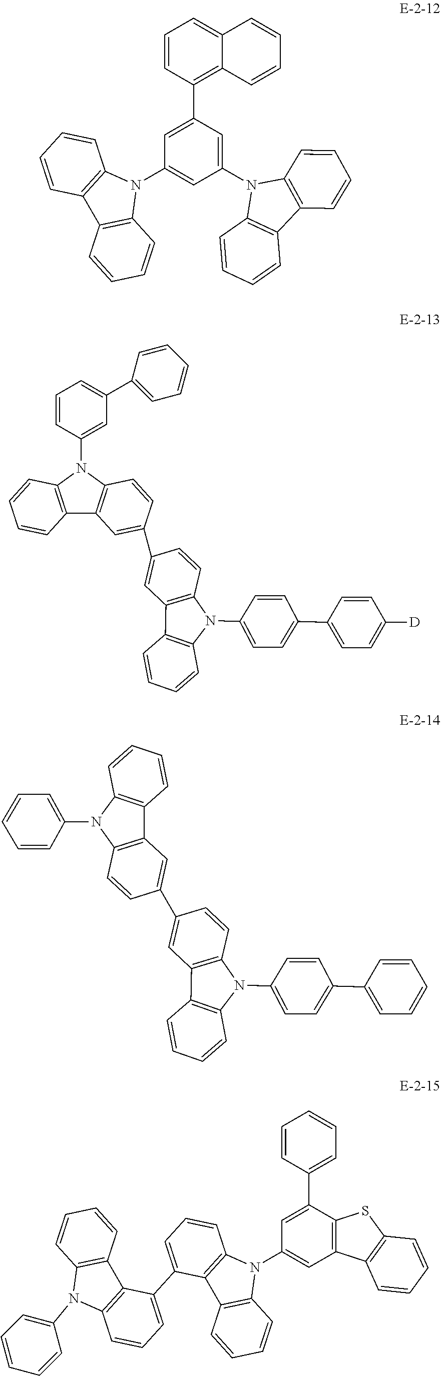 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

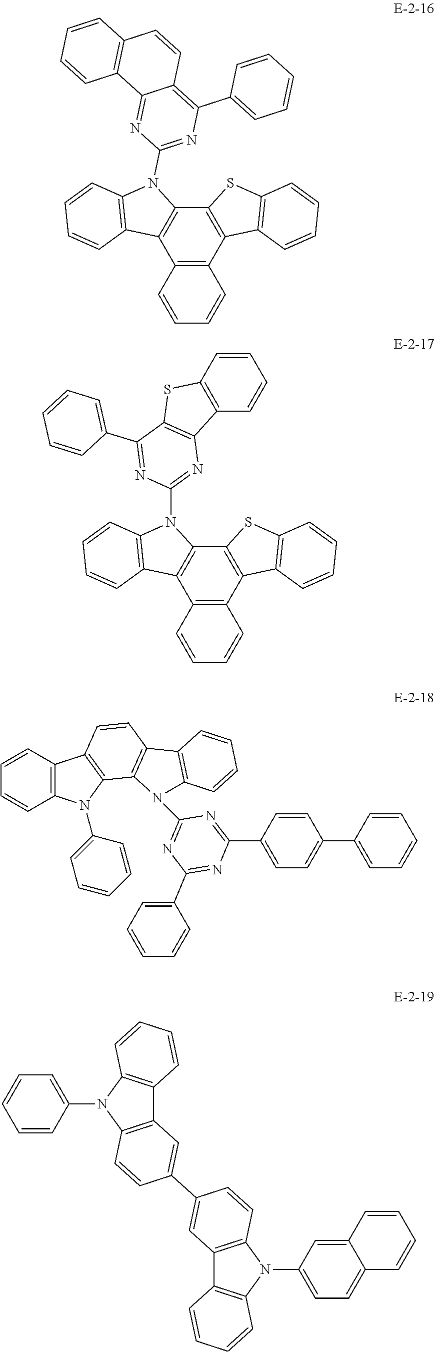

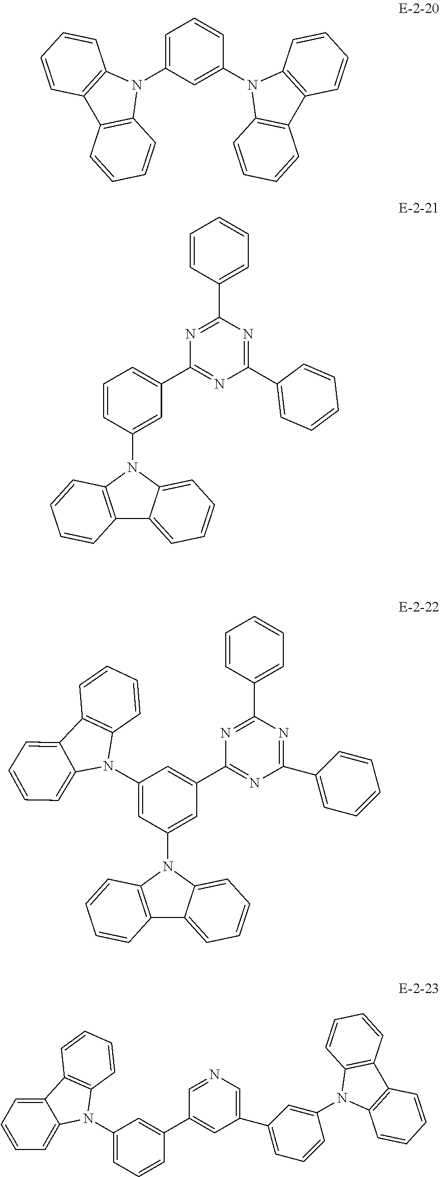 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

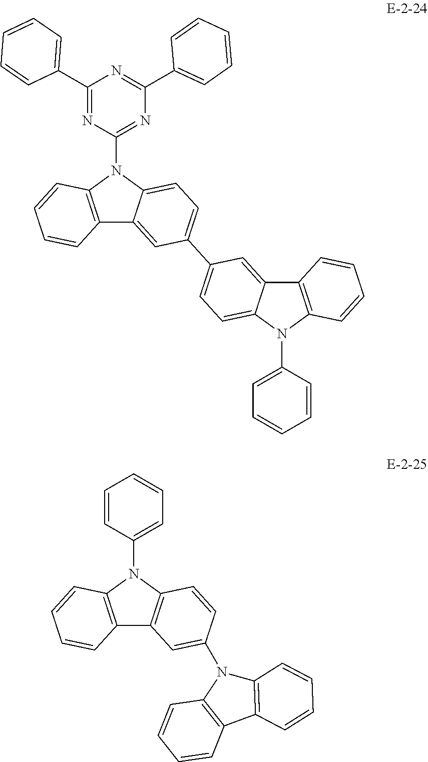 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-n2c3ccccc3c3cc(-n4c5ccccc5c5ccccc54)ccc32)cc1]

The emission layer EML may further include any suitable material generally available in the art as a host material. In some embodiments, the emission layer EML may include as a host material, at least one selected from bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments of the present disclosure are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH₂), hexaphenylcyclotrisiloxane (DPSiO₃), octaphenylcyclotetra siloxane (DPSiO₄), etc. may be used as the host material.

The emission layer EML may include a compound represented by Formula M-a and/or Formula M-b below. The compound represented by Formula M-a or Formula M-b may be used as a phosphorescence dopant material.

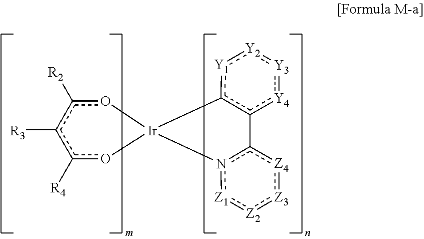

In Formula M-a, Y₁ to Y₄, and Z₁ to Z₄ may be each independently CR₁ or N, and R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, “m” is 0 or 1, and “n” is 2 or 3. In Formula M-a, if “m” is 0, “n” is 3, and if “m” is 1, “n” is 2.

The compound represented by Formula M-a may be used as a phosphorescence dopant.

The compound represented by Formula M-a may be represented by any one selected from among Compounds M-a1 to M-a25 below. However, Compounds M-a1 to M-a25 below are examples, and the compound represented by Formula M-a is not limited to the compounds represented by Compounds M-a1 to M-a25 below.

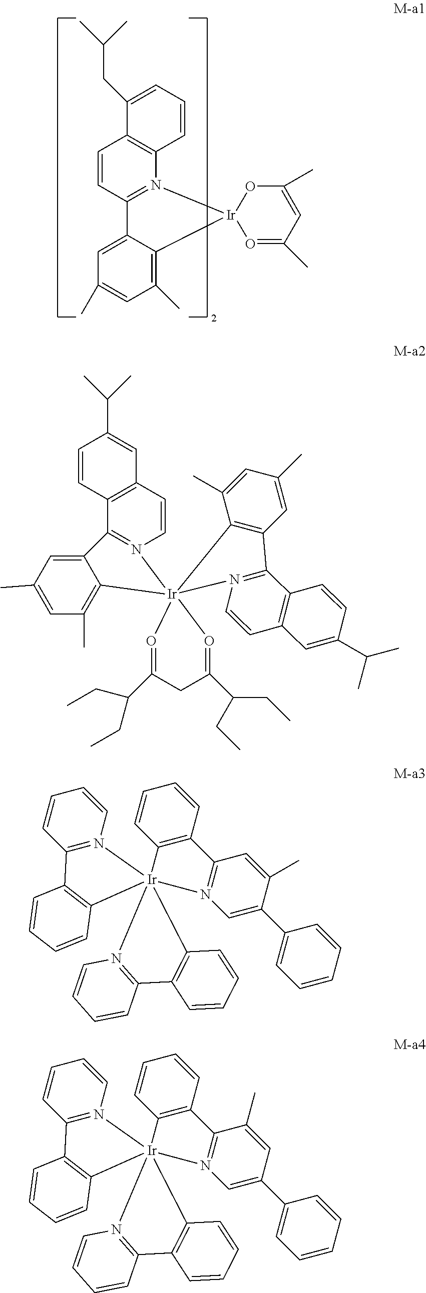

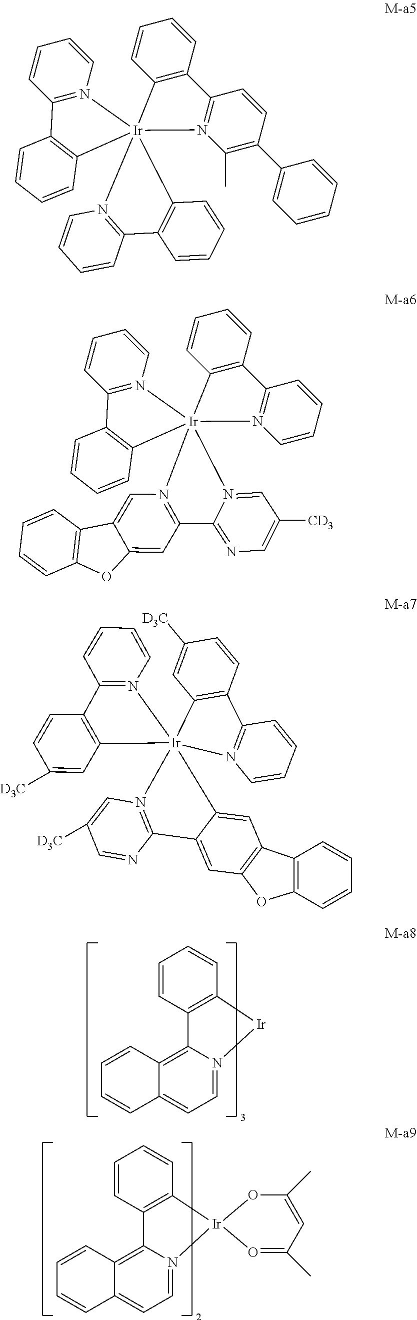

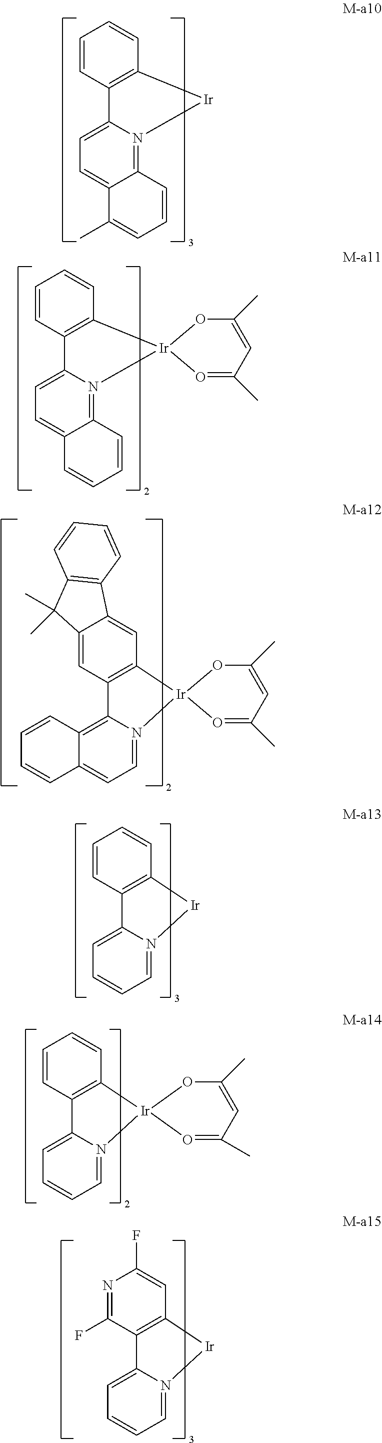

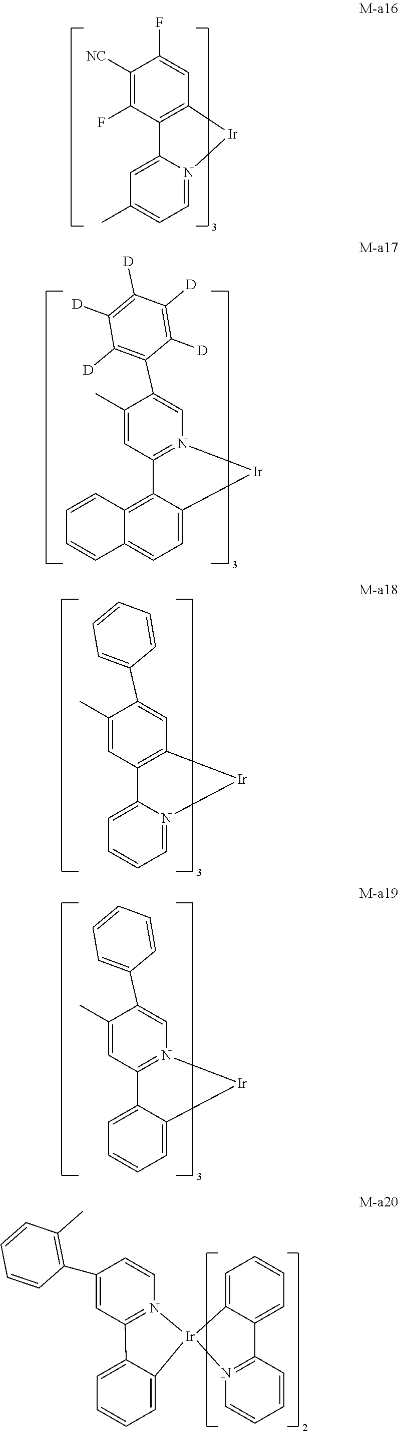

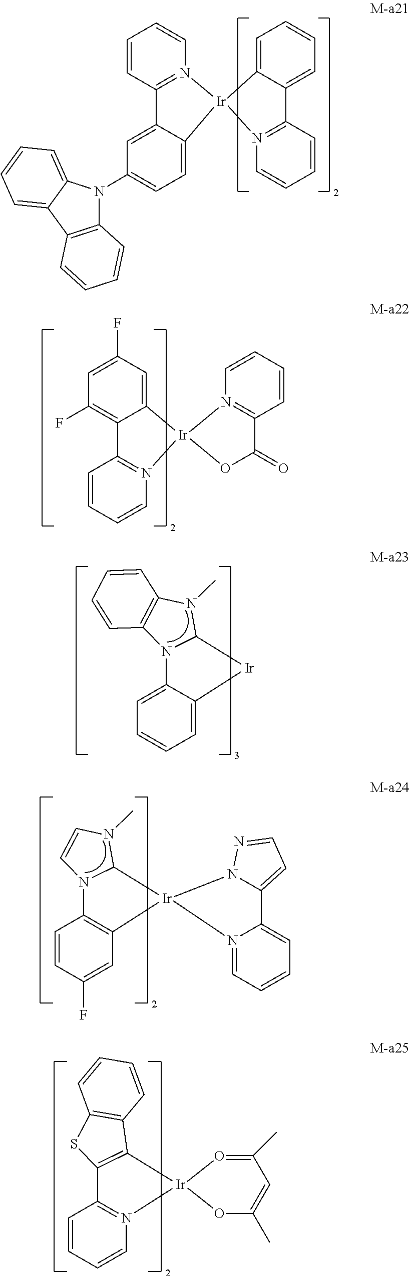

Compound M-a1 and Compound M-a2 may be used as red dopant materials, and Compound M-a3 to Compound M-a7 may be used as green dopant materials.

In an embodiment, the emission layer EML of the light emitting diode ED may include at least one selected from the compound represented by Formula 1, the compound represented by Formula E-2b, or a compound represented by Formula M-b.

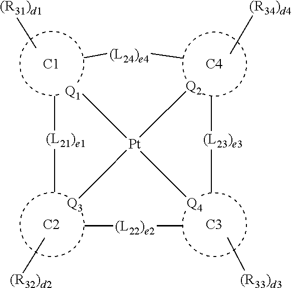

In Formula M-b, Q₁ to Q₄ are each independently C or N, C1 to C4 are each independently a substituted or unsubstituted hydrocarbon ring of 5 to 30 ring-forming carbon atoms, or a substituted or unsubstituted heterocycle of 2 to 30 ring-forming carbon atoms. L₂₁ to L₂₄ are each independently a direct linkage,

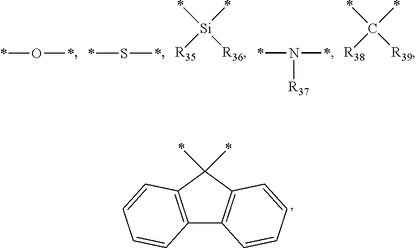

a substituted or unsubstituted divalent alkyl group of 1 to 30 carbon atoms, a substituted or unsubstituted arylene group of 6 to 50 ring-forming carbon atoms, or a substituted or unsubstituted heteroarylene group of 2 to 50 ring-forming carbon atoms, and e1 to e4 are each independently 0 or 1. R₃₁ to R₃₉ are each independently a hydrogen atom, a deuterium atom, a halogen atom, a cyano group, a substituted or unsubstituted amine group, a substituted or unsubstituted alkyl group of 1 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring, and d1 to d4 are each independently an integer of 0 to 4.

The compound represented by Formula M-b may be used as a blue phosphorescence dopant and/or a green phosphorescence dopant.

The compound represented by Formula M-b may be represented by any one selected from among the compounds below. For example, the compound represented by Formula M-b may be represented by Compound M-b-10. However, the compounds below are examples, and the compound represented by Formula M-b is not limited to the compounds represented below.

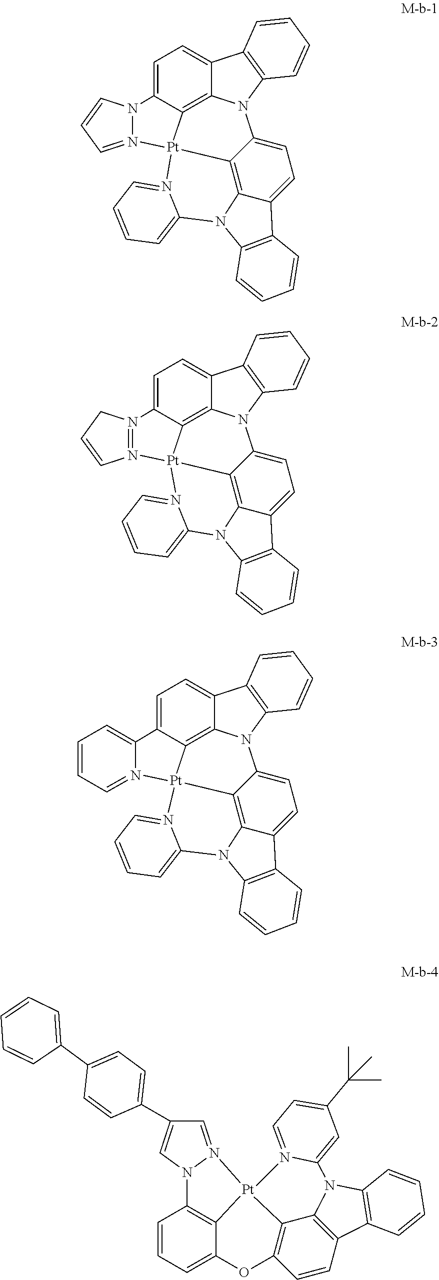

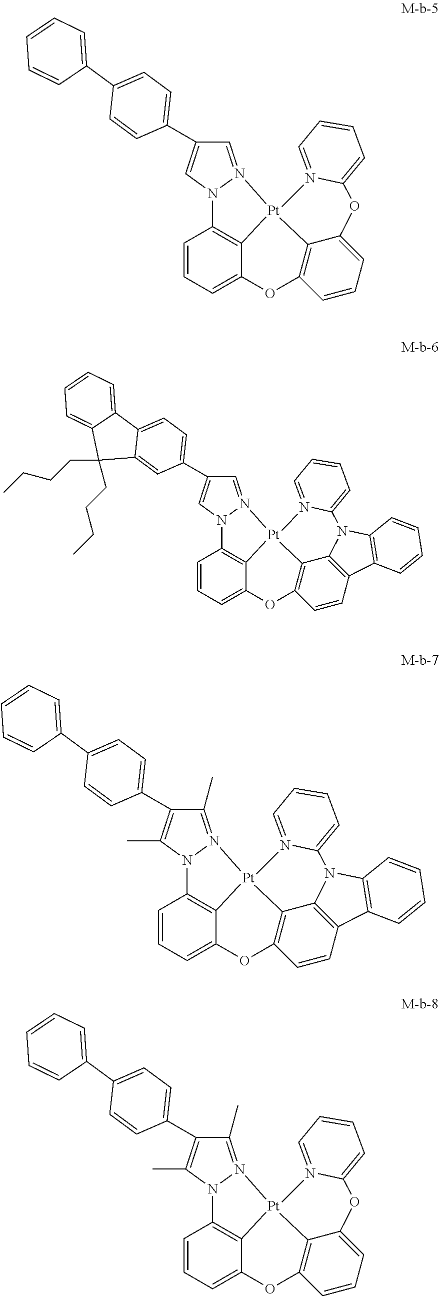

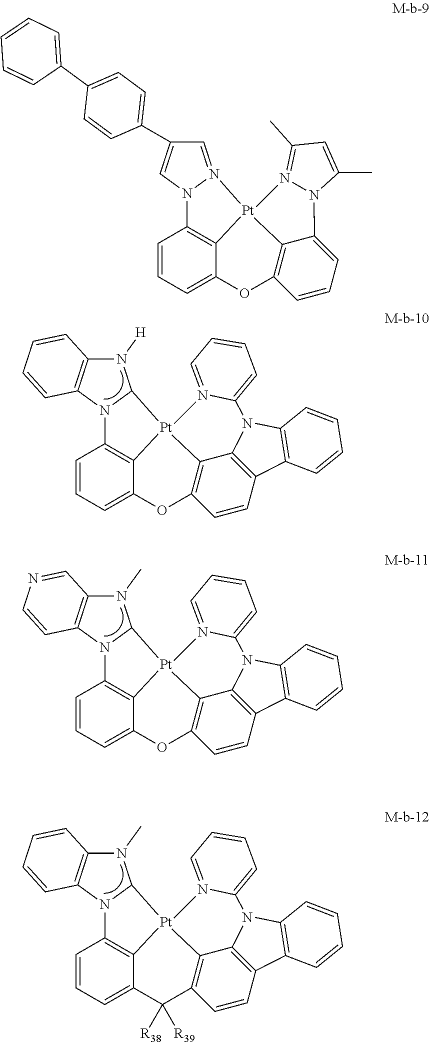

In the compounds above, R, R₃₈, and R₃₉ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

The emission layer EML may include any one selected from among Formula F-a to Formula F-c below. The compounds represented by Formula F-a to Formula F-c below may be used as fluorescence dopant materials.

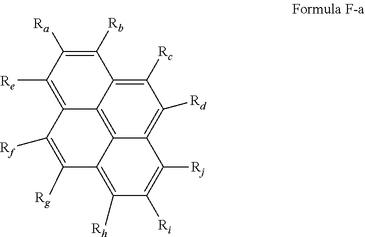

In Formula F-a, two selected from Rₐ to Rⱼ may be each independently substituted with *—NAr₁Ar₂. The remainder not substituted with *—NAr₁Ar₂ among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one selected from among Ar₁ and Ar₂ may be a heteroaryl group including O or S as a ring-forming atom.

The emission layer EML may include at least one selected from among Compounds FD1 to FD22 below as a fluorescence dopant.

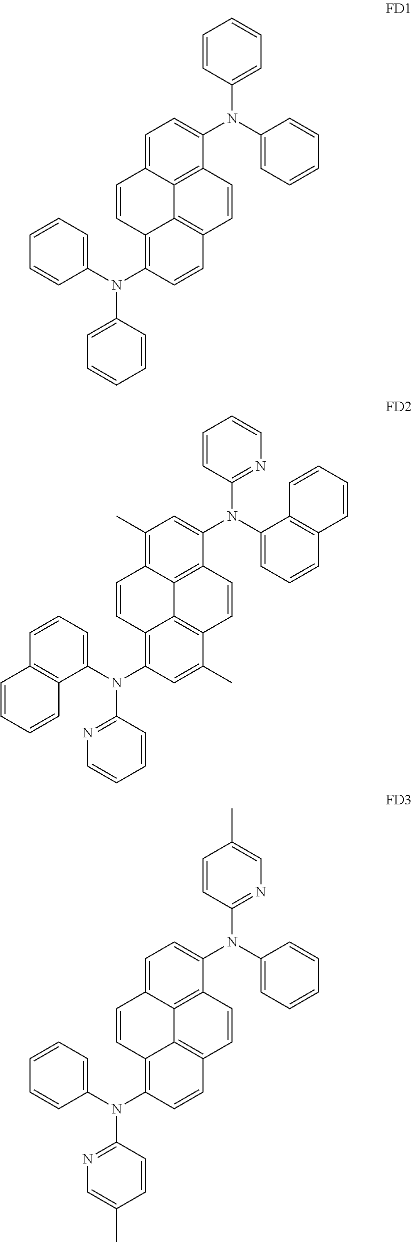 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1]

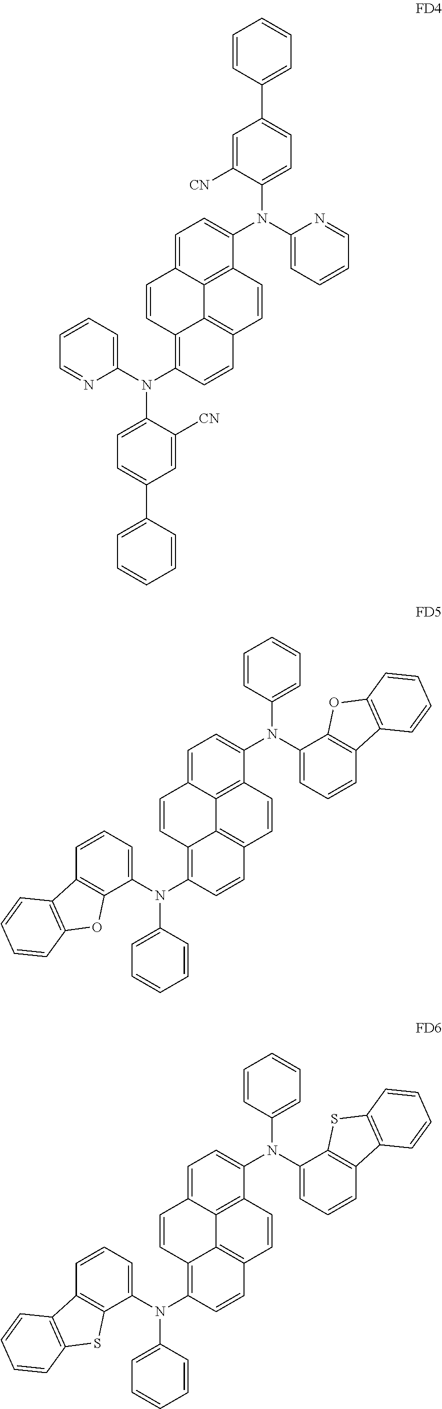

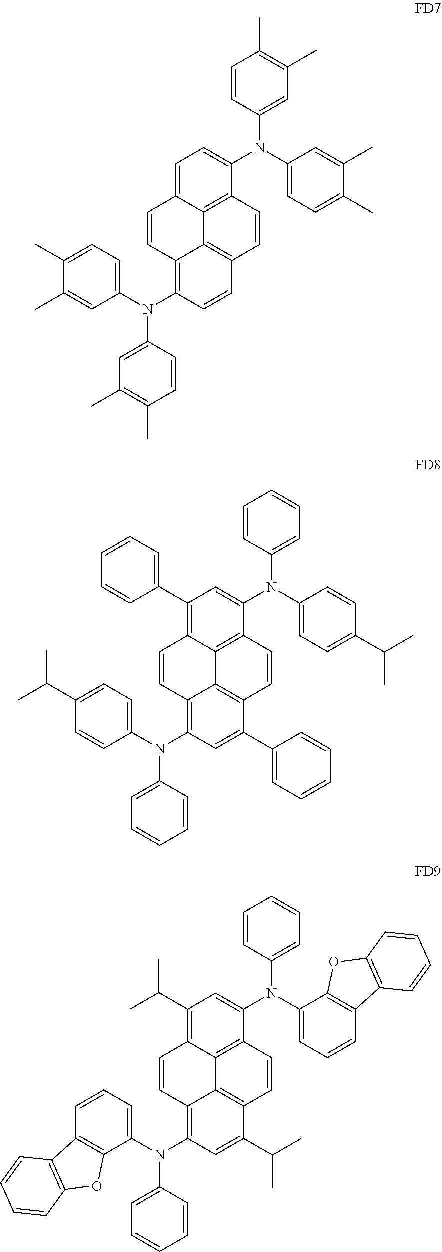

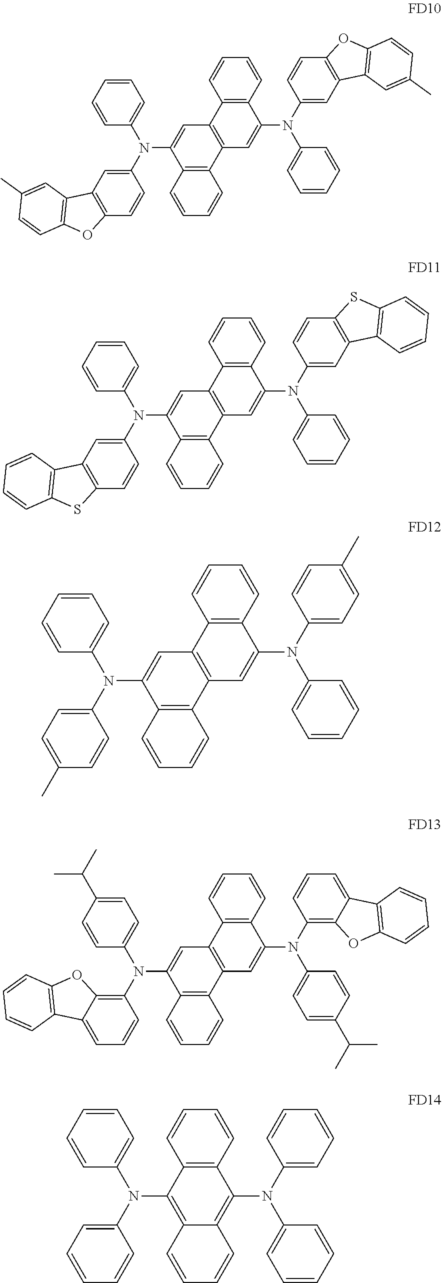

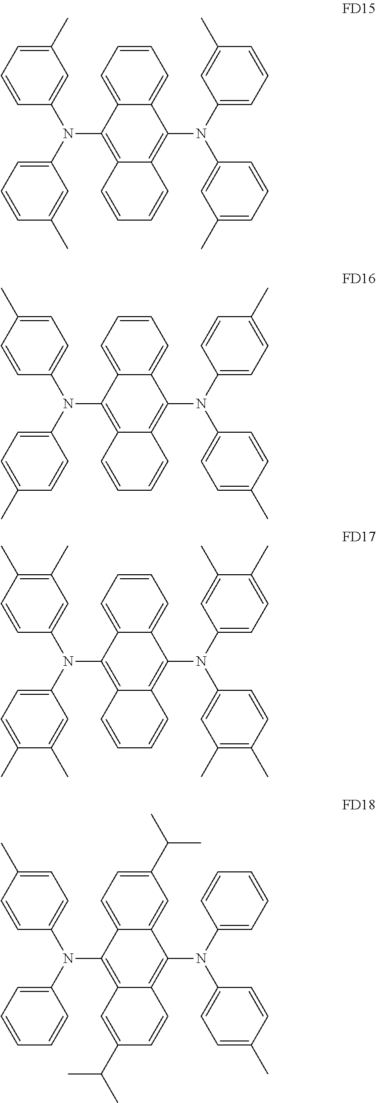

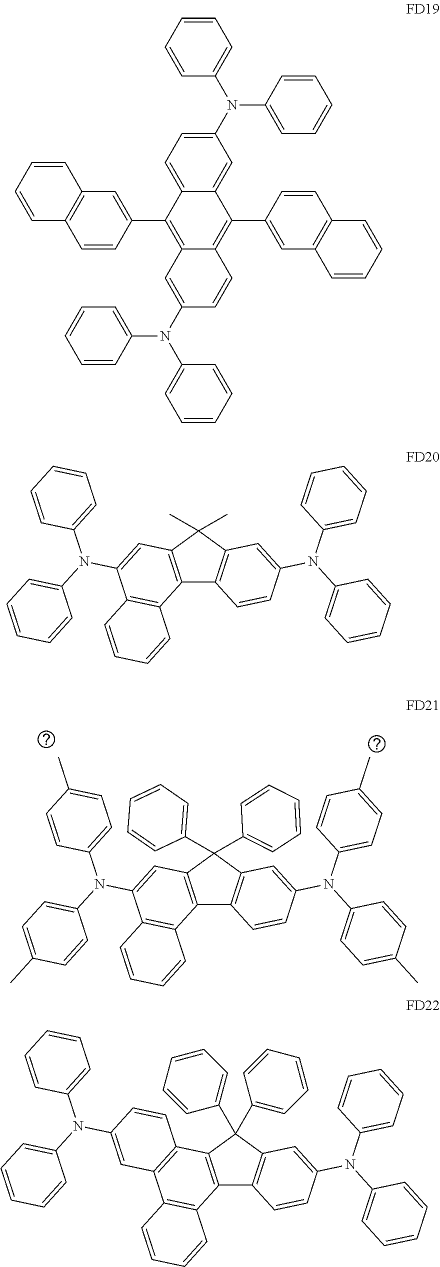

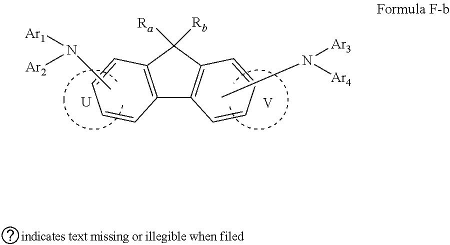

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula F-b, Ar₁ to Ar₄ may be each independently a substituted or unsubstituted aryl group of 6 to 30 ring-forming carbon atoms, or a substituted or unsubstituted heteroaryl group of 2 to 30 ring-forming carbon atoms.

In Formula F-b, U and V may be each independently a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may be each independently 0 or 1. For example, in Formula F-b, if the number of U or V is 1, one ring forms a fused ring at the part designated by U or V, and if the number of U or V is 0, a ring is not present at the part designated by U or V. In some embodiments, if the number of U is 0, and the number of V is 1, or if the number of U is 1, and the number of V is 0, a fused ring having the fluorene core of Formula F-b may be a ring compound having four rings. In addition, if the number of both U and V is 0, the fused ring having the fluorene core of Formula F-b may be a ring compound having three rings. In addition, if the number of both U and V is 1, a fused ring having the fluorene core of Formula F-b may be a ring compound having five rings.

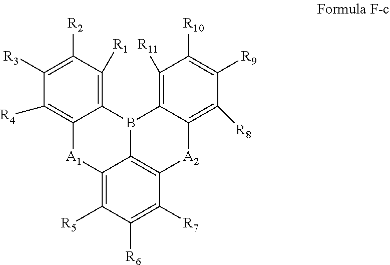

In Formula F-c, A₁ and A₂ may be each independently O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may be each independently combined with the substituents of an adjacent ring to form a fused ring. For example, if A₁ and A₂ are each independently NRₘ, A₁ may be combined with R₄ or R₅ to form a ring. In addition, A₂ may be combined with R₇ or R₈ to form a ring.

In an embodiment, the emission layer EML may include as a dopant material, styryl derivatives (for example, 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and/or derivatives thereof (for example, 2,5,8,11-tetra-t-butylperylene (TBP)), pyrene and/or derivatives thereof (for example, 1,1-dipyrene, 1,4-dipyrenylbenzene, and/or 1,4-bis(N,N-diphenylamino)pyrene), etc.

The emission layer EML may include any suitable phosphorescence dopant material generally available in the art. In some embodiments, the phosphorescence dopant may include a metal complex including iridium (Ir), platinum (Pt), osmium (Os), gold (Au), titanium (Ti), zirconium (Zr), hafnium (Hf), europium (Eu), terbium (Tb), and/or thulium (Tm). In some embodiments, iridium(III) bis(4,6-difluorophenylpyridinato-N,C2′)picolinato (Flrpic), bis(2,4-difluorophenylpyridinato)-tetrakis(1-pyrazolyl)borate iridium(III) (Flr₆), and/or platinum octaethyl porphyrin (PtOEP) may be used as the phosphorescence dopant. However, embodiments of the present disclosure are not limited thereto.

The emission layer EML may include a quantum dot material. The core of the quantum dot may be selected from a group II-VI compound, a group III-VI compound, a group I-III-VI compound, a group III-V compound, a group III-II-V compound, a group IV-VI compound, a group IV element, a group IV compound, and combinations thereof.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and mixtures thereof.

The group III-VI compound may include a binary compound such as In₂S₃, and/or In₂Se₃, a ternary compound such as InGaS₃, and/or InGaSe₃, and/or optional combinations thereof.

The group I-III-VI compound may be selected from a ternary compound selected from the group consisting of AgInS, AgInS₂, CuInS, CuInS₂, AgGaS₂, CuGaS₂, CuGaO₂, AgGaO₂, AgAlO₂ and mixtures thereof, and/or a quaternary compound such as AgInGaS₂, and/or CuInGaS₂.

The group III-V compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and mixtures thereof. The group III-V compound may further include a group II metal. For example, InZnP, etc. may be selected as a group III-II-V compound.

The group IV-VI compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The group IV element may be selected from the group consisting of Si, Ge, and a mixture thereof. The group IV compound may be a binary compound selected from the group consisting of SiC, SiGe, and a mixture thereof.

In this case, the binary compound, the ternary compound, and/or the quaternary compound may be present at a uniform (e.g., substantially uniform) concentration in a particle or may be present at a partially different concentration distribution state in the same particle. In addition, a core/shell structure in which one quantum dot wraps another quantum dot may be possible. The interface of the core and the shell may have a concentration gradient in which the concentration of an element present in the shell decreases along a direction toward a center of the core.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal oxide, a non-metal oxide, a semiconductor compound, or combinations thereof.

For example, the metal oxide or the non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but embodiments of the present disclosure are not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have a full width of half maximum (FWHM) of emission wavelength spectrum of about 45 nm or less, about 40 nm or less, or, for example, about 30 nm or less. Within this range, color purity and/or color reproducibility may be improved. In addition, light emitted via such quantum dot is emitted in all directions, and light view angle properties may be improved.

In addition, the shape of the quantum dot may be generally used shapes in the art, without specific limitation. For example, the shape of spherical, pyramidal, multi-arm, or cubic nanoparticle, nanotube, nanowire, nanofiber, nanoplate particle, etc. may be used.

The quantum dot may control the color of light emitted according to the particle size, and accordingly, the quantum dot may have various suitable emission colors such as blue, red and green.

In the light emitting diode ED of an embodiment, as shown in FIG. 3 to FIG. 6, the electron transport region ETR is provided on the emission layer EML. The electron transport region ETR may include at least one selected from a hole blocking layer HBL, an electron transport layer ETL or an electron injection layer EIL. However, embodiments of the present disclosure are not limited thereto.

The electron transport region ETR may have a single layer formed using a single material, a single layer formed using a plurality of different materials, or a multilayer structure having a plurality of layers formed using a plurality of different materials.

For example, the electron transport region ETR may have a single layer structure of an electron injection layer EIL or an electron transport layer ETL, or a single layer structure formed using an electron injection material and an electron transport material. Further, the electron transport region ETR may have a single layer structure formed using a plurality of different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1 below.

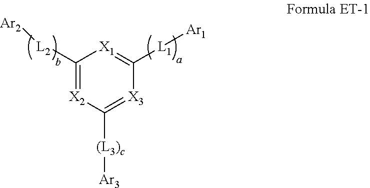

In Formula ET-1, at least one selected from among X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, “a” to “c” may be each independently an integer of 0 to 10. In Formula ET-1, L₁ to L₃ may be each independently a direct linkage, a substituted or unsubstituted arylene group of 6 to 30 ring-forming carbon atoms, or a substituted or unsubstituted heteroarylene group of 2 to 30 ring-forming carbon atoms. If “a” to “c” are integers of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or mixtures thereof, without limitation.

The electron transport region ETR may include at least one selected from among Compounds ET1 to ET36 below.

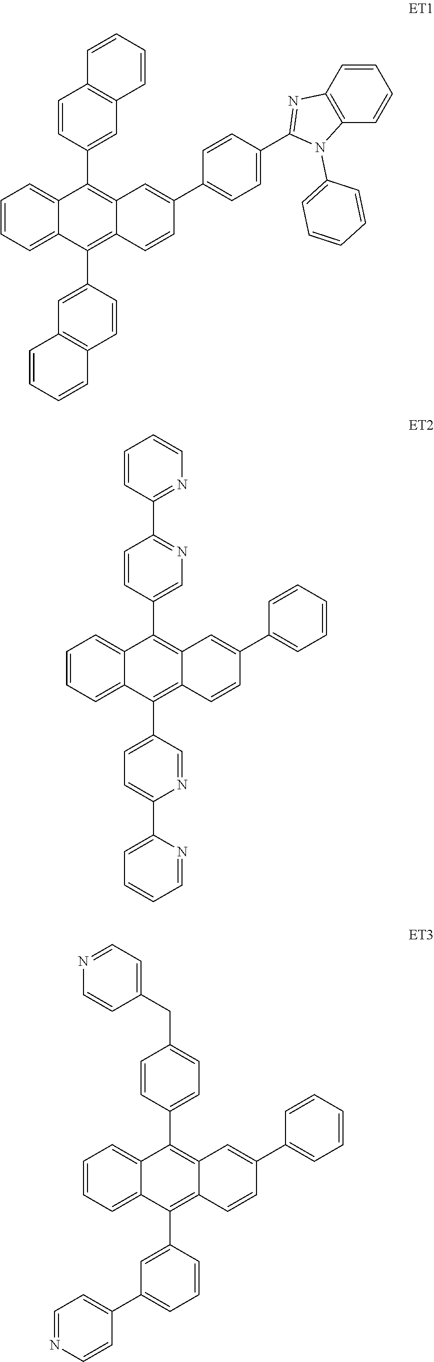 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4ccc(Cc5ccncc5)cc4)c3c2)cc1]

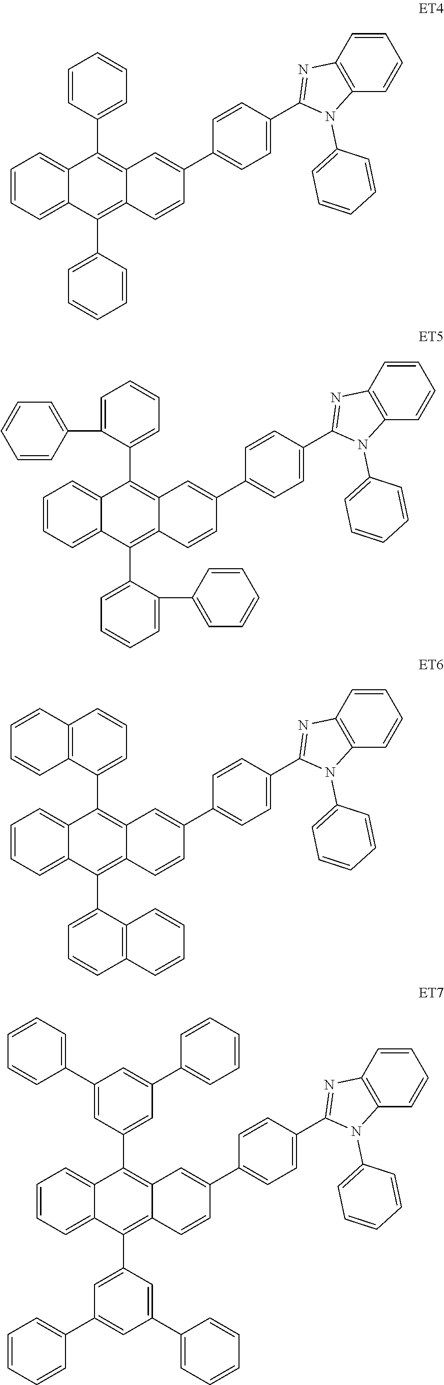 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

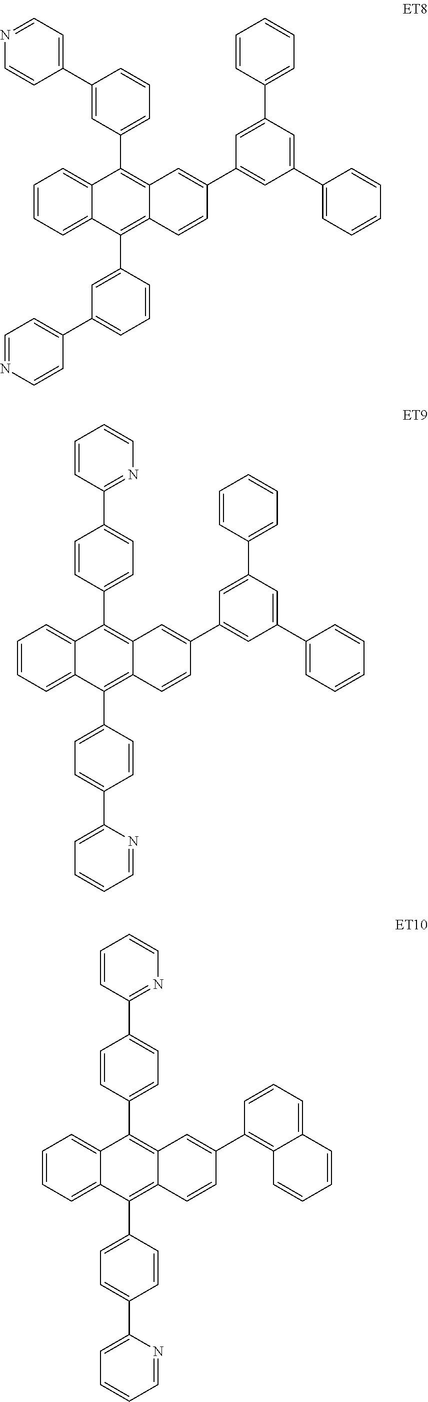 [SMILES: c1ccc(-c2cc(-c3ccccc3)cc(-c3ccc4c(-c5cccc(-c6ccncc6)c5)c5ccccc5c(-c5cccc(-c6ccncc6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

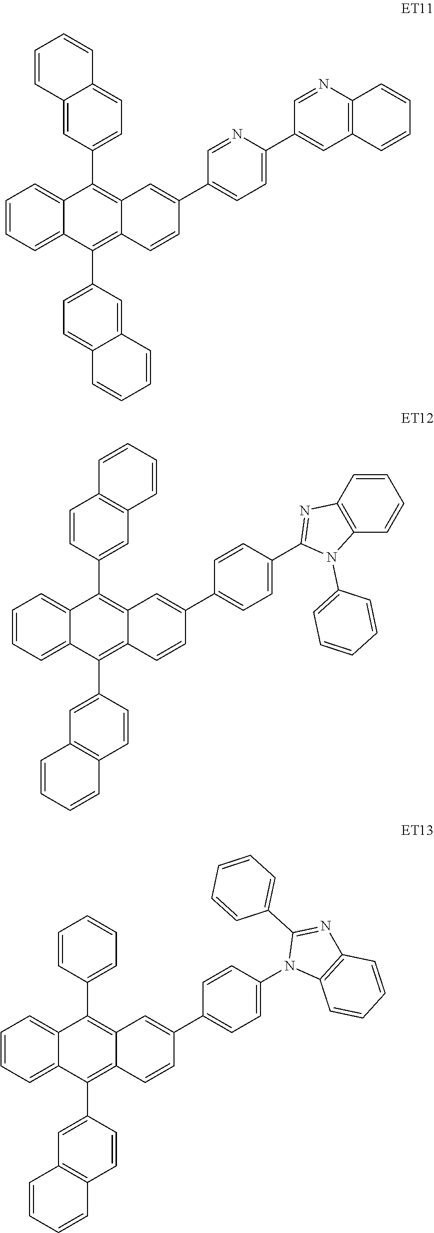

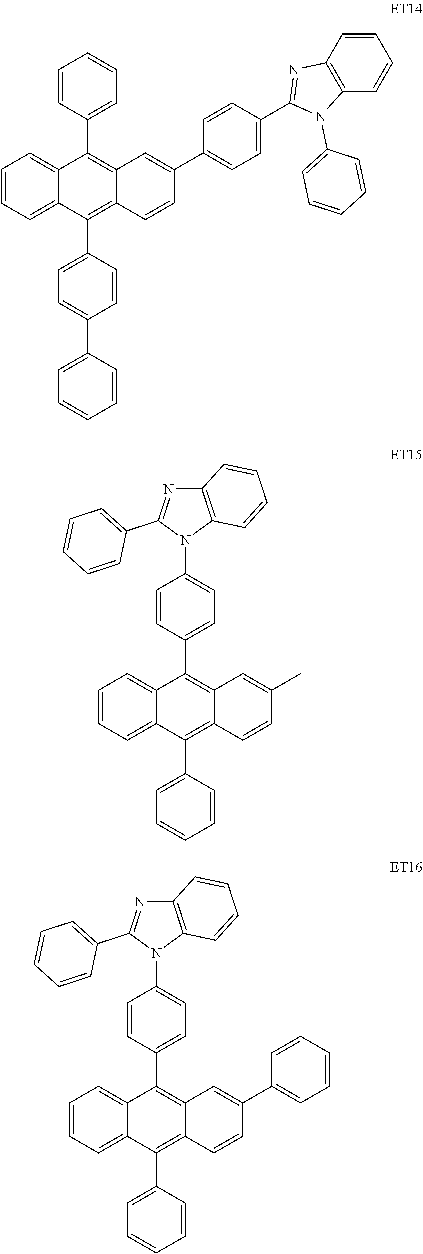

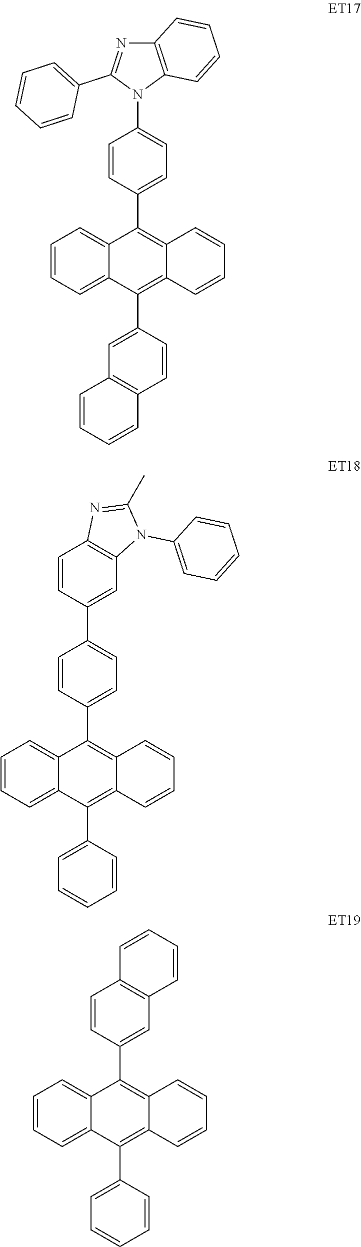

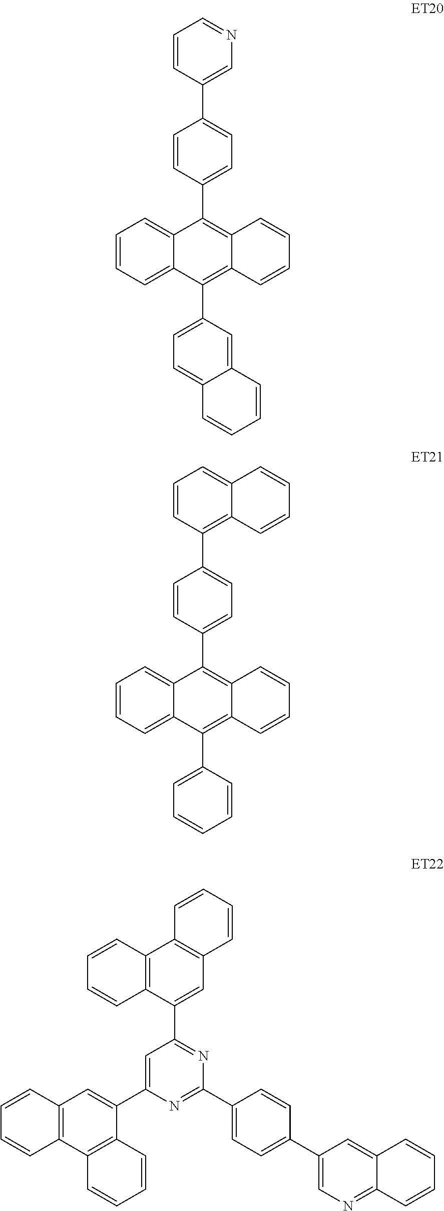

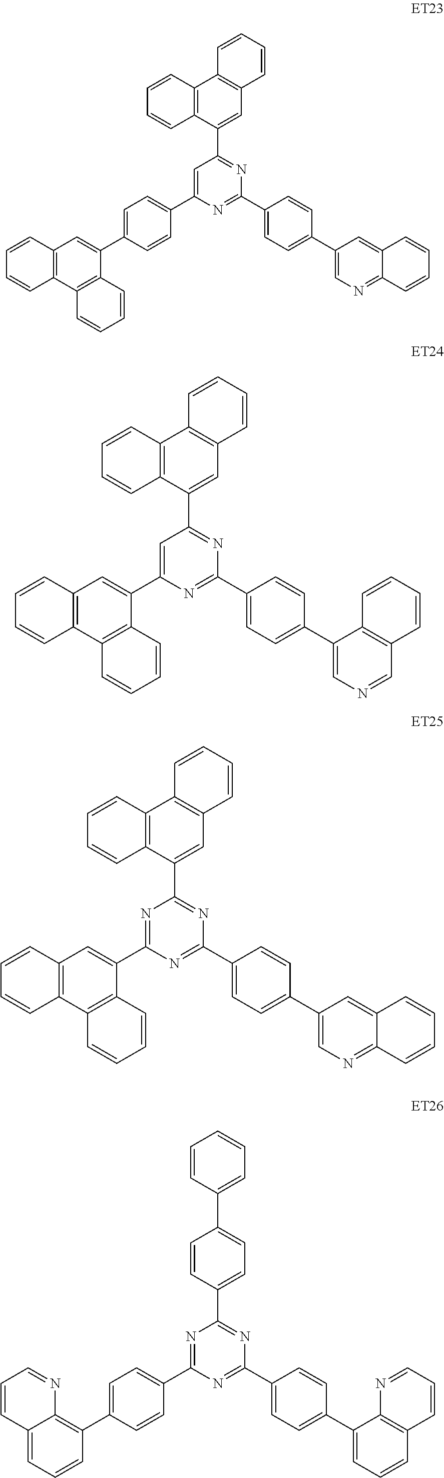 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)cncc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

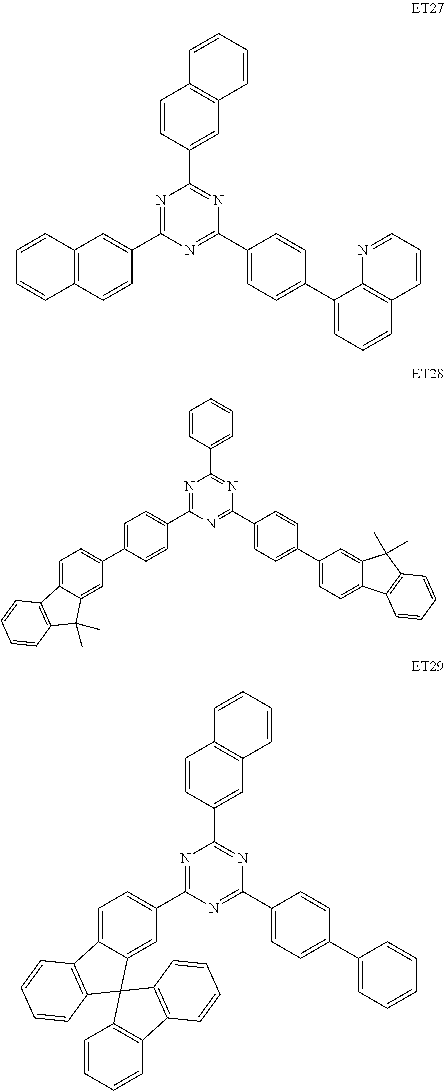 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc5c(c4)C4(c6ccccc6-c6ccccc64)c4ccccc4-5)nc(-c4ccc5ccccc5c4)n3)cc2)cc1]

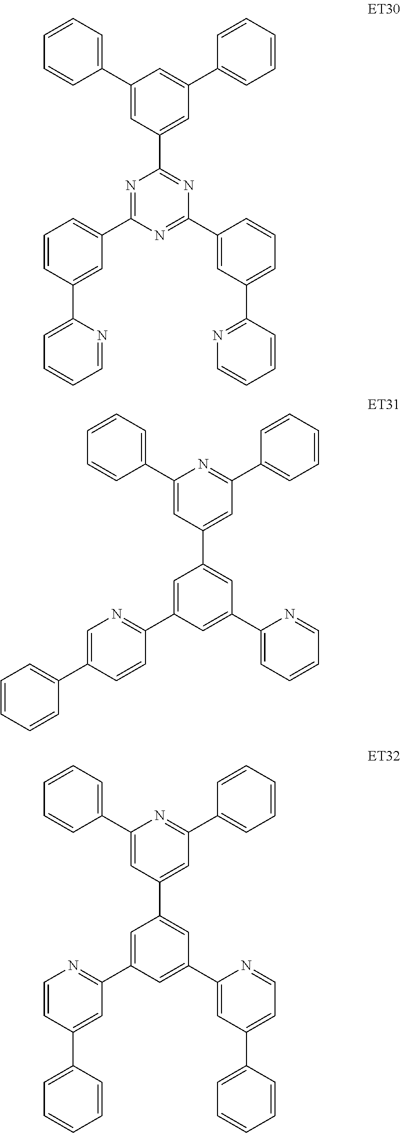 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

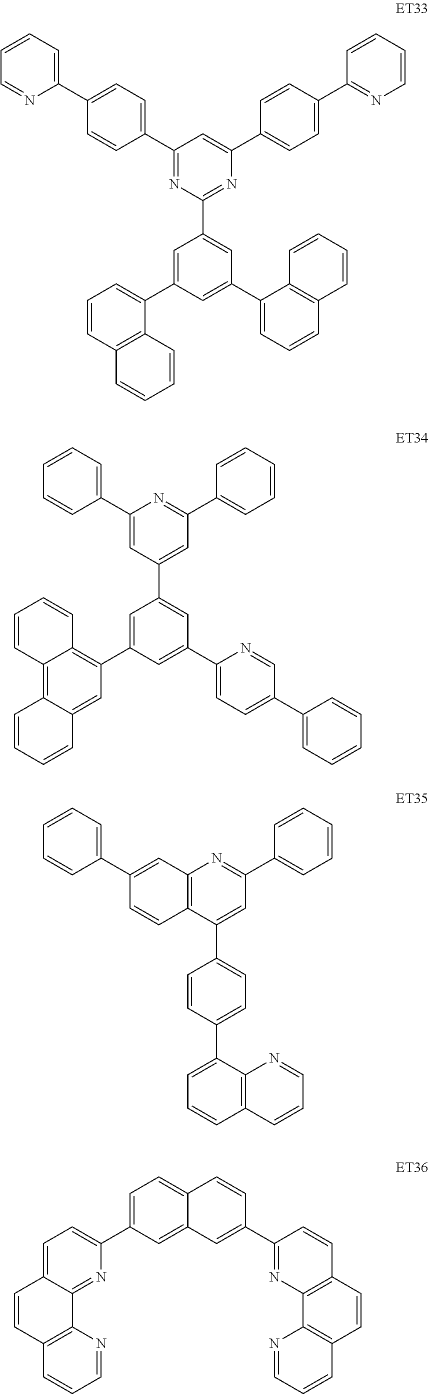 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccccc4)nc3c2)cc1 ; c1cnc2c(c1)ccc1ccc(-c3ccc4ccc(-c5ccc6ccc7cccnc7c6n5)cc4c3)nc12]

In addition, the electron transport region ETR may include a metal halide such as LiF, NaCl, CsF, RbCl, RbI, CuI, and/or KI, a metal of the lanthanides such as Yb, and/or a co-deposited material of the metal halide and the metal of the lanthanides. For example, the electron transport region ETR may include KI:Yb, RbI:Yb, etc., as the co-deposited material. The electron transport region ETR may use a metal oxide such as Li₂O and/or BaO, and/or 8-hydroxy-lithium quinolate (Liq). However, embodiments of the present disclosure are not limited thereto. The electron transport region ETR also may be formed using a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, and/or metal stearates.

The electron transport region ETR may include at least one selected from 2,9-dimethyl-4,7-diphenyl-1,10-phenanthroline (BCP), and 4,7-diphenyl-1,10-phenanthroline (Bphen) in addition to, or instead of, the aforementioned materials. However, embodiments of the present disclosure are not limited thereto.

The electron transport region ETR may include the compounds of the electron transport region in at least one selected from among an electron injection layer EIL, an electron transport layer ETL, and a hole blocking layer HBL.

If the electron transport region ETR includes the electron transport layer ETL, the thickness of the electron transport layer ETL may be from about 100 Å to about 1,000 Å, or, for example, from about 150 Å to about 500 Å. If the thickness of the electron transport layer ETL satisfies the above-described range, suitable or satisfactory electron transport properties may be obtained without substantial increase of a driving voltage. If the electron transport region ETR includes the electron injection layer EIL, the thickness of the electron injection layer EIL may be from about 1 Å to about 100 Å, and from about 3 Å to about 90 Å. If the thickness of the electron injection layer EIL satisfies the above described range, suitable or satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, if the first electrode EL1 is an anode, the second electrode EL2 may be a cathode, and if the first electrode EL1 is a cathode, the second electrode EL2 may be an anode.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds including thereof, and/or mixtures thereof (for example, AgMg, AgYb, and/or MgAg). In some embodiments, the second electrode EL2 may have a multilayered structure including a reflective layer or a transflective layer formed using the above-described materials and a transparent conductive layer formed using ITO, IZO, ZnO, ITZO, etc. For example, the second electrode EL2 may include the aforementioned metal materials, combinations of two or more metal materials selected from the aforementioned metal materials, and/or oxides of the aforementioned metal materials.

The second electrode EL2 may be connected with an auxiliary electrode. If the second electrode EL2 is connected with the auxiliary electrode, the resistance of the second electrode EL2 may decrease.

A capping layer CPL may be further on the second electrode EL2 in the light emitting diode ED of an embodiment. The capping layer CPL may include a multilayer or a single layer.

In an embodiment, the capping layer CPL may be an organic layer and/or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., and/or includes an epoxy resin, and/or acrylate such as methacrylate. In addition, a capping layer CPL may include at least one among Compounds P1 to P5 below, but embodiments of the present disclosure are not limited thereto.

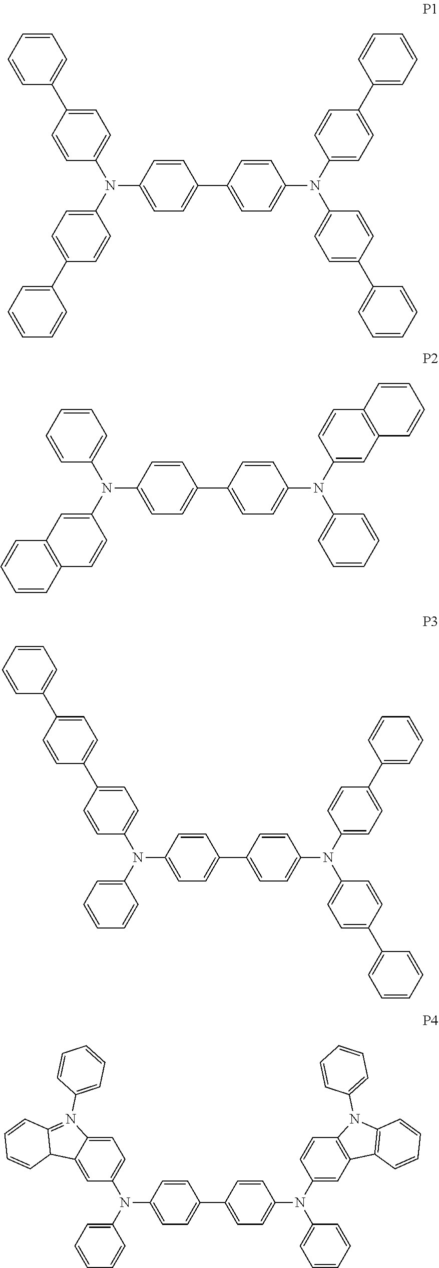

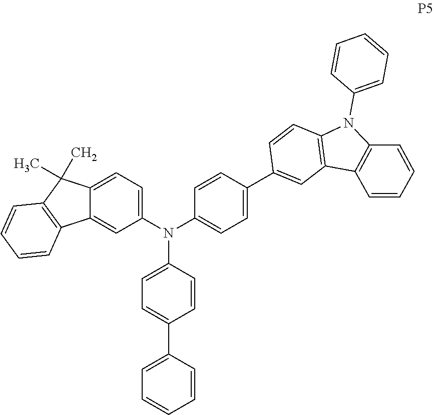 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or more. For example, the refractive index of the capping layer CPL with respect to light in a wavelength range of about 550 nm to about 660 nm may be about 1.6 or more.

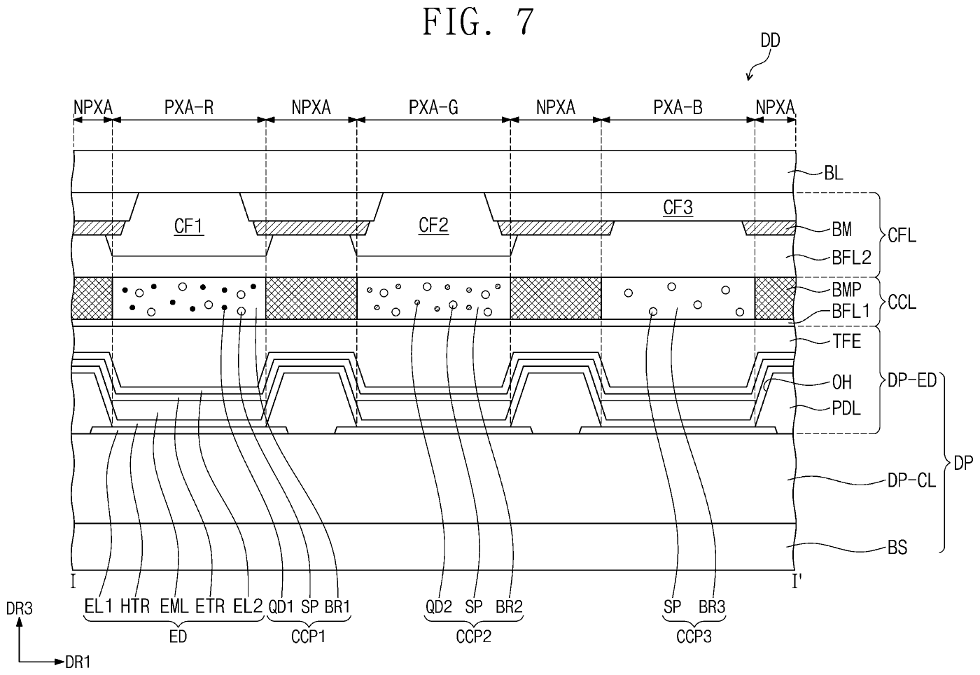

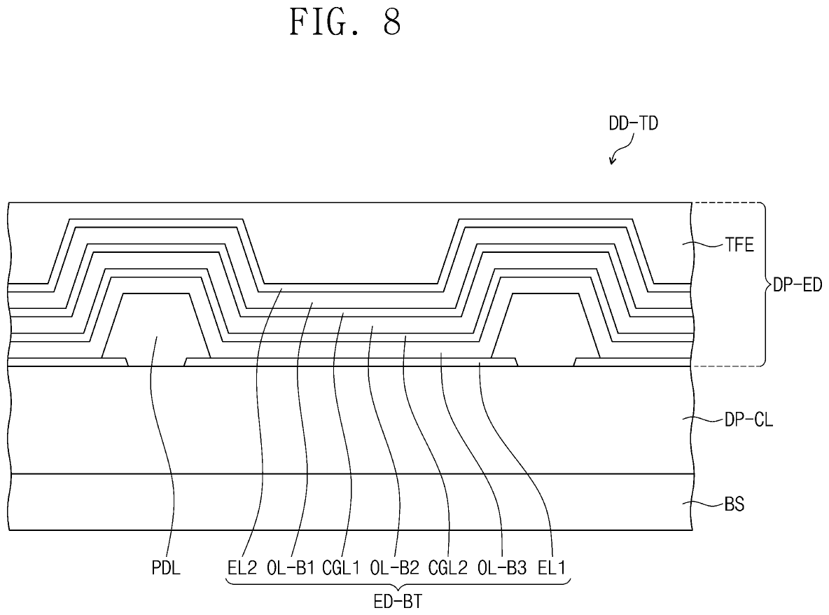

FIG. 7 and FIG. 8 are cross-sectional views of display apparatuses according to embodiments, respectively. In the explanation of the display apparatuses of embodiments, referring to FIG. 7 and FIG. 8, the portions of the description overlapping with the explanation of FIG. 1 to FIG. 6 will not be repeated here, and the different features will be primarily explained.

Referring to FIG. 7, the display apparatus DD according to an embodiment may include a display panel DP including a display device layer DP-ED, a light controlling layer CCL on the display panel DP, and a color filter layer CFL.

In an embodiment shown in FIG. 7, the display panel DP includes a base layer BS, a circuit layer DP-CL provided on the base layer BS and a display device layer DP-ED, and the display device layer DP-ED may include a light emitting diode ED.

The light emitting diode ED may include a first electrode EL1, a hole transport region HTR on the first electrode EL1, an emission layer EML on the hole transport region HTR, an electron transport region ETR on the emission layer EML, and a second electrode EL2 on the electron transport region ETR. The same (e.g., substantially the same) structures of the light emitting diodes ED of FIG. 3 to FIG. 6 may be applied to the structure of the light emitting diode ED shown in FIG. 7.

Referring to FIG. 7, the emission layer EML may be in an opening portion OH defined in a pixel definition layer PDL. For example, the emission layer EML divided by the pixel definition layer PDL and correspondingly provided to each of luminous areas PXA-R, PXA-G and PXA-B may emit light in the same (e.g., substantially the same) wavelength region. In the display apparatus DD of an embodiment, the emission layer EML may emit blue light. Different from the drawings, in an embodiment, the emission layer EML may be provided as a common layer for all luminous areas PXA-R, PXA-G, and PXA-B.

The light controlling layer CCL may be on the display panel DP. The light controlling layer CCL may include a light converter. The light converter may be a quantum dot and/or a phosphor. The light converter may transform the wavelength of light provided and then emit the transformed light. For example, the light controlling layer CCL may be a layer including a quantum dot and/or a layer including a phosphor.

The light controlling layer CCL may include a plurality of light controlling parts CCP1, CCP2, and CCP3. The light controlling parts CCP1, CCP2, and CCP3 may be separated (e.g., spaced apart) from one another.

Referring to FIG. 7, a partition pattern BMP may be between the separated light controlling parts CCP1, CCP2, and CCP3, but embodiments of the present disclosure are not limited thereto. In FIG. 7, the partition pattern BMP is shown not to be overlapped with the light controlling parts CCP1, CCP2, and CCP3, but at least a portion of the edge of the light controlling parts CCP1, CCP2, and CCP3 may be overlapped with the partition pattern BMP.

The light controlling layer CCL may include a first light controlling part CCP1 including a first quantum dot QD1 to convert a first color light provided from the light emitting diode ED into a second color light, a second light controlling part CCP2 including a second quantum dot QD2 to convert a first color light into third color light, and a third light controlling part CCP3 to transmit the first color light.

In an embodiment, the first light controlling part CCP1 may provide red light which is the second color light, and the second light controlling part CCP2 may provide green light which is the third color light. The third light controlling part CCP3 may transmit and provide blue light which is the first color light provided from the light emitting diode ED. For example, the first quantum dot QD1 may be a red quantum dot, and the second quantum dot QD2 may be a green quantum dot. For the quantum dots QD1 and QD2, the same (e.g., substantially the same) description as provided above may be applied.

In addition, the light controlling layer CCL may further include a scatterer SP (e.g., a light scatterer SP). The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but include the scatterer SP.

The scatterer SP may be an inorganic particle. For example, the scatterer SP may include at least one selected from among TiO₂, ZnO, Al₂O₃, SiO₂, and hollow silica. The scatterer SP may include one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light controlling part CCP1, the second light controlling part CCP2, and the third light controlling part CCP3 may include base resins BR1, BR2, and BR3, respectively, to disperse the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3. The base resins BR1, BR2, and BR3 are mediums in which the quantum dots QD1 and QD2 and the scatterer SP are dispersed, and may be composed of various suitable resin compositions which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may block or reduce the penetration of moisture and/or oxygen (hereinafter, may be referred to as “humidity/oxygen”). The barrier layer BFL1 may be on the light controlling parts CCP1, CCP2, and CCP3 to block or reduce the exposure of the light controlling parts CCP1, CCP2, and CCP3 to humidity/oxygen. The barrier layer BFL1 may cover the light controlling parts CCP1, CCP2, and CCP3. In addition, the barrier layer BFL2 may be provided between the light controlling parts CCP1, CCP2, and CCP3 and filters CF1, CF2 and CF3.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride, and/or a metal thin film securing light transmittance. The barrier layers BFL1 and BFL2 may further include an organic layer. The barrier layers BFL1 and BFL2 may be composed of a single layer of a plurality of layers.

In the display apparatus DD of an embodiment, the color filter layer CFL may be on the light controlling layer CCL. For example, the color filter layer CFL may be directly on the light controlling layer CCL. In this case, the barrier layer BFL2 may be omitted.

The color filter layer CFL may include a light blocking part BM and filters CF1, CF2 and CF3. The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye. Embodiments of the present disclosure are not limited thereto, and the third filter CF3 may not include the pigment and/or dye. The third filter CF3 may include a polymer photosensitive resin and not include a pigment or dye. The third filter CF3 may be transparent. The third filter CF3 may be formed using a transparent photosensitive resin.

In addition, in an embodiment, the first filter CF1 and the second filter CF2 may be yellow filters. The first filter CF1 and the second filter CF2 may be provided in one body without distinction.

The light blocking part BM may be a black matrix. The light blocking part BM may be formed by including an organic light blocking material or an inorganic light blocking material including a black pigment and/or black dye. The light blocking part BM may prevent or reduce light leakage phenomenon and divide the boundaries among adjacent filters CF1, CF2, and CF3. In addition, in an embodiment, the light blocking part BM may be formed as a blue filter.

The first to third filters CF1, CF2, and CF3 may respectively correspond to a red luminous area PXA-R, green luminous area PXA-G, and blue luminous area PXA-B.

A base substrate BL may be on the color filter layer CFL. The base substrate BL may be a member providing a base surface on which the color filter layer CFL, the light controlling layer CCL, etc. are located. The base substrate BL may be a glass substrate, a metal substrate, a plastic substrate, etc. However, embodiments of the present disclosure are not limited thereto, and the base substrate BL may be an inorganic layer, an organic layer, and/or a composite material layer. In addition, different from the drawing, the base substrate BL may be omitted in an embodiment.

FIG. 8 is a cross-sectional view showing a portion of the display apparatus according to an embodiment. In a display apparatus DD-TD of an embodiment, the light emitting diode ED-BT may include a plurality of light emitting structures OL-B1, OL-B2, and OL-B3. The light emitting diode ED-BT may include a first electrode EL1 and a second electrode EL2 facing each other, and the plurality of light emitting structures OL-B1, OL-B2, and OL-B3 stacked in order in a thickness direction and provided between the first electrode EL1 and the second electrode EL2. Each of the light emitting structures OL-B1, OL-B2, and OL-B3 may include an emission layer EML (FIG. 7), and a hole transport region HTR and an electron transport region ETR together with the emission layer EML (FIG. 7) therebetween.

For example, the light emitting diode ED-BT included in the display apparatus DD-TD of an embodiment may be a light emitting diode of a tandem structure including a plurality of emission layers.

In an embodiment shown in FIG. 8, light emitted from the light emitting structures OL-B1, OL-B2, and OL-B3 may be all blue light. However, embodiments of the present disclosure are not limited thereto, and the wavelength regions of light emitted from the light emitting structures OL-B1, OL-B2, and OL-B3, respectively, may be different from each other. For example, the light emitting diode ED-BT including the plurality of light emitting structures OL-B1, OL-B2, and OL-B3 that emit light in different wavelength regions may emit white light (e.g., may emit light in the same wavelength regions).

Charge generating layers CGL1 and CGL2 may be between neighboring light emitting structures OL-B1, OL-B2, and OL-B3. The charge generating layers CGL1 and CGL2 may include a p-type charge generating layer and/or an n-type charge generating layer.

The above-described polycyclic compound of an embodiment may be included in at least one selected from the light emitting structures OL-B1, OL-B2, and OL-B3 included in the display apparatus DD-TD of an embodiment.

The light emitting diode ED according to embodiments of the present disclosure may include the polycyclic compound of an embodiment in at least one functional layer between a first electrode EL1 and a second electrode EL2, and may show improved life. The light emitting diode ED according to an embodiment may include the polycyclic compound of an embodiment in at least one selected from among a hole transport region HTR, an emission layer EML, and an electron transport region ETR, between the first electrode EL1 and the second electrode EL2, and/or in a capping layer CPL.

For example, the polycyclic compound according to an embodiment may be included in the emission layer EML of the light emitting diode ED of an embodiment, and the light emitting diode ED of an embodiment may show a low driving voltage, high efficiency and long-life characteristics.

The polycyclic compound of an embodiment includes a fused structure of ring compounds to a boron atom and has a structure in which pyrrole is directly connected with a boron atom. For example, through the direct connection of the nitrogen atom of the pyrrole with the boron atom, an N—B bond may be formed. The polycyclic compound of the present disclosure includes the N—B bond, and, while the present application is not limited by any particular mechanism or theory, it is believed that due to the electron donating properties of the nitrogen atom, the p orbital of the boron atom may be stabilized, and the stability and multiple resonance of a molecule may be improved.

The light emitting diode of embodiments of the present disclosure includes the polycyclic compound of in at least one functional layer, and may show markedly improved light emitting diode life, emission efficiency and color purity.

Hereinafter, the polycyclic compound according to embodiments and the light emitting diode of embodiments including thereof will be further explained by referring to embodiments and comparative embodiments. In addition, the embodiments below are only illustrations to assist the understanding of the subject matter of the present disclosure, and the scope of the present disclosure is not limited thereto.

### Example 1. Synthesis of Polycyclic Compound

The synthetic method of embodiments of a polycyclic compound of the present disclosure will be further explained by illustrating the synthetic methods of Compound 5, Compound 16, Compound 22, Compound 45, Compound 65, Compound 80, and Compound 104. In addition, the synthetic methods of the polycyclic compounds explained hereinafter are embodiments, and the synthetic method of the polycyclic compound according to an embodiment of the present disclosure is not limited to the embodiments below.

### 1) Synthesis of Compound 5

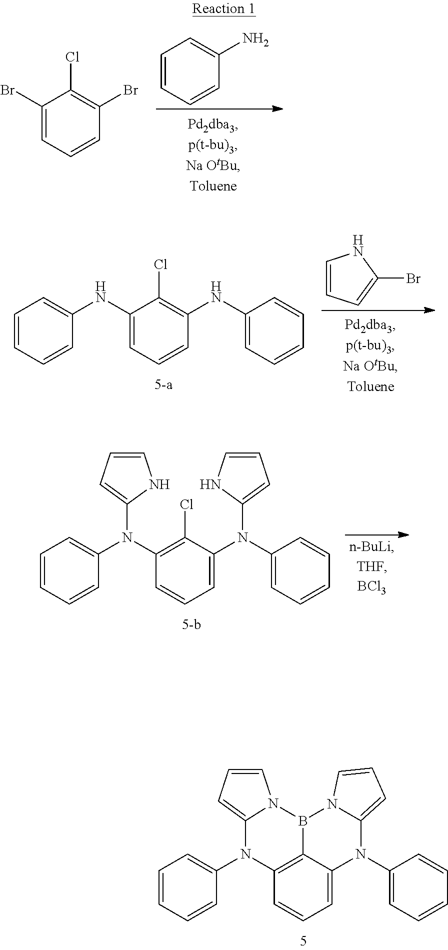

### Synthesis of Intermediate Compound 5-a

Under an argon atmosphere, 1,3-dibromo-2-chloro-benzene (10 g, 42 mmol), aniline (8.1 g, 84 mmol), pd₂dba₃ (1.9 g, 2.1 mmol), and tris-tert-butyl phosphine (2.0 mL, 4.1 mmol) were added to a 2 L flask and dissolved in 400 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 5-a (colorless liquid, 8.3 g, 76%). The compound thus obtained was confirmed as Intermediate Compound 5-a through ESI-LCMS.

ESI-LCMS: [M]⁺: C₁₈H₁₆N₂. 260.1237.

### Synthesis of Intermediate Compound 5-b

Under an argon atmosphere, Intermediate Compound 5-a (8 g, 31 mmol), 2-bromo pyrrole (9.9 g, 67 mmol), pd₂dba₃ (1.4 g, 1.6 mmol), and tris-tert-butyl phosphine (1.5 mL, 3.2 mmol) were added to a 1 L flask and dissolved in 300 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 5-b (colorless liquid, 8.1 g, 67%). The compound thus obtained was confirmed as Intermediate Compound 5-b through ESI-LCMS.

ESI-LCMS: [M]⁺: C₂₆H₂₁N₄Cl. 424.1878.

### Synthesis of Compound 5

Under an argon atmosphere, Intermediate Compound 5-b (8 g, 20 mmol) was added to a 1 L flask and dissolved in 200 mL of anhydrous THF, and the reaction solution was cooled to about −70 degrees. While maintaining the temperature, n-BuLi (5 equiv.) was slowly added dropwisely thereto, and the temperature was slowly raised to room temperature and then raised to about 80 degrees, and refluxing and stirring were performed for about 6 hours. The temperature was reduced again to room temperature, and BCl₃ (1.5 equiv.) was added thereto, followed by refluxing and stirring at about 80 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Compound 5 (yellow solid, 2.0 g, 26%). The compound thus obtained was confirmed as Compound 5 through ¹H-NMR and ESI-LCMS.

¹H-NMR (400 MHz, CDCl₃): d=9.11 (d, 2H), 7.24 (m, 5H), 7.08 (d, 4H), 7.00 (m, 2H), 6.83 (d, 2H), 6.33 (m, 4H).

ESI-LCMS: [M]⁺: C₂₆H₁₉N₄B. 398.1667.

### 2) Synthesis of Compound 16

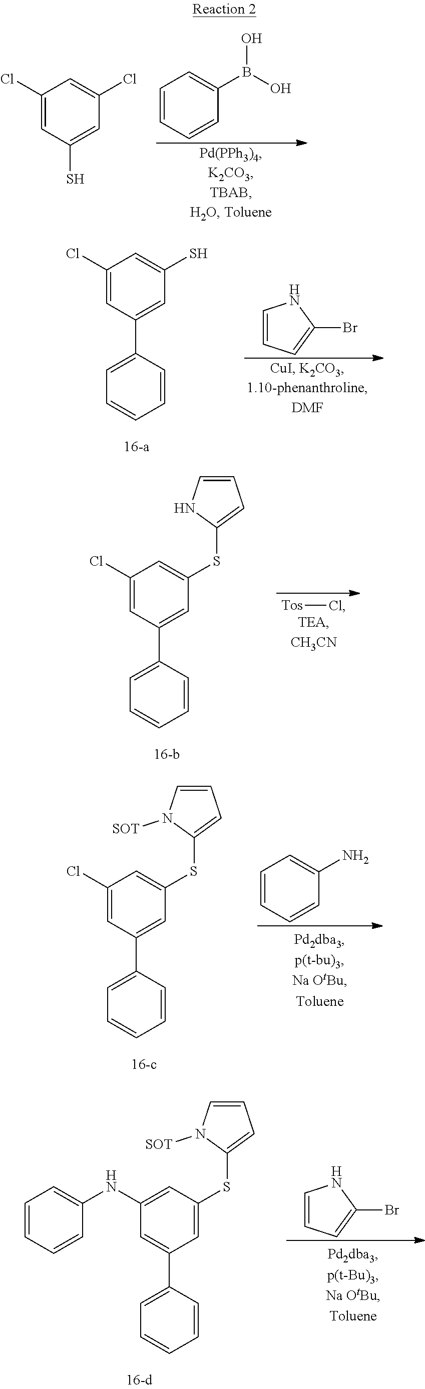

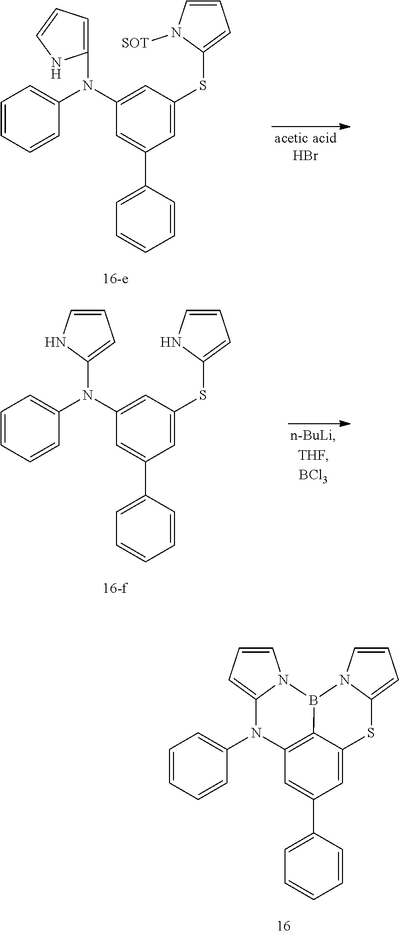

### Synthesis of Intermediate Compound 16-a

Under an argon atmosphere, 3,5-dichloro-thiophenol (20 g, 75 mmol), phenylboronic acid (9.1 g, 75 mmol), pd(PPh₃)₄ (2.6 g, 2.3 mmol), and K₂CO₃ (31 g, 225 mmol) were added to a 2 L flask and dissolved in 500 mL of toluene and 150 mL of H₂O, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 16-a (colorless liquid, 8.5 g, 43%). The compound thus obtained was confirmed as Intermediate Compound 16-a through ESI-LCMS.

ESI-LCMS: [M]⁺: C₁₂H₉SCl. 220.0101.

### Synthesis of Intermediate Compound 16-b

Under an argon atmosphere, Intermediate Compound 16-a (8 g, 36 mmol), 2-bromo pyrrole (5.3 g, 36 mmol), CuI (6.8 g, 36 mmol), 1,10-phenanthroline (6.3 g, 36 mmol), and K₂CO₃ (15 g, 108 mmol) were added to a 1 L flask and dissolved in 500 mL of DMF, and the resultant reaction solution was stirred at about 160 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 16-b (yellow liquid, 7.7 g, 75%). The compound thus obtained was confirmed as Intermediate Compound 16-b through ESI-LCMS.

ESI-LCMS: [M]⁺: C₁₆H₁₂NClS. 285.0401.

### Synthesis of Intermediate Compound 16-c

Under an argon atmosphere, Intermediate Compound 16-b (7.5 g, 26 mmol), p-toluenesulfonyl chloride (5 g, 26 mmol), and triethylamine (6.5 g, 52 mmol) were added to a 1 L flask and dissolved in 300 mL of anhydrous CH₂Cl₂, and the resultant reaction solution was stirred at room temperature for about 12 hours. After finishing the reaction, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 16-c (colorless liquid, 7.3 g, 83%). The compound thus obtained was confirmed as Intermediate Compound 16-c through ESI-LCMS.

ESI-LCMS: [M]⁺: C₂₂H₁₆NClO₂S₂. 425.0331.

### Synthesis of Intermediate Compound 16-d

Under an argon atmosphere, Intermediate Compound 16-c (7 g, 16 mmol), aniline (16 g, 16 mmol), pd₂dba₃ (0.7 g, 0.8 mmol), tris-tert-butyl phosphine (0.7 mL, 1.6 mmol), and sodium tert-butoxide (4.6 g, 48 mmol) were added to a 1 L flask and dissolved in 150 mL of toluene, and the resultant reaction solution was stirred at about 100 degrees for about 12 hours. After cooling, water (1 L) and ethyl acetate (300 mL) were added, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 16-d (colorless liquid, 6.1 g, 77%). The compound thus obtained was confirmed as Intermediate Compound 16-d through ESI-LCMS.

ESI-LCMS: [M]⁺: C₂₉H₂₄N₂O₂S₂. 496.1312.

### Synthesis of Intermediate Compound 16-e

Under an argon atmosphere, Intermediate Compound 16-d (6 g, 12 mmol), 2-bromo pyrrole (1.8 g, 12 mmol), pd₂dba₃ (0.5 g, 0.6 mmol), tris-tert-butyl phosphine (0.5 mL, 1.2 mmol), and sodium tert-butoxide (3.4 g, 36 mmol) were added to a 1 L flask and dissolved in 120 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 16-e (yellow liquid, 5.6 g, 83%). The compound thus obtained was confirmed as Intermediate Compound 16-e through ESI-LCMS.

ESI-LCMS: [M]⁺: C₃₃H₂₇N₃O₂S₂. 561.1514.

### Synthesis of Intermediate Compound 16-f

Under an argon atmosphere, Intermediate Compound 16-e (5.5 g, 9.8 mmol) was added to a 1 L flask and dissolved in 100 mL of acetic acid, and 20 mL of HBr was added thereto. The resultant reaction solution was stirred at about 100 degrees for about 12 hours. After cooling, the pH was adjusted to neutral using NaOH. Water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 16-f (pale yellow solid, 3.6 g, 90%). The compound thus obtained was confirmed as Intermediate Compound 16-f through ESI-LCMS.

ESI-LCMS: [M]⁺: C₂₆H₂₁N₃S. 407.1117.

### Synthesis of Compound 16

Under an argon atmosphere, Intermediate Compound 16-f (3 g, 7.3 mmol) was added to a 1 L flask and dissolved in 50 mL of anhydrous THF, and the resultant reaction solution was cooled to about −70 degrees. While maintaining the temperature, n-BuLi (5 equiv.) was slowly added dropwisely thereto, and the temperature was slowly raised to room temperature and then raised to about 80 degrees, and refluxing and stirring were performed for about 6 hours. The temperature was reduced again to room temperature, and BCl₃ (1.5 equiv.) was added thereto, followed by refluxing and stirring at about 80 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Compound 16 (yellow solid, 0.9 g, 31%). The compound thus obtained was confirmed as Compound 16 through ¹H-NMR and ESI-LCMS.

¹H-NMR (400 MHz, CDCl₃): d=9.27 (d, 2H), 7.78 (d, 2H), 7.49 (t, 2H), 7.41 (m, 1H), 7.24 (m, 3H), 7.08 (m, 4H), 6.33 (m, 4H).

ESI-LCMS: [M]⁺: C₂₆H₁₈N₃BS. 415.3167.

### 3) Synthesis of Compound 22

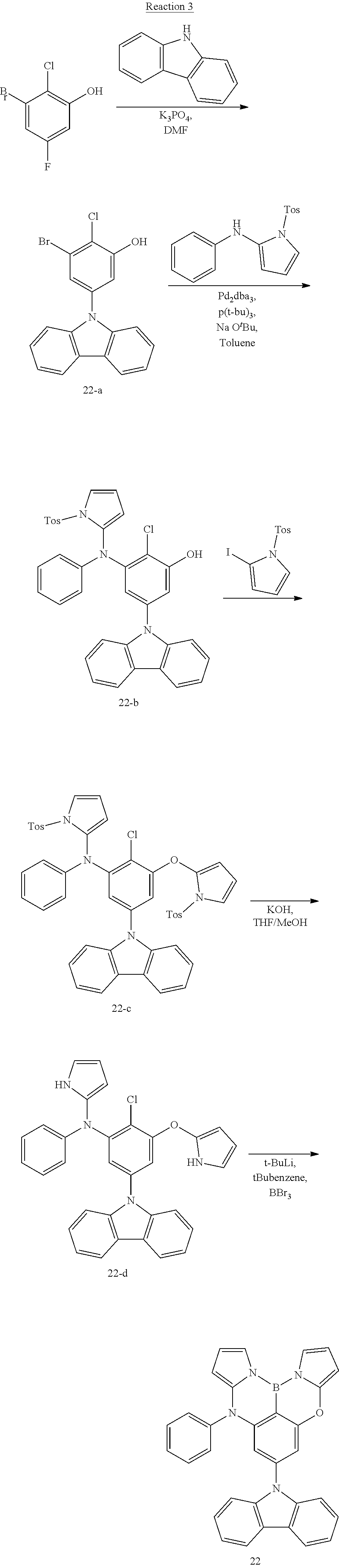

### Synthesis of Intermediate Compound 22-a

Under an argon atmosphere, 3-bromo-2-chloro-5-fluorophenol (10 g, 44 mmol), carbazole (7.4 g, 44 mmol), and K₃PO₄ (41 g, 220 mmol) were added to a 2 L flask and dissolved in 500 mL of DMF, and the resultant reaction solution was stirred at about 160 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 22-a (white solid, 13 g, 82%). The compound thus obtained was confirmed as Intermediate Compound 22-a through ESI-LCMS.

ESI-LCMS: [M]⁺: C₁₈H₁₁BrClNO. 370.9712.

### Synthesis of Intermediate Compound 22-b

Under an argon atmosphere, Intermediate Compound 22-a (13 g, 35 mmol), N-phenyl-1-tosyl-1H-pyrrol-2-amine (10.8 g, 12 mmol), pd₂dba₃ (1.6 g, 1.7 mmol), tris-tert-butyl phosphine (1.6 mL, 3.4 mmol), and sodium tert-butoxide (10 g, 105 mmol) were added to a 1 L flask and dissolved in 350 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 22-b (white solid, 15 g, 71%). The compound thus obtained was confirmed as Intermediate Compound 22-b through ESI-LCMS.

ESI-LCMS: [M]⁺: C₃₅H₂₆N₃O₃SCl. 603.1407.

### Synthesis of Intermediate Compound 22-c

Under an argon atmosphere, Intermediate Compound 22-b (15 g, 25 mmol), 2-iodo-1-tosyl-1H-pyrrole (8.6 g, 25 mmol), and K₃PO₄ (15 g, 75 mmol) were added to a 1 L flask and dissolved in 300 mL of DMF, and the resultant reaction solution was stirred at about 160 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 22-c (white solid, 13 g, 65%). The compound thus obtained was confirmed as Intermediate Compound 22-c through ESI-LCMS.

ESI-LCMS: [M]⁺: C₄₆H₃₅N₄O₅S₂Cl. 822.1727.

### Synthesis of Intermediate Compound 22-d

Under an argon atmosphere, Intermediate Compound 22-c (13 g, 15 mmol), and KOH (8.4 g, 150 mmol) were added to a 1 L flask and dissolved in 150 mL of THF and 150 mL of MeOH, and the resultant reaction solution was refluxed and stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 22-d (white solid, 5.2 g, 68%). The compound thus obtained was confirmed as Intermediate Compound 22-d through ESI-LCMS.

ESI-LCMS: [M]⁺: C₃₂H₂₃N₄OCl. 514.1612.

### Synthesis of Compound 22

Under an argon atmosphere, Intermediate Compound 22-d (5 g, 10 mmol) was added and dissolved in 50 mL of t-butyl benzene, and the resultant reaction solution was cooled to about −20 degrees. While maintaining the temperature, t-BuLi (5 equiv.) was slowly added dropwisely thereto, and the temperature was slowly raised to room temperature and then raised to about 80 degrees, and refluxing and stirring were performed for about 6 hours. The temperature was reduced again to room temperature, and BBr₃ (1.5 equiv.) was added thereto, followed by refluxing and stirring at about 80 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Compound 22 (yellow solid, 0.7 g, 15%). The compound thus obtained was confirmed as Compound 22 through ¹H-NMR and ESI-LCMS.

¹H-NMR (400 MHz, CDCl₃): d=8.55 (d, 2H), 7.94 (d, 2H), 7.49 (t, 2H), 7.31 (d, 2H), 7.24 (m, 4H), 7.08 (m, 3H), 6.79 (s, 1H), 6.58 (s, 1H), 6.27 (m, 4H).

ESI-LCMS: [M]⁺: C₃₂H₂₁N₄BO. 488.1812.

### 4) Synthesis of Compound 45

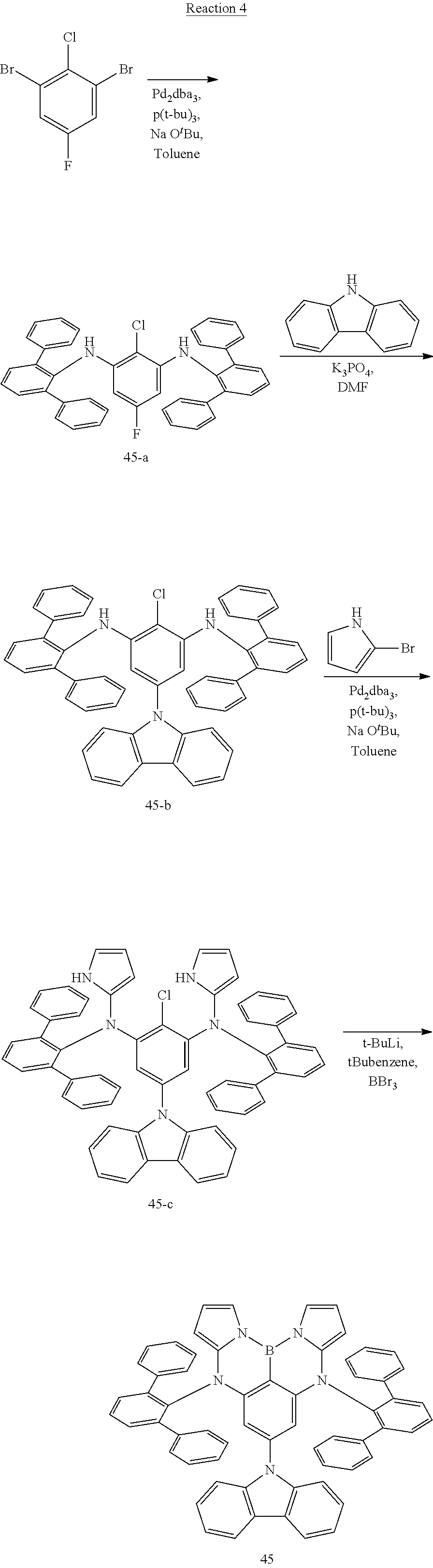

### Synthesis of Intermediate Compound 45-a

Under an argon atmosphere, 1,3-dibromo-2-chloro-5-fluorobenzene (10 g, 35 mmol), [1,1′:3′,1″-terphenyl]-2′-amine (17 g, 70 mmol), pd₂dba₃ (1.6 g, 1.7 mmol), tris-tert-butyl phosphine (1.6 mL, 3.4 mmol), and sodium tert-butoxide (10 g, 105 mmol) were added to a 1 L flask and dissolved in 350 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 45-a (white solid, 16 g, 76%). The compound thus obtained was confirmed as Intermediate Compound 45-a through ESI-LCMS.

ESI-LCMS: [M]⁺: C₄₂H₃₀N₂FCl. 616.2007.

### Synthesis of Intermediate Compound 45-b

Under an argon atmosphere, Intermediate Compound 45-a (15 g, 24 mmol), carbazole (8.6 g, 24 mmol), and K₃PO₄ (15 g, 75 mmol) were added to a 1 L flask and dissolved in 300 mL of DMF, and the resultant reaction solution was stirred at about 160 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 45-b (white solid, 10.8 g, 59%). The compound thus obtained was confirmed as Intermediate Compound 45-b through ESI-LCMS.

ESI-LCMS: [M]⁺: C₅₄H₃₈N₃Cl. 763.2812.

### Synthesis of Intermediate Compound 45-c

Under an argon atmosphere, Intermediate Compound 45-b (10 g, 13 mmol), 2-bromo-1H-pyrrole (3.8 g, 26 mmol), pd₂dba₃ (0.6 g, 0.65 mmol), tris-tert-butyl phosphine (0.6 mL, 1.3 mmol), and sodium tert-butoxide (3.7 g, 39 mmol) were added thereto and dissolved in 150 mL of toluene, and the resultant reaction solution was stirred at about 100 degrees for about 12 hours. After cooling, water (1 L) and ethyl acetate (300 mL) were added thereto, extraction was performed, and organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 45-c (white solid, 7.8 g, 67%). The compound thus obtained was confirmed as Intermediate Compound 45-c through ESI-LCMS.

ESI-LCMS: [M]⁺: C₆₂H₄₄N₅Cl. 893.3303.

### Synthesis of Compound 45

Under an argon atmosphere, Intermediate Compound 45-c (7 g, 7.8 mmol) was added to a 1 L flask and dissolved in 50 mL of t-butyl benzene, and the resultant reaction solution was cooled to about −20 degrees. While maintaining the temperature, t-BuLi (5 equiv.) was slowly added dropwisely thereto, and the temperature was slowly raised to room temperature and then raised to about 80 degrees, and refluxing and stirring were performed for about 6 hours. The temperature was reduced again to room temperature, and BBr₃ (1.5 equiv.) was added thereto, followed by refluxing and stirring at about 80 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Compound 45 (yellow solid, 0.74 g, 11%). The compound thus obtained was confirmed as Compound 45 through ¹H-NMR and ESI-LCMS.

¹H-NMR (400 MHz, CDCl₃): d=8.62 (d, 2H), 8.22 (t, 4H), 7.85 (d, 2H), 7.43 (m, 16H), 7.24 (m, 4H), 7.08 (m, 8H), 6.89 (s, 2H), 6.38 (m, 4H).

ESI-LCMS: [M]⁺: C₆₂H₄₂N₅B. 867.2997.

### 5) Synthesis of Compound 65

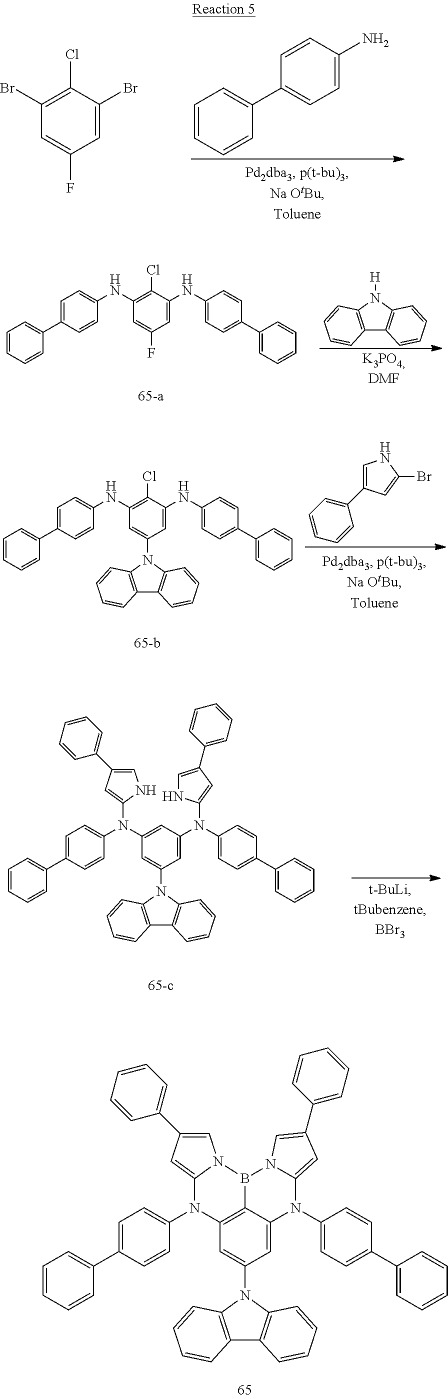

### Synthesis of Intermediate Compound 65-a

Under an argon atmosphere, 1,3-dibromo-2-chloro-5-fluorobenzene (10 g, 35 mmol), 4-amino biphenyl (11.8 g, 70 mmol), pd₂dba₃ (0.6 g, 0.65 mmol), tris-tert-butyl phosphine (0.6 mL, 1.3 mmol), and sodium tert-butoxide (3.7 g, 39 mmol) were added to a 1 L flask and dissolved in 150 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 65-a (white solid, 11.8 g, 73%). The compound thus obtained was confirmed as Intermediate Compound 65-a through ESI-LCMS.

ESI-LCMS: [M]⁺: C₃₀H₂₂N₂ClF. 464.1512.

### Synthesis of Intermediate Compound 65-b

Under an argon atmosphere, Intermediate Compound 65-a (11 g, 24 mmol), carbazole (8.6 g, 24 mmol), and K₃PO₄ (15 g, 75 mmol) were added to a 1 L flask and dissolved in 300 mL of DMF, and the resultant reaction solution was stirred at about 160 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 65-b (white solid, 9.2 g, 63%). The compound thus obtained was confirmed as Intermediate Compound 65-b through ESI-LCMS.

ESI-LCMS: [M]⁺: C₄₂H₃₀N₃Cl. 611.2177.

### Synthesis of Intermediate Compound 65-c

Under an argon atmosphere, Intermediate Compound 65-b (9 g, 15 mmol), 2-bromo-4-phenyl-1H-pyrrole (6.7 g, 30 mmol), pd₂dba₃ (0.68 g, 0.75 mmol), tris-tert-butyl phosphine (0.7 mL, 1.5 mmol), and sodium tert-butoxide (4.2 g, 45 mmol) were added to a 1 L flask and dissolved in 150 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 65-c (white solid, 9.5 g, 74%). The compound thus obtained was confirmed as Intermediate Compound 65-c through ESI-LCMS.

ESI-LCMS: [M]⁺: C₆₂H₄₅N₅. 859.3778.

### Synthesis of Compound 65

Under an argon atmosphere, Intermediate Compound 65-c (9 g, 10 mmol) was added to a 1 L flask and dissolved in 200 mL of t-butyl benzene, and the resultant reaction solution was cooled to about −20 degrees. While maintaining the temperature, t-BuLi (5 equiv.) was slowly added dropwisely thereto, and the temperature was slowly raised to room temperature and then raised to about 80 degrees, and refluxing and stirring were performed for about 6 hours. The temperature was reduced again to room temperature, and BBr₃ (1.5 equiv.) was added thereto, followed by refluxing and stirring at about 80 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Compound 65 (yellow solid, 0.78 g, 9%). The compound thus obtained was confirmed as Compound 65 through ¹H-NMR and ESI-LCMS.

¹H-NMR (400 MHz, CDCl₃): d=8.58 (d, 2H), 7.95 (d, 2H), 7.75 (d, 4H), 7.38 (m, 28H), 7.20 (d, 4H), 6.89 (s, 2H), 6.53 (s, 2H).

ESI-LCMS: [M]⁺: C₆₂H₄₂N₅B. 867.2997.

### 6) Synthesis of Compound 80

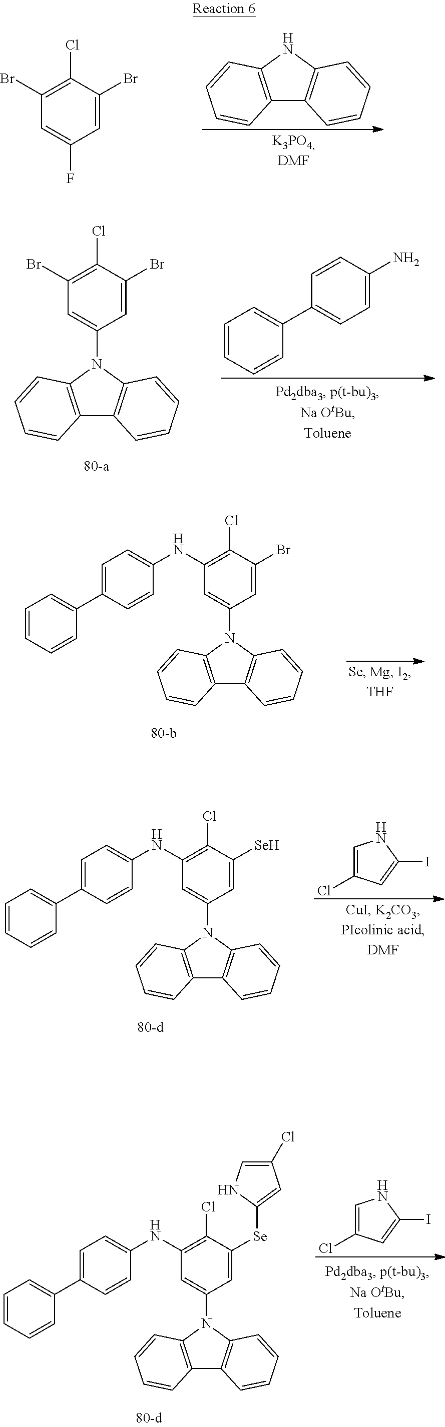

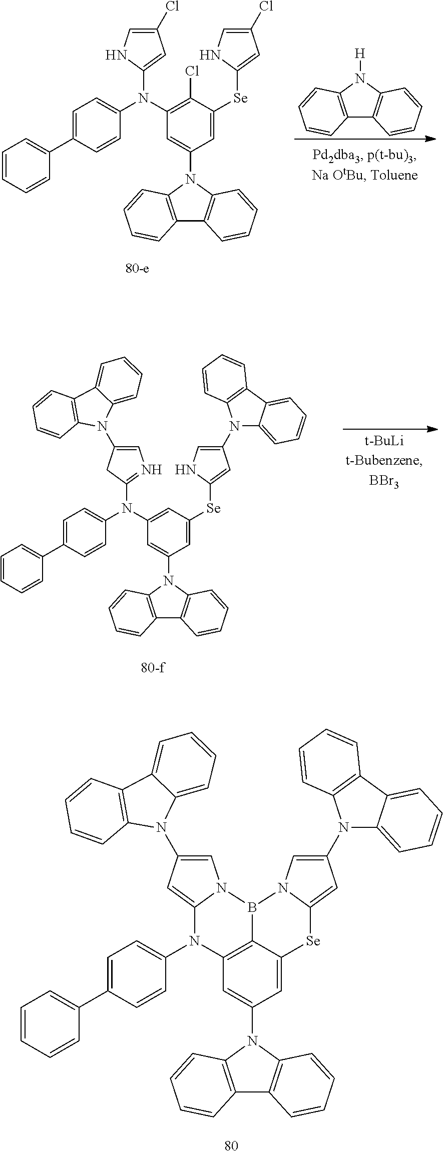 [SMILES: Clc1c[nH]c([Se]c2cc(-n3c4ccccc4c4ccccc43)cc(N(c3ccc(-c4ccccc4)cc3)c3cc(Cl)c[nH]3)c2Cl)c1 ; c1ccc2c(c1)[nH]c1ccccc12 ; C1=C(n2c3ccccc3c3ccccc32)CC(N(c2ccc(-c3ccccc3)cc2)c2cc([Se]c3cc(-n4c5ccccc5c5ccccc54)c[nH]3)cc(-n3c4ccccc4c4ccccc43)c2)=N1 ; c1ccc(-c2ccc(N3c4cc(-n5c6ccccc6c6ccccc65)cc5c4B(n4cc(-n6c7ccccc7c7ccccc76)cc4[Se]5)n4cc(-n5c6ccccc6c6ccccc65)cc43)cc2)cc1]

### Synthesis of Intermediate Compound 80-a

Under an argon atmosphere, 1,3-dibromo-2-chloro-5-fluorobenzene (10 g, 35 mmol), carbazole (5.8 g, 35 mmol), and K₃PO₄ (20 g, 105 mmol) were added to a 1 L flask and dissolved in 500 mL of DMF, and the resultant reaction solution was stirred at about 160 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 80-a (white solid, 9 g, 59%). The compound thus obtained was confirmed as Intermediate Compound 80-a through ESI-LCMS.

ESI-LCMS: [M]⁺: C₁₈H₁₀NClBr₂. 432.8974.

### Synthesis of Intermediate Compound 80-b

Under an argon atmosphere, Intermediate Compound 80-a (9 g, 20 mmol), 4-amino biphenyl (3.5 g, 20 mmol), pd₂dba₃ (0.9 g, 1 mmol), tris-tert-butyl phosphine (0.9 mL, 2 mmol), and sodium tert-butoxide (5.8 g, 60 mmol) were added to a 1 L flask and dissolved in 200 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 80-b (white solid, 5.8 g, 58%). The compound thus obtained was confirmed as Intermediate Compound 80-b through ESI-LCMS.

ESI-LCMS: [M]⁺: C₃₀H₂₀N₂BrCl. 522.0518.

### Synthesis of Intermediate Compound 80-c

Under an argon atmosphere, Intermediate Compound 80-b (5.8 g, 11 mmol), and Mg (0.5 g, 22 mmol) were added to a 1 L flask and dissolved in 100 mL of anhydrous THF, and iodine (catalytic amount) was added thereto. The temperature of the reaction solution was raised to about 60 degrees, stirring was performed for about 1 hour, and a selenium powder was added thereto. After stirring at about 80 degrees for about 6 hours and after cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 80-c (white solid, 3.8 g, 66%). The compound thus obtained was confirmed as Intermediate Compound 80-c through ESI-LCMS.

ESI-LCMS: [M]⁺: C₃₀H₂₁N₂SeCl. 524.0614.

### Synthesis of Intermediate Compound 80-d

Under an argon atmosphere, Intermediate Compound 80-c (3.8 g, 7.2 mmol), 4-chloro-2-iodo-1H-pyrrole (1.3 g, 7.2 mmol), CuI (1.4 g, 7.2 mmol), picolinic acid (0.9 g, 7.2 mmol), and K₂CO₃ (5 g, 36 mmol) were added to a 1 L flask and dissolved in 100 mL of DMF, and the resultant reaction solution was stirred at about 160 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 80-d (white solid, 3.6 g, 81%). The compound thus obtained was confirmed as Intermediate Compound 80-d through ESI-LCMS.

ESI-LCMS: [M]⁺: C₃₄H₂₃N₃SeCl₂. 623.0404.

### Synthesis of Intermediate Compound 80-e

Under an argon atmosphere, Intermediate Compound 80-d (3.5 g, 5.6 mmol), 4-chloro-2-iodo-1H-pyrrole (1.3 g, 5.6 mmol), pd₂dba₃ (0.25 g, 0.3 mmol), tris-tert-butyl phosphine (0.3 mL, 0.6 mmol), and sodium tert-butoxide (14.7 g, 15 mmol) were added to a 1 L flask and dissolved in 60 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 80-e (white solid, 3 g, 75%). The compound thus obtained was confirmed as Intermediate Compound 80-e through ESI-LCMS.

ESI-LCMS: [M]⁺: C₃₈H₂₅N₄Cl₃Se. 722.0333.

### Synthesis of Intermediate Compound 80-f

Under an argon atmosphere, Intermediate Compound 80-e (3 g, 4.2 mmol), carbazole (1.4 g, 8.4 mmol), pd₂dba₃ (0.2 g, 0.2 mmol), tris-tert-butyl phosphine (0.2 mL, 0.4 mmol), and sodium tert-butoxide (11.8 g, 12 mmol) were added to a 1 L flask and dissolved in 50 mL of toluene, and the resultant reaction solution was stirred at about 100 degrees for about 12 hours. After cooling, water (1 L) and ethyl acetate (300 mL) were added thereto, extraction was performed, and organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 80-f (white solid, 3.5 g, 88%). The compound thus obtained was confirmed as Intermediate Compound 80-f through ESI-LCMS.

ESI-LCMS: [M]⁺: C₆₂H₄₂N₆Se. 950.2699.

### Synthesis of Compound 80

Under an argon atmosphere, Intermediate Compound 80-f (3.5 g, 3.6 mmol) was added to a 1 L flask and dissolved in 50 mL of t-butyl benzene, and the resultant reaction solution was cooled to about −20 degrees. While maintaining the temperature, t-BuLi (5 equiv.) was slowly added dropwisely thereto, and the temperature was slowly raised to room temperature and then raised to about 80 degrees, and refluxing and stirring were performed for about 6 hours. The temperature was reduced again to room temperature, and BBr₃ (1.5 equiv.) was added thereto, followed by refluxing and stirring at about 80 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Compound 80 (yellow solid, 0.28 g, 8%). The compound thus obtained was confirmed as Compound 80 through ¹H-NMR and ESI-LCMS.

¹H-NMR (400 MHz, CDCl₃): d=8.55 (d, 6H), 7.94 (d, 6H), 7.75 (d, 2H), 7.58 (m, 18H), 7.20 (m, 8H), 6.33 (s, 2H).

ESI-LCMS: [M]⁺: C₆₂H₃₉N₆BSe. 958.2576.

### 7) Synthesis of Compound 104

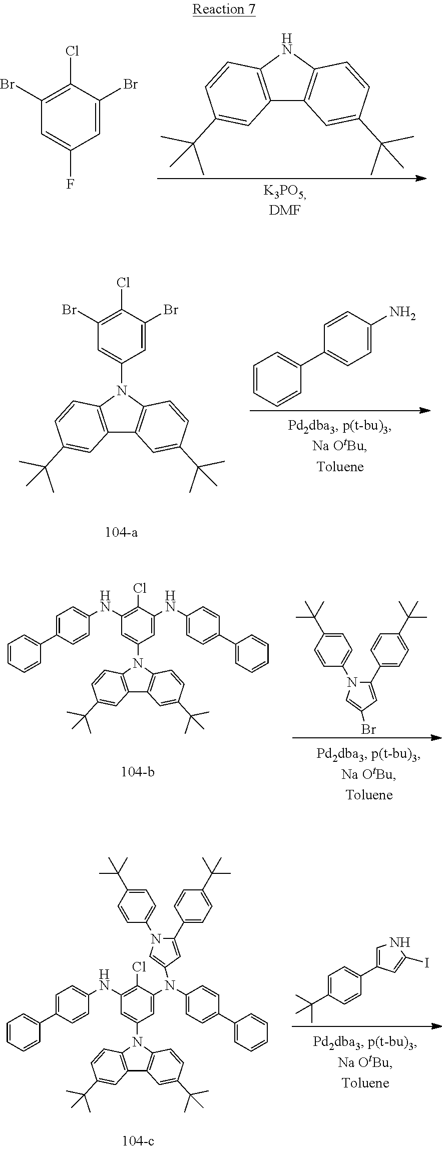

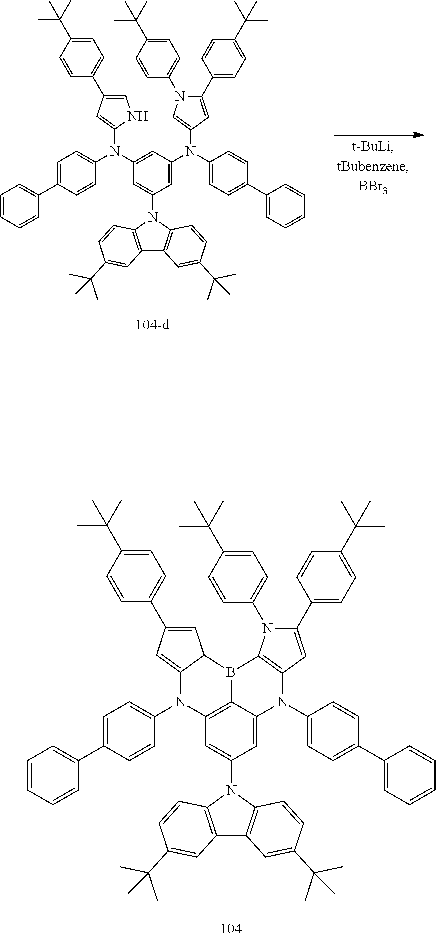 [SMILES: CC(C)(C)c1ccc(-c2c[nH]c(N(c3ccc(-c4ccccc4)cc3)c3cc(N(c4ccc(-c5ccccc5)cc4)c4cc(-c5ccc(C(C)(C)C)cc5)n(-c5ccc(C(C)(C)C)cc5)c4)cc(-n4c5ccc(C(C)(C)C)cc5c5cc(C(C)(C)C)ccc54)c3)c2)cc1 ; CC(C)(C)c1ccc(C2=CC3B4c5c(cc(-n6c7ccc(C(C)(C)C)cc7c7cc(C(C)(C)C)ccc76)cc5N(c5ccc(-c6ccccc6)cc5)c5cc(-c6ccc(C(C)(C)C)cc6)n(-c6ccc(C(C)(C)C)cc6)c54)N(c4ccc(-c5ccccc5)cc4)C3=C2)cc1]

### Synthesis of Intermediate Compound 104-a

Under an argon atmosphere, 1,3-dibromo-2-chloro-5-fluorobenzene (10 g, 35 mmol), 3,6-di-tert-butyl-9H-carbazole (9.8 g, 35 mmol), and K₃PO₄ (20 g, 105 mmol) were added to a 1 L flask and dissolved in 500 mL of DMF, and the resultant reaction solution was stirred at about 160 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 104-a (white solid, 12 g, 63%). The compound thus obtained was confirmed as Intermediate Compound 104-a through ESI-LCMS.

ESI-LCMS: [M]⁺: C₂₆H₂₆NClBr₂. 545.0160.

### Synthesis of Intermediate Compound 104-b

Under an argon atmosphere, Intermediate Compound 104-a (12 g, 22 mmol), 4-amino biphenyl (7.4 g, 44 mmol), pd₂dba₃ (0.9 g, 1 mmol), tris-tert-butyl phosphine (0.9 mL, 2 mmol), and sodium tert-butoxide (5.8 g, 60 mmol) were added to a 1 L flask and dissolved in 250 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 104-b (white solid, 11.6 g, 73%). The compound thus obtained was confirmed as Intermediate Compound 104-b through ESI-LCMS.

ESI-LCMS: [M]⁺: C₅₀H₄₆N₃Cl. 723.3457.

### Synthesis of Intermediate Compound 104-c

Under an argon atmosphere, Intermediate Compound 104-b (11 g, 15 mmol), 4-bromo-1,2-bis(4-(tert-butyl)phenyl)-1H-pyrrole (6.1 g, 15 mmol), pd₂dba₃ (0.69 g, 0.75 mmol), tris-tert-butyl phosphine (0.7 mL, 1.5 mmol), and sodium tert-butoxide (4.1 g, 45 mmol) were added to a 1 L flask and dissolved in 150 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 104-c (white solid, 9.8 g, 62%). The compound thus obtained was confirmed as Intermediate Compound 104-c through ESI-LCMS.

ESI-LCMS: [M]⁺: C₇₄H₇₃N₄Cl. 1052.5554.

### Synthesis of Intermediate Compound 104-d

Under an argon atmosphere, Intermediate Compound 104-c (10 g, 9.5 mmol), 4-(4-(tert-butyl)phenyl)-2-iodo-1H-pyrrole (3.1 g, 15 mmol), pd₂dba₃ (0.69 g, 0.5 mmol), tris-tert-butyl phosphine (0.7 mL, 1 mmol), and sodium tert-butoxide (2.8 g, 28 mmol) were added to a 1 L flask and dissolved in 150 mL of toluene, and the resultant reaction solution was stirred at about 100 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Intermediate Compound 104-d (white solid, 8.5 g, 74%). The compound thus obtained was confirmed as Intermediate Compound 104-d through ESI-LCMS.

ESI-LCMS: [M]⁺: C₈₈H₈₈N₅. 1215.7127.

### Synthesis of Compound 104

Under an argon atmosphere, to a 1 L flask, Intermediate Compound 104-d (8.5 g, 7 mmol) was added to a 1 L flask and dissolved in 50 mL of t-butyl benzene, and the resultant reaction solution was cooled to about −20 degrees. While maintaining the temperature, t-BuLi (5 equiv.) was slowly added dropwisely thereto, and the temperature was slowly raised to room temperature and then raised to about 80 degrees, and refluxing and stirring were performed for about 6 hours. The temperature was reduced again to room temperature, and BBr₃ (1.5 equiv.) was added thereto, followed by refluxing and stirring at about 80 degrees for about 12 hours. After cooling, water (1 L) and ethyl acetate (300 mL) were added thereto, extraction was performed, and the resultant organic layers were collected, dried with MgSO₄ and filtered. The solvent of the filtrate solution was removed under a reduced pressure, and the solid thus obtained was separated by column chromatography using silica gel and using CH₂Cl₂ and hexane as developing solvents to obtain Compound 104 (yellow solid, 1 g, 12%). The compound thus obtained was confirmed as Compound 104 through ¹H-NMR and ESI-LCMS.

¹H-NMR (400 MHz, CDCl₃): d=8.55 (d, 6H), 7.94 (d, 6H), 7.75 (d, 2H), 7.58 (m, 18H), 7.20 (m, 8H), 6.33 (s, 2H).

ESI-LCMS: [M]⁺: C₈₈H₈₆N₅B. 1223.6917.

### Example 2. Manufacture of Light Emitting Diode and Evaluation of Polycyclic Compound

A light emitting diode of an embodiment, including a polycyclic compound of an embodiment in an emission layer was manufactured by a method below.

Light emitting diodes of the Examples were manufactured using Compound 5, Compound 16, Compound 22, Compound 45, Compound 65, Compound 80 and Compound 104 above, respectively, as dopant materials of an emission layer.

Light emitting diodes of Comparative Examples were manufactured using Comparative Compound C1, Comparative Compound C2, Comparative Compound C3, and Comparative Compound C4, respectively, as dopant materials of an emission layer.

The compounds used in an emission layer in Example 1 to Example 8, and Comparative Example 1 to Comparative Example 4 are as follows.

### Example Compounds Used for Manufacturing Diodes

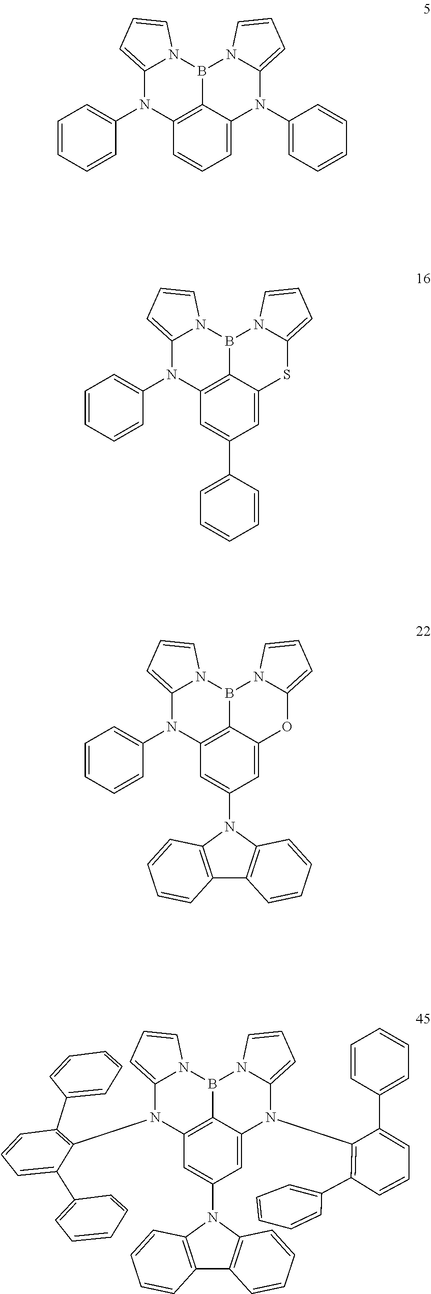 [SMILES: c1ccc(N2c3cccc4c3B(n3cccc32)n2cccc2N4c2ccccc2)cc1 ; c1ccc(-c2cc3c4c(c2)N(c2ccccc2)c2cccn2B4n2cccc2S3)cc1 ; c1ccc(N2c3cc(-n4c5ccccc5c5ccccc54)cc4c3B(n3cccc3O4)n3cccc32)cc1 ; c1ccc(-c2cccc(-c3ccccc3)c2N2c3cc(-n4c5ccccc5c5ccccc54)cc4c3B(n3cccc32)n2cccc2N4c2c(-c3ccccc3)cccc2-c2ccccc2)cc1]

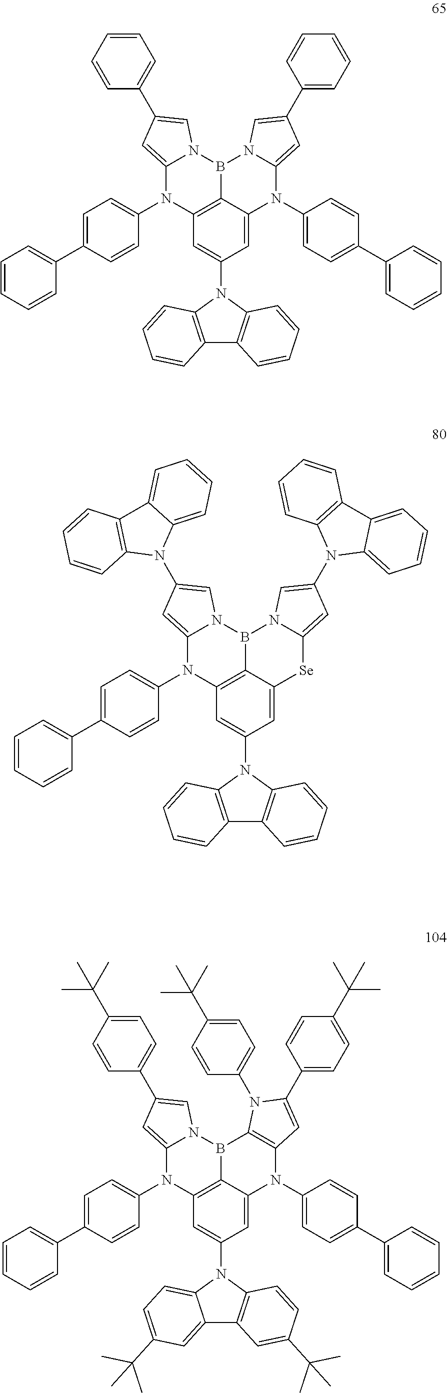 [SMILES: c1ccc(-c2ccc(N3c4cc(-n5c6ccccc6c6ccccc65)cc5c4B(n4cc(-c6ccccc6)cc43)n3cc(-c4ccccc4)cc3N5c3ccc(-c4ccccc4)cc3)cc2)cc1 ; c1ccc(-c2ccc(N3c4cc(-n5c6ccccc6c6ccccc65)cc5c4B(n4cc(-n6c7ccccc7c7ccccc76)cc4[Se]5)n4cc(-n5c6ccccc6c6ccccc65)cc43)cc2)cc1 ; CC(C)(C)c1ccc(-c2cc3n(c2)B2c4c(cc(-n5c6ccc(C(C)(C)C)cc6c6cc(C(C)(C)C)ccc65)cc4N3c3ccc(-c4ccccc4)cc3)N(c3ccc(-c4ccccc4)cc3)c3cc(-c4ccc(C(C)(C)C)cc4)n(-c4ccc(C(C)(C)C)cc4)c32)cc1]

### Comparative Compounds Used for Manufacturing Diodes

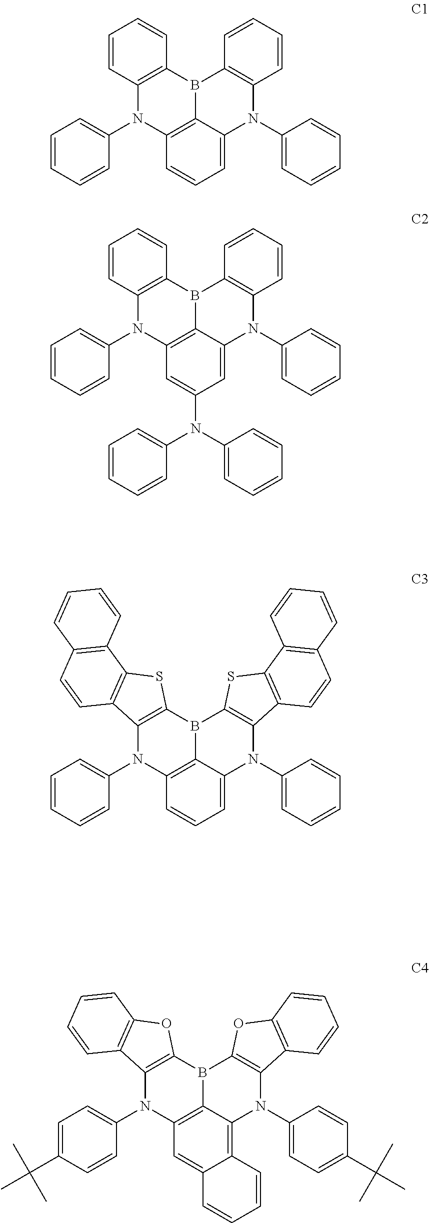 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; c1ccc(N2c3cccc4c3B(c3sc5c(ccc6ccccc65)c32)c2sc3c(ccc5ccccc53)c2N4c2ccccc2)cc1 ; CC(C)(C)c1ccc(N2c3cc4ccccc4c4c3B(c3oc5ccccc5c32)c2oc3ccccc3c2N4c2ccc(C(C)(C)C)cc2)cc1]

### Manufacture of Light Emitting Diode

For the formation of a first electrode, an ITO glass substrate of 15 Ω/cm² (1200 Å) of Corning Co. was cut into a size of 50 mm×50 mm×0.7 mm, washed by ultrasonic waves using isopropyl alcohol and pure water for about 5 minutes, respectively, and cleaned by exposing to ultraviolet rays for about 30 minutes and exposing to ozone, and then this glass substrate was installed in a vacuum deposition apparatus.

On the glass substrate, NPD was vacuum deposited to a thickness of about 300 Å to form a hole injection layer, and on the hole injection layer, Compound H-1-19 was vacuum deposited to a thickness of about 200 Å to form a hole transport layer.

On the hole transport layer thus formed, a hole transport compound, CzSi was vacuum deposited to a thickness of about 100 Å to form an emission auxiliary layer.

On the emission auxiliary layer thus formed, the Example Compound or Comparative Compound used as a dopant, and Compound E17 used as a host were co-deposited to a weight ratio of dopant:host of 1:99 to form an emission layer with a thickness of about 200 Å.

In another embodiment, on the emission auxiliary layer, the Example Compound or Comparative Compound and Compound M-b-10 used as a dopant, and Compound E-2-12 and Compound E-2-22, used as hosts were co-deposited to a weight ratio of dopant:host of 1:99 to form an emission layer with a thickness of about 200 Å.

Then, on the emission layer, TSPO1 was vacuum deposited to a thickness of about 200 Å to form an electron transport layer, and TPBi was deposited on the electron transport layer to a thickness of about 300 Å to form a buffer layer.

On the buffer layer thus formed, alkali metal halide, LiF was deposited to a thickness of about 10 Å to form an electron injection layer, and aluminum (Al) was vacuum deposited on the electron injection layer to a thickness of about 3000 Å to form a LiF/Al second electrode.

On the LiF/Al electrode, Compound P4 was vacuum deposited to a thickness of about 700 Å to form a capping layer and to manufacture a light emitting diode.

The structures of the compounds used for the manufacture of the light emitting diodes are as follows.

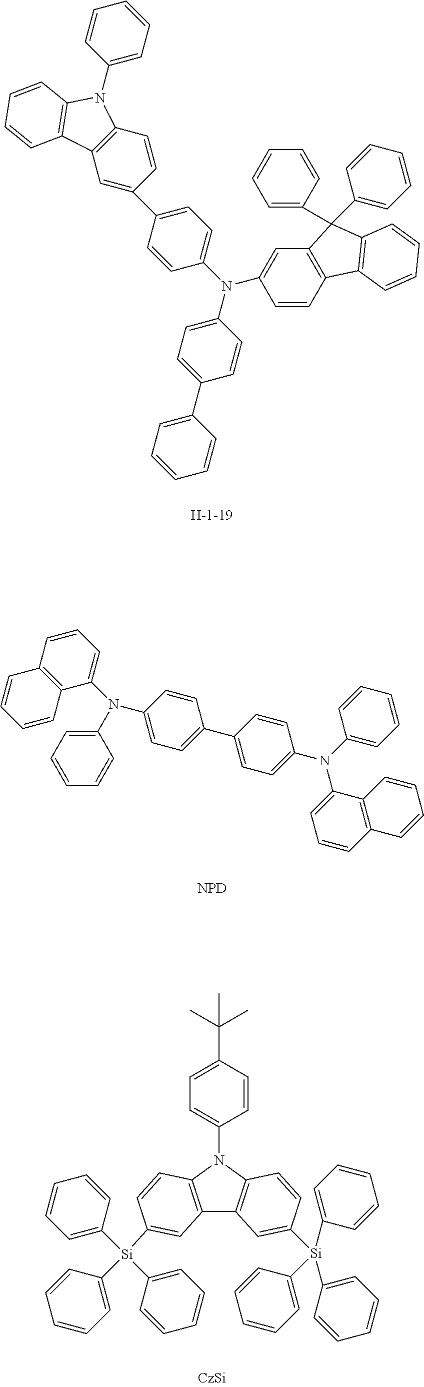 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(N(c2ccc(-c3ccc(N(c4ccccc4)c4cccc5ccccc45)cc3)cc2)c2cccc3ccccc23)cc1 ; "NPD" ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

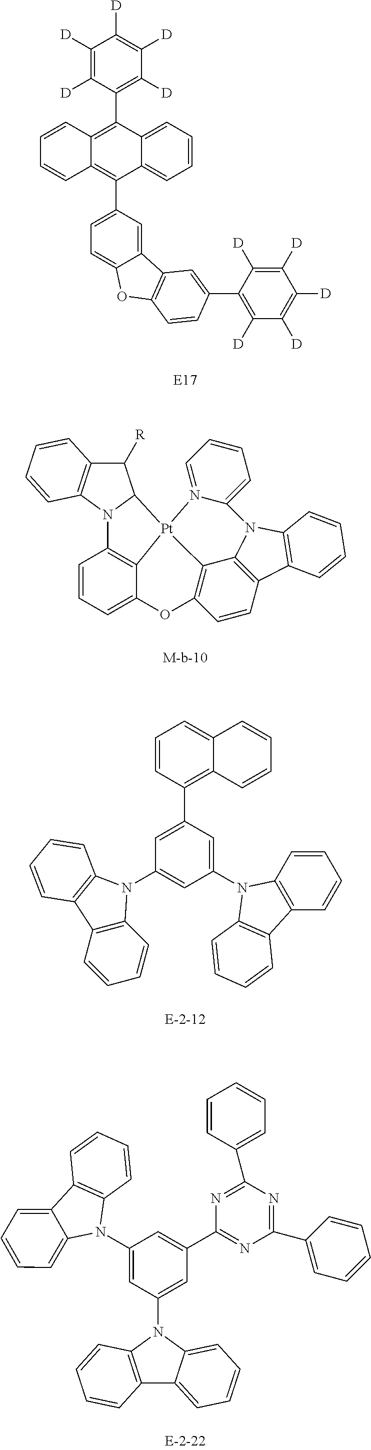

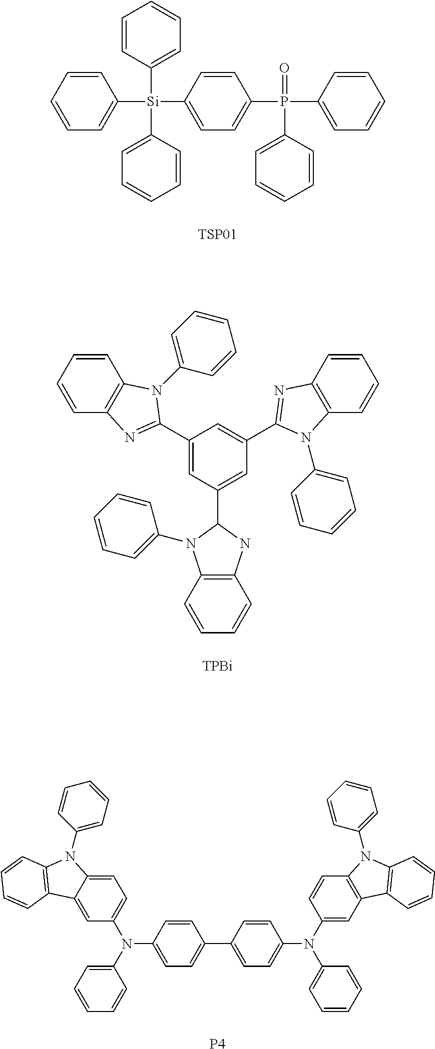

### Evaluation of Properties of Light Emitting Diode

In Table 1 and Table 2, the evaluation results of the light emitting diodes of Example 1 to Example 7, and Comparative Example 1 to Comparative Example 4 are shown.

In Table 1 and Table 2, the dopant compound, driving voltage, emission efficiency, emission wavelength, and life ratio of the light emitting diodes thus manufactured are shown.

In Table 1 and Table 2, the driving voltage and the emission efficiency were measured under a current density of about 10 mA/cm². In Table 1 and Table 2, the life ratios show relative ratios based on the deterioration time of luminance from an initial value to about 95% when continuously driving the light emitting diode of Comparative Example 1 under a current density of about 10 mA/cm².

In Table 1, Compound E17 below was used as a host material.

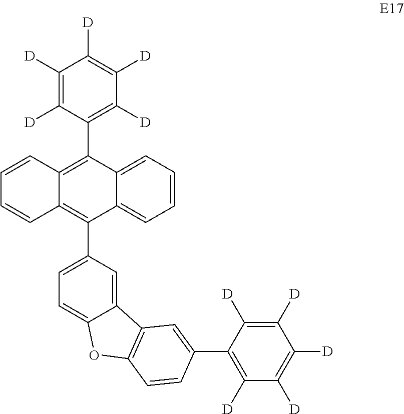 [SMILES: [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H]]

In Table 2, Compounds E-2-12 and E-2-22 below were mixed to a ratio of 1:1 and used as a host material.

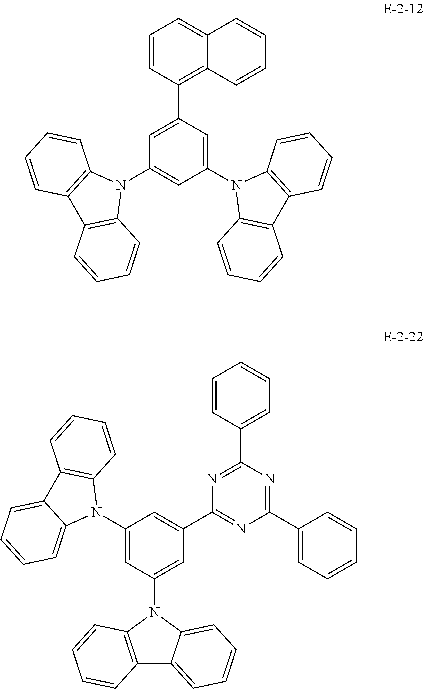 [SMILES: c1ccc2c(-c3cc(-n4c5ccccc5c5ccccc54)cc(-n4c5ccccc5c5ccccc54)c3)cccc2c1 ; c1ccc(-c2nc(-c3ccccc3)nc(-c3cc(-n4c5ccccc5c5ccccc54)cc(-n4c5ccccc5c5ccccc54)c3)n2)cc1]

In Table 2, Compound M-b-10 below was additionally used as the dopant material in addition to the Example Compound or Comparative Compound.

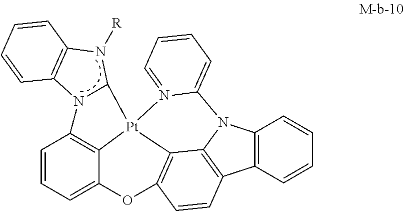

In Table 1 and Table 2, Compound H-1-19 below was used as a hole transport layer material.

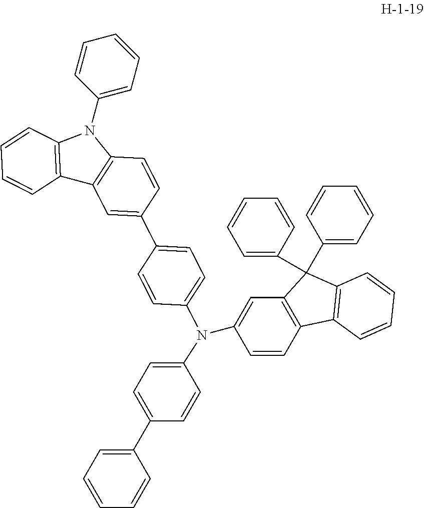 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

TABLE 1

| | | Driving | Emission | Emission | Life |
|---|---|---|---|---|---|
| | Dopant | voltage | efficiency | wavelength | ratio |
| Division | compound | (V) | (cd/A) | (nm) | (T₉₅) |
| Example 1 | Compound 5 | 3.6 | 5.1 | 455 | 6.8 |
| Example 2 | Compound 16 | 3.5 | 7.3 | 460 | 7.5 |
| Example 3 | Compound 22 | 3.4 | 5.6 | 451 | 7.4 |
| Example 4 | Compound 45 | 3.7 | 5.9 | 453 | 8.5 |
| Example 5 | Compound 65 | 3.3 | 6.3 | 458 | 9.3 |
| Example 6 | Compound 80 | 3.4 | 10.2 | 462 | 7.5 |
| Example 7 | Compound 104 | 3.4 | 8.6 | 463 | 11.7 |
| Comparative | Comparative | 4.1 | 2.8 | 448 | 1 |
| Example 1 | Compound C1 | | | | |
| Comparative | Comparative | 4.0 | 3.3 | 445 | 1.2 |
| Example 2 | Compound C2 | | | | |
| Comparative | Comparative | 3.7 | 4.2 | 452 | 3.5 |
| Example 3 | Compound C3 | | | | |
| Comparative | Comparative | 3.6 | 3.8 | 475 | 9.3 |
| Example 4 | Compound C4 | | | | |

TABLE 2

| | | Driving | Emission | Emission | Life |
|---|---|---|---|---|---|
| | Dopant | voltage | efficiency | wavelength | ratio |
| Division | compound | (V) | (cd/A) | (nm) | (T₉₅) |
| Example 1 | Compound 5 | 4.3 | 20.3 | 455 | 2.8 |
| Example 2 | Compound 16 | 4.2 | 27.3 | 460 | 3.5 |
| Example 3 | Compound 22 | 4.3 | 25.4 | 451 | 3.2 |
| Example 4 | Compound 45 | 4.3 | 25.5 | 453 | 5.8 |
| Example 5 | Compound 65 | 4.5 | 26.2 | 458 | 5.3 |
| Example 6 | Compound 80 | 4.4 | 28.5 | 462 | 3.5 |
| Example 7 | Compound 104 | 4.3 | 22.3 | 463 | 5.7 |
| Comparative | Comparative | 4.8 | 15.2 | 448 | 1 |
| Example 1 | Compound C1 | | | | |
| Comparative | Comparative | 4.9 | 18.3 | 445 | 1.1 |
| Example 2 | Compound C2 | | | | |
| Comparative | Comparative | 4.6 | 20.1 | 452 | 1.7 |
| Example 3 | Compound C3 | | | | |
| Comparative | Comparative | 4.9 | 16.3 | 475 | 2.3 |
| Example 4 | Compound C4 | | | | |

Referring to the results of Table 1 and Table 2, it can be seen that the light emitting diodes of Example 1 to Example 7 showed low driving voltages, excellent emission efficiency, improved color purity and excellent life ratios when compared to the light emitting diodes of Comparative Example 1 to Comparative Example 4. The polycyclic compound included in the light emitting diodes of Examples 1 to 7 includes a fused structure of pyrrole and ring compounds having a boron atom as a center, and has a structure in which the nitrogen atom of the pyrrole is directly connected with the boron atom. While the present application is not limited by any particular mechanism or theory, it is believed that due to the electron donating properties of the nitrogen atom, a vacant p orbital of the boron atom may be stabilized, and the multiple resonance effects and molecular stability of the polycyclic compound of embodiments of the present disclosure may be improved.

Comparative Compounds C1 to C4 disclose fused polycyclic compound structures having a boron atom as a center, but do not disclose a structure in which pyrrole is directed connected with a boron atom, and show degraded properties when compared to the light emitting diodes of Example 1 to Example 7.

Referring to Table 1, Comparative Compound C4 showed an excellent life ratio but showed low emission efficiency when compared to the light emitting diodes of Examples 1-4 and 6, and showed the range of emission wavelength of about 475 nm and degraded color purity.

The polycyclic compound of an embodiment includes pyrrole which is directly connected with a boron atom, and material stability was improved.

The light emitting diode of an embodiment includes the polycyclic compound of an embodiment in at least one functional layer, and diode properties are improved. For example, the light emitting diode of an embodiment includes the polycyclic compound of an embodiment in an emission layer, and may show a low driving voltage, improved emission efficiency and improved diode life.

The light emitting diode of embodiments of the present disclosure may show increased emission efficiency and excellent life.

Although embodiments of the present disclosure have been described, it is understood that the present disclosure should not be limited to these embodiments, and various changes and modifications can be included within the spirit and scope of the appended claims, and equivalents thereof.

1. A light emitting diode, comprising:
a first electrode;
a second electrode on the first electrode; and
at least one functional layer between the first electrode and the second electrode,
wherein the at least one functional layer comprises at least one selected from among a polycyclic compound represented by Formula 1 and a compound represented by Formula E-1: 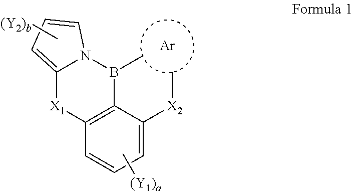
in Formula 1, Ar is a substituted or unsubstituted aromatic ring,
X₁ and X₂ are each independently CR₁R₂, NR₃, O, S, or Se,
Y₁, Y₂, and R₁ to R₃ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring, and
a and b are each independently an integer of 0 to 3, 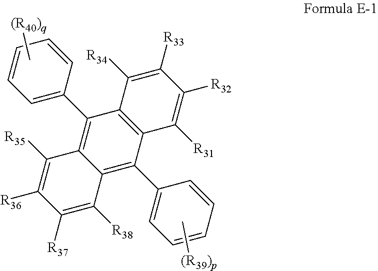
in Formula E-1, R₃₁ to R₄₀ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring, and
p and q are each independently an integer of 0 to 5.

2. The light emitting diode of claim 1, wherein the at least one functional layer comprises an emission layer, a hole transport region between the first electrode and the emission layer, and an electron transport region between the emission layer and the second electrode, and
the emission layer comprises the polycyclic compound represented by Formula 1.

3. The light emitting diode of claim 2, wherein the emission layer comprises a dopant and a host, and
the dopant comprises the polycyclic compound represented by Formula 1.

4. The light emitting diode of claim 2, wherein the emission layer emits blue light.

5. The light emitting diode of claim 2, wherein the emission layer emits thermally activated delayed fluorescence.

6. The light emitting diode of claim 1, wherein Ar is a substituted or unsubstituted aromatic heterocycle.

7. The light emitting diode of claim 1, wherein Ar is a substituted or unsubstituted pentagonal ring.

8. The light emitting diode of claim 1, wherein the polycyclic compound represented by Formula 1 is represented by Formula 2-1 or Formula 2-2: 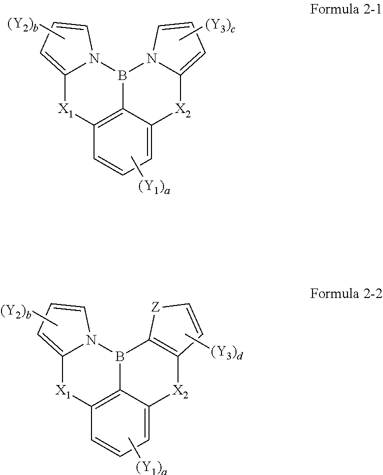
in Formula 2-1 and Formula 2-2, Z is CR₄R₅, NR₆, O, S, or Se,
Y₃, and R₄ to R₆ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring,
c is an integer of 0 to 3,
d is an integer of 0 to 2, and
X₁, X₂, Y₁, Y₂, a, and b are the same as defined with respect to Formula 1.

9. The light emitting diode of claim 8, wherein a, b, and c are each independently 0 or 1.

10. The light emitting diode of claim 8, wherein the polycyclic compound represented by Formula 2-1 is represented by Formula 3-1 or Formula 3-2: 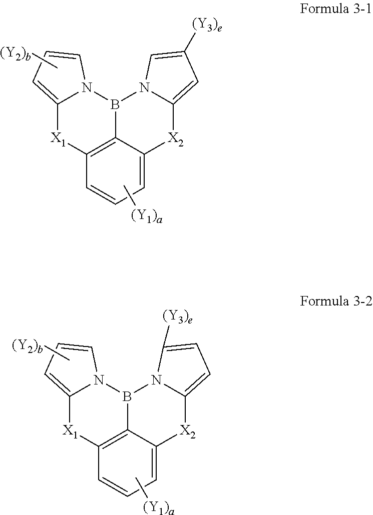
in Formula 3-1 and Formula 3-2, e is 0 or 1, and
X₁, X₂, Y₁ to Y₃, a, and b are the same as defined with respect to Formula 1 and Formula 2-1.

11. The light emitting diode of claim 8, wherein Y₁ to Y₃ are each independently a hydrogen atom, a deuterium atom, a substituted or unsubstituted amine group, a substituted or unsubstituted alkyl group of 1 to 30 carbon atoms, a substituted or unsubstituted aryl group of 6 to 50 ring-forming carbon atoms, or a substituted or unsubstituted heteroaryl group of 2 to 50 ring-forming carbon atoms.

12. The light emitting diode of claim 1, wherein the polycyclic compound represented by Formula 1 is represented by Formula 4-1 or Formula 4-2: 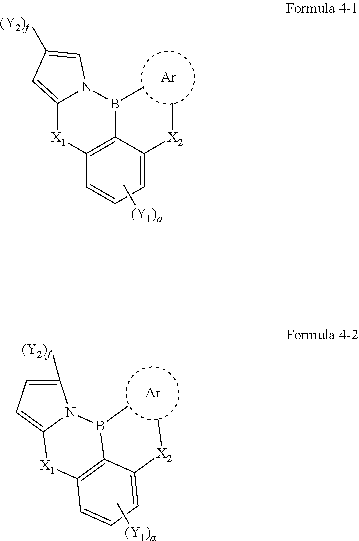
in Formula 4-1 and Formula 4-2, f is 0 or 1, and
X₁, X₂, Y₁, Y₂, and a are the same as defined with respect to Formula 1.

13. The light emitting diode of claim 1, wherein X₁ and X₂ are each independently NR₃, O, S, or Se.

14. The light emitting diode of claim 1, wherein the polycyclic compound represented by Formula 1 comprises any one selected from among compounds shown in Compound Group 1:

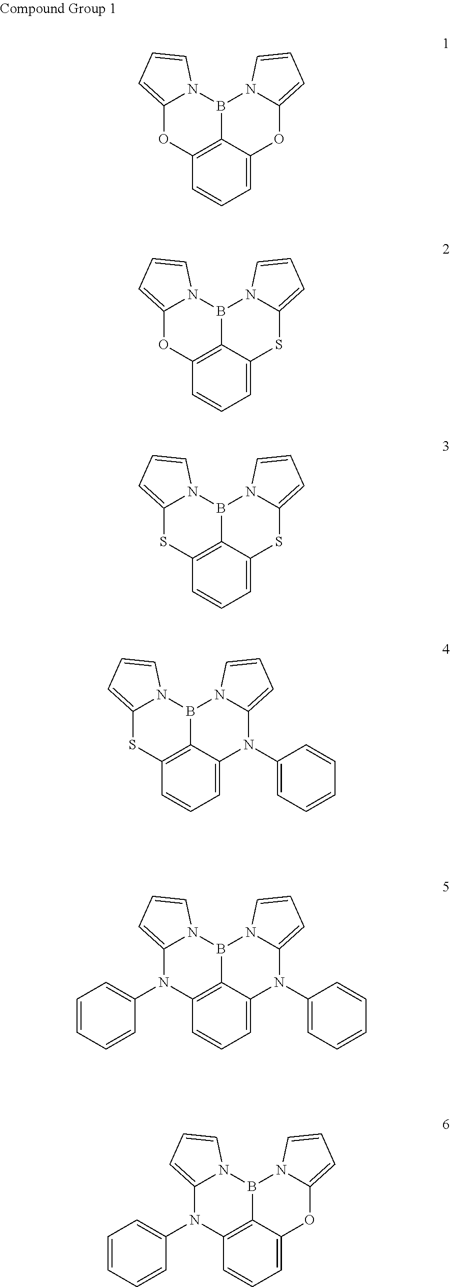 [SMILES: c1cc2c3c(c1)Oc1cccn1B3n1cccc1O2 ; c1cc2c3c(c1)Sc1cccn1B3n1cccc1O2 ; c1cc2c3c(c1)Sc1cccn1B3n1cccc1S2 ; c1ccc(N2c3cccc4c3B(n3cccc3S4)n3cccc32)cc1 ; c1ccc(N2c3cccc4c3B(n3cccc32)n2cccc2N4c2ccccc2)cc1 ; c1ccc(N2c3cccc4c3B(n3cccc3O4)n3cccc32)cc1]

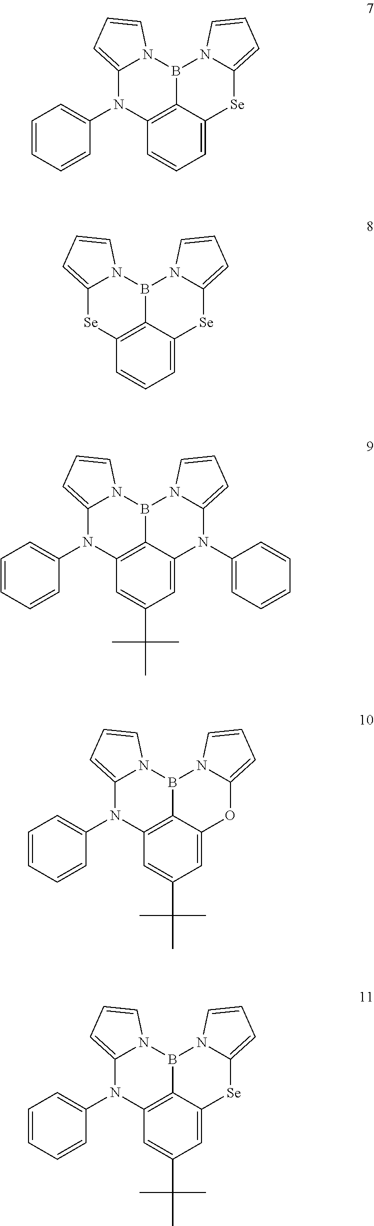 [SMILES: c1ccc(N2c3cccc4c3B(n3cccc3[Se]4)n3cccc32)cc1 ; c1cc2c3c(c1)[Se]c1cccn1B3n1cccc1[Se]2 ; CC(C)(C)c1cc2c3c(c1)N(c1ccccc1)c1cccn1B3n1cccc1N2c1ccccc1 ; CC(C)(C)c1cc2c3c(c1)N(c1ccccc1)c1cccn1B3n1cccc1O2 ; CC(C)(C)c1cc2c3c(c1)N(c1ccccc1)c1cccn1B3n1cccc1[Se]2]

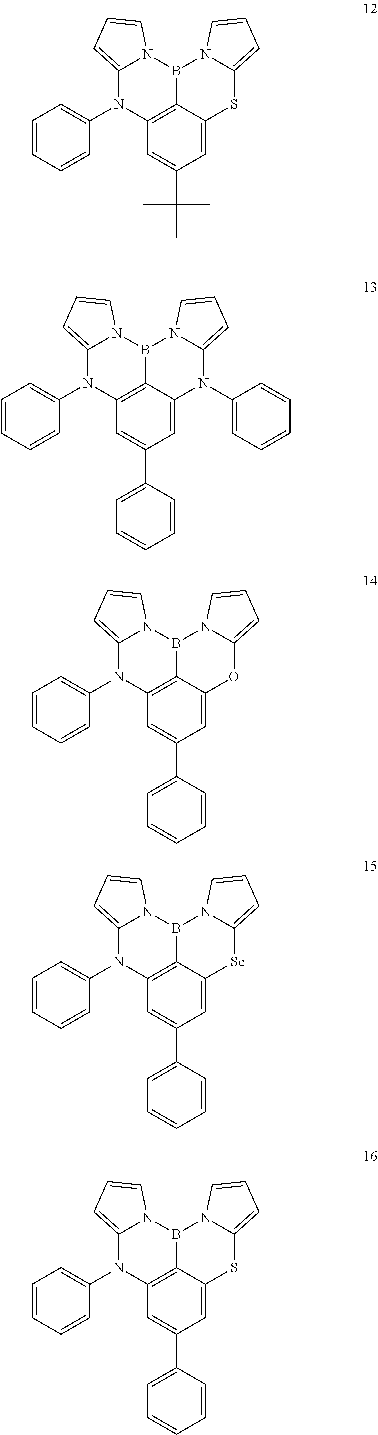

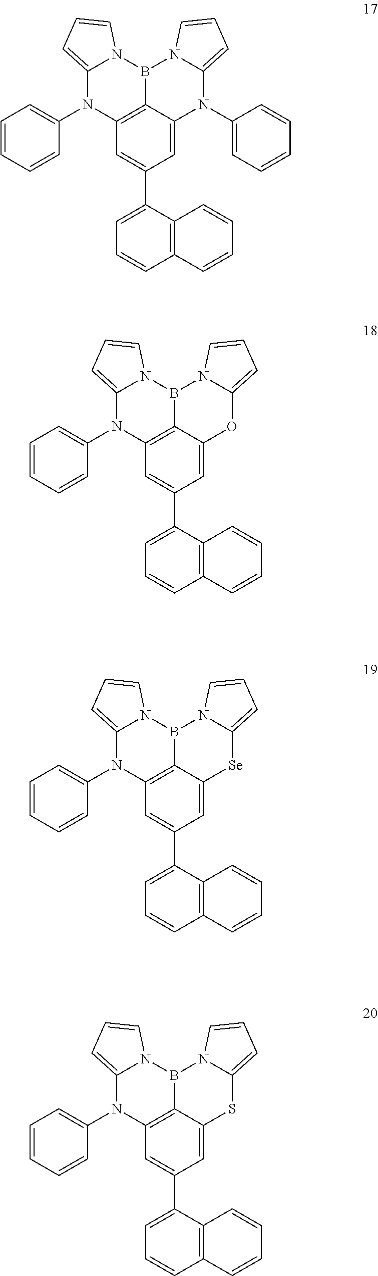 [SMILES: c1ccc(N2c3cc(-c4cccc5ccccc45)cc4c3B(n3cccc32)n2cccc2N4c2ccccc2)cc1 ; c1ccc(N2c3cc(-c4cccc5ccccc45)cc4c3B(n3cccc3O4)n3cccc32)cc1 ; c1ccc(N2c3cc(-c4cccc5ccccc45)cc4c3B(n3cccc3[Se]4)n3cccc32)cc1 ; c1ccc(N2c3cc(-c4cccc5ccccc45)cc4c3B(n3cccc3S4)n3cccc32)cc1]

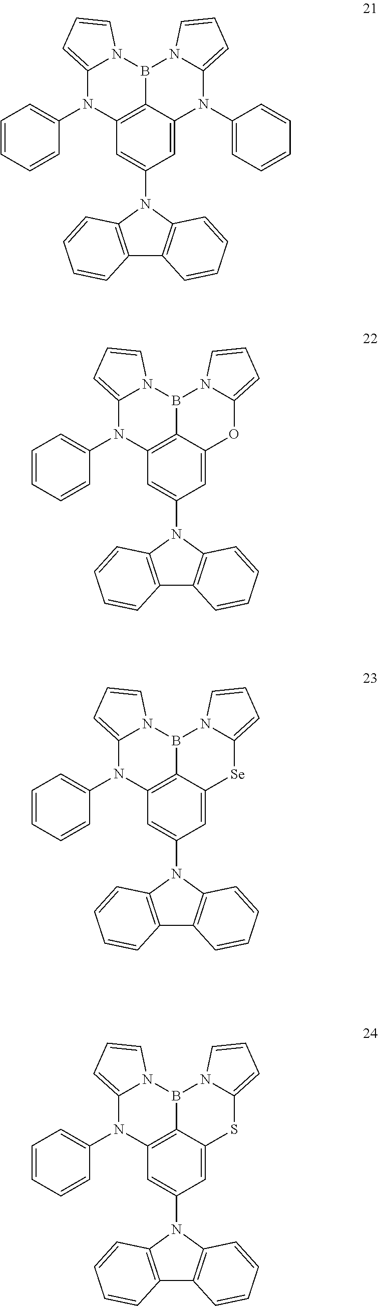 [SMILES: c1ccc(N2c3cc(-n4c5ccccc5c5ccccc54)cc4c3B(n3cccc32)n2cccc2N4c2ccccc2)cc1 ; c1ccc(N2c3cc(-n4c5ccccc5c5ccccc54)cc4c3B(n3cccc3O4)n3cccc32)cc1 ; c1ccc(N2c3cc(-n4c5ccccc5c5ccccc54)cc4c3B(n3cccc3[Se]4)n3cccc32)cc1 ; c1ccc(N2c3cc(-n4c5ccccc5c5ccccc54)cc4c3B(n3cccc3S4)n3cccc32)cc1]

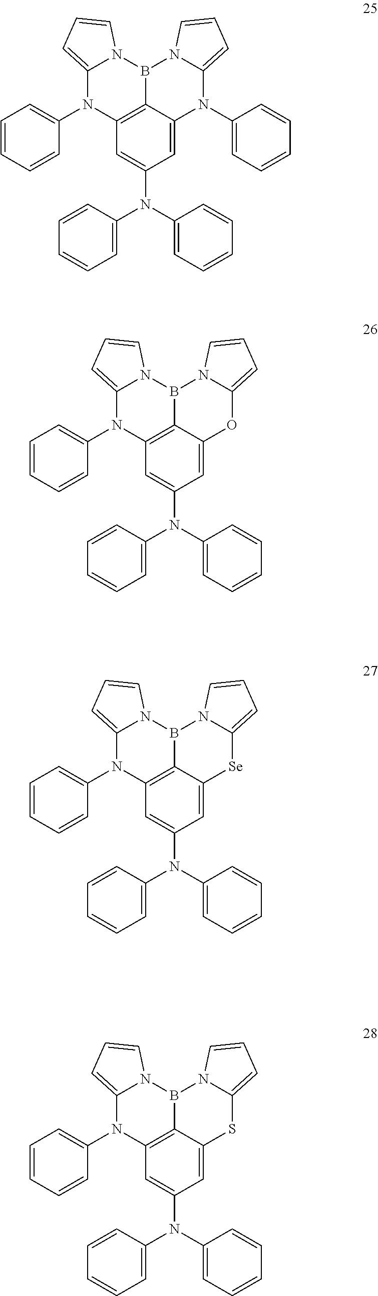 [SMILES: c1ccc(N(c2ccccc2)c2cc3c4c(c2)N(c2ccccc2)c2cccn2B4n2cccc2N3c2ccccc2)cc1 ; c1ccc(N(c2ccccc2)c2cc3c4c(c2)N(c2ccccc2)c2cccn2B4n2cccc2O3)cc1 ; c1ccc(N(c2ccccc2)c2cc3c4c(c2)N(c2ccccc2)c2cccn2B4n2cccc2[Se]3)cc1 ; c1ccc(N(c2ccccc2)c2cc3c4c(c2)N(c2ccccc2)c2cccn2B4n2cccc2S3)cc1]

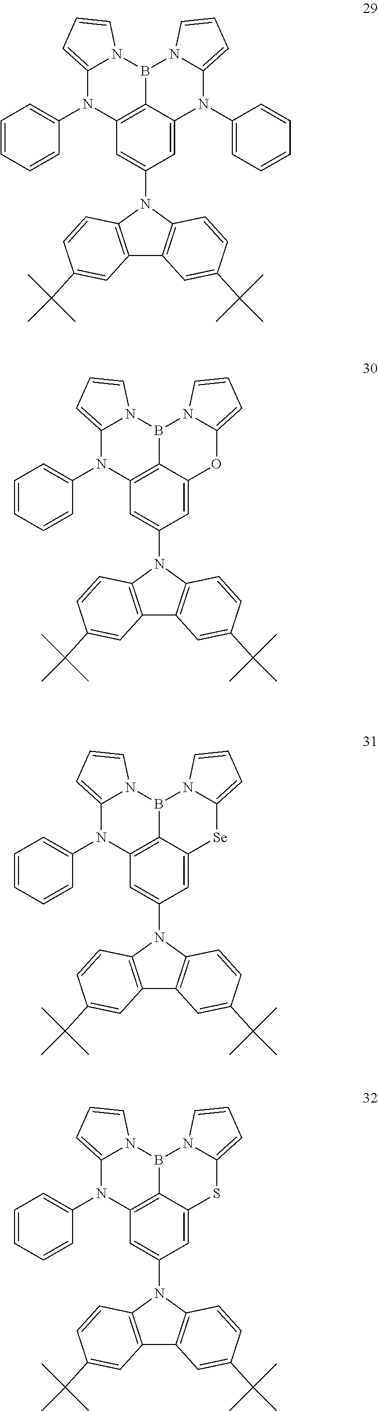 [SMILES: CC(C)(C)c1ccc2c(c1)c1cc(C(C)(C)C)ccc1n2-c1cc2c3c(c1)N(c1ccccc1)c1cccn1B3n1cccc1N2c1ccccc1 ; CC(C)(C)c1ccc2c(c1)c1cc(C(C)(C)C)ccc1n2-c1cc2c3c(c1)N(c1ccccc1)c1cccn1B3n1cccc1O2 ; CC(C)(C)c1ccc2c(c1)c1cc(C(C)(C)C)ccc1n2-c1cc2c3c(c1)N(c1ccccc1)c1cccn1B3n1cccc1[Se]2 ; CC(C)(C)c1ccc2c(c1)c1cc(C(C)(C)C)ccc1n2-c1cc2c3c(c1)N(c1ccccc1)c1cccn1B3n1cccc1S2]

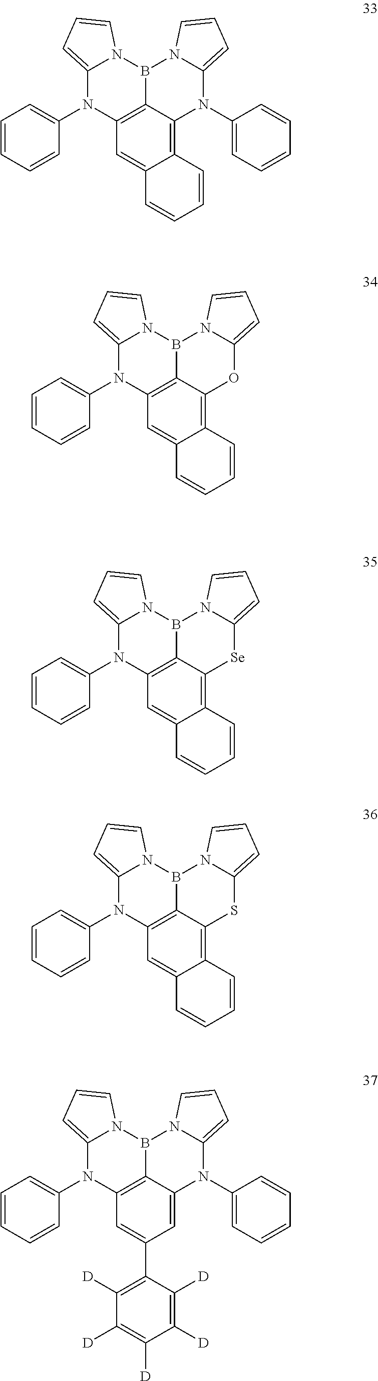 [SMILES: c1ccc(N2c3cc4ccccc4c4c3B(n3cccc32)n2cccc2N4c2ccccc2)cc1 ; c1ccc(N2c3cc4ccccc4c4c3B(n3cccc3O4)n3cccc32)cc1 ; c1ccc(N2c3cc4ccccc4c4c3B(n3cccc3[Se]4)n3cccc32)cc1 ; c1ccc(N2c3cc4ccccc4c4c3B(n3cccc3S4)n3cccc32)cc1 ; [2H]c1c([2H])c([2H])c(-c2cc3c4c(c2)N(c2ccccc2)c2cccn2B4n2cccc2N3c2ccccc2)c([2H])c1[2H]]

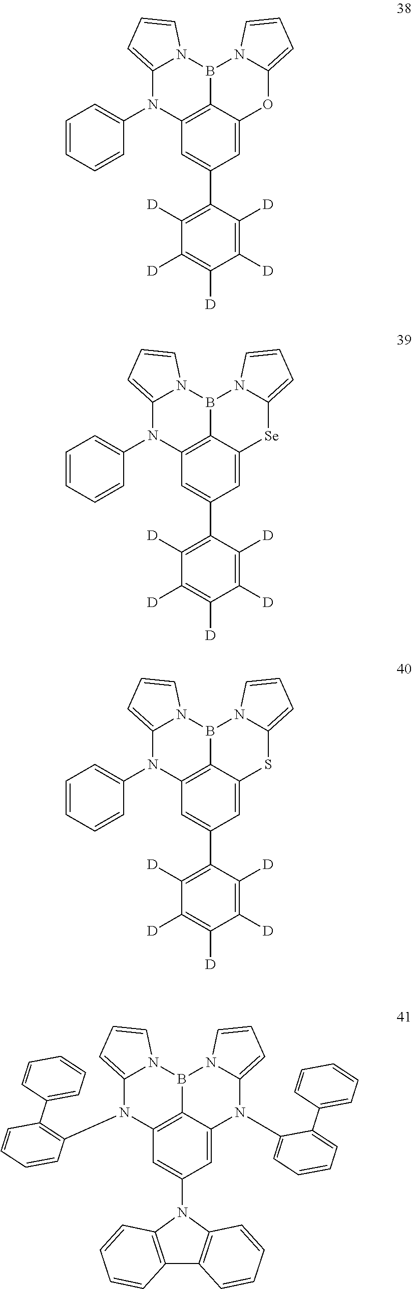 [SMILES: [2H]c1c([2H])c([2H])c(-c2cc3c4c(c2)N(c2ccccc2)c2cccn2B4n2cccc2O3)c([2H])c1[2H] ; [2H]c1c([2H])c([2H])c(-c2cc3c4c(c2)N(c2ccccc2)c2cccn2B4n2cccc2[Se]3)c([2H])c1[2H] ; [2H]c1c([2H])c([2H])c(-c2cc3c4c(c2)N(c2ccccc2)c2cccn2B4n2cccc2S3)c([2H])c1[2H] ; c1ccc(-c2ccccc2N2c3cc(-n4c5ccccc5c5ccccc54)cc4c3B(n3cccc32)n2cccc2N4c2ccccc2-c2ccccc2)cc1]

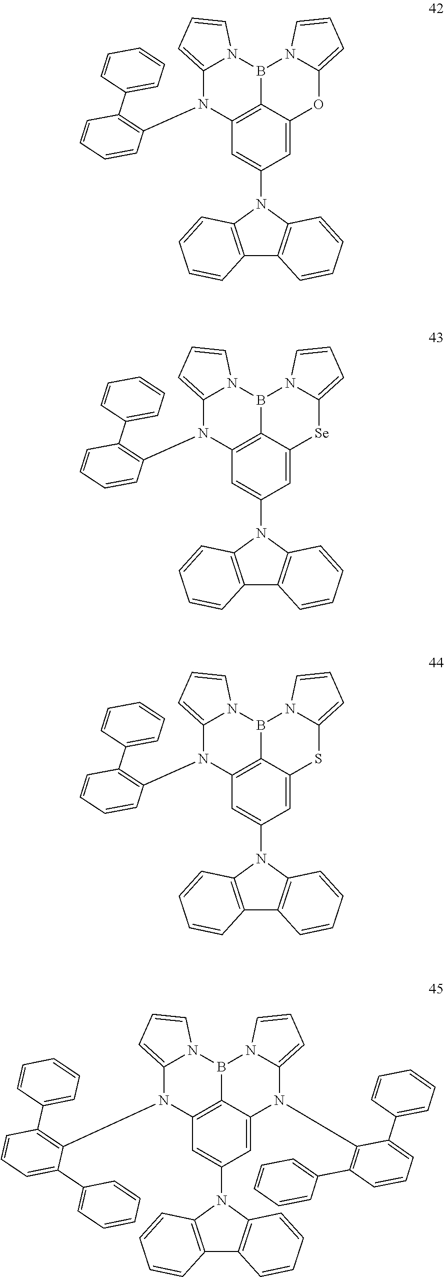 [SMILES: c1ccc(-c2ccccc2N2c3cc(-n4c5ccccc5c5ccccc54)cc4c3B(n3cccc3O4)n3cccc32)cc1 ; c1ccc(-c2ccccc2N2c3cc(-n4c5ccccc5c5ccccc54)cc4c3B(n3cccc3[Se]4)n3cccc32)cc1 ; c1ccc(-c2ccccc2N2c3cc(-n4c5ccccc5c5ccccc54)cc4c3B(n3cccc3S4)n3cccc32)cc1 ; c1ccc(-c2cccc(-c3ccccc3)c2N2c3cc(-n4c5ccccc5c5ccccc54)cc4c3B(n3cccc32)n2cccc2N4c2c(-c3ccccc3)cccc2-c2ccccc2)cc1]

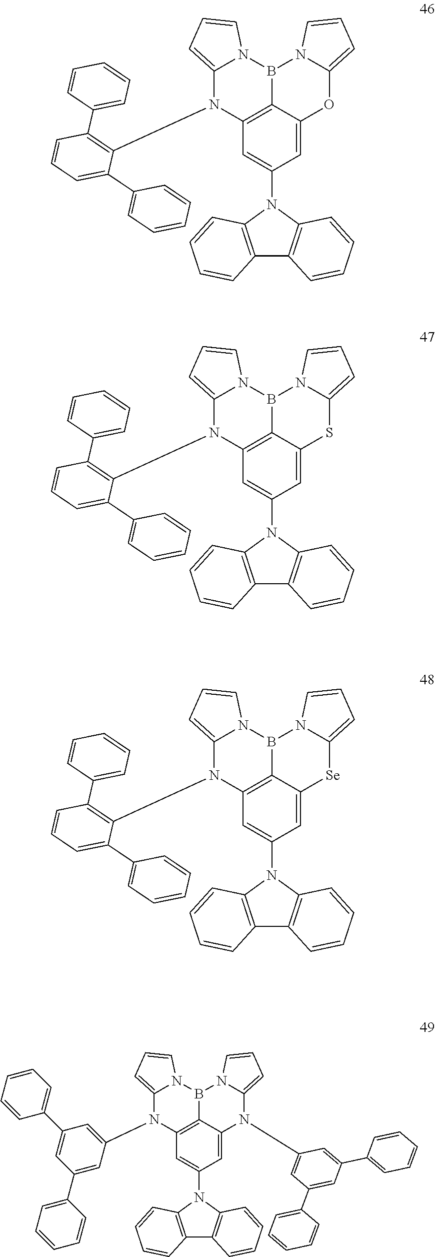 [SMILES: c1ccc(-c2cccc(-c3ccccc3)c2N2c3cc(-n4c5ccccc5c5ccccc54)cc4c3B(n3cccc3O4)n3cccc32)cc1 ; c1ccc(-c2cccc(-c3ccccc3)c2N2c3cc(-n4c5ccccc5c5ccccc54)cc4c3B(n3cccc3S4)n3cccc32)cc1 ; c1ccc(-c2cccc(-c3ccccc3)c2N2c3cc(-n4c5ccccc5c5ccccc54)cc4c3B(n3cccc3[Se]4)n3cccc32)cc1 ; c1ccc(-c2cc(-c3ccccc3)cc(N3c4cc(-n5c6ccccc6c6ccccc65)cc5c4B(n4cccc43)n3cccc3N5c3cc(-c4ccccc4)cc(-c4ccccc4)c3)c2)cc1]

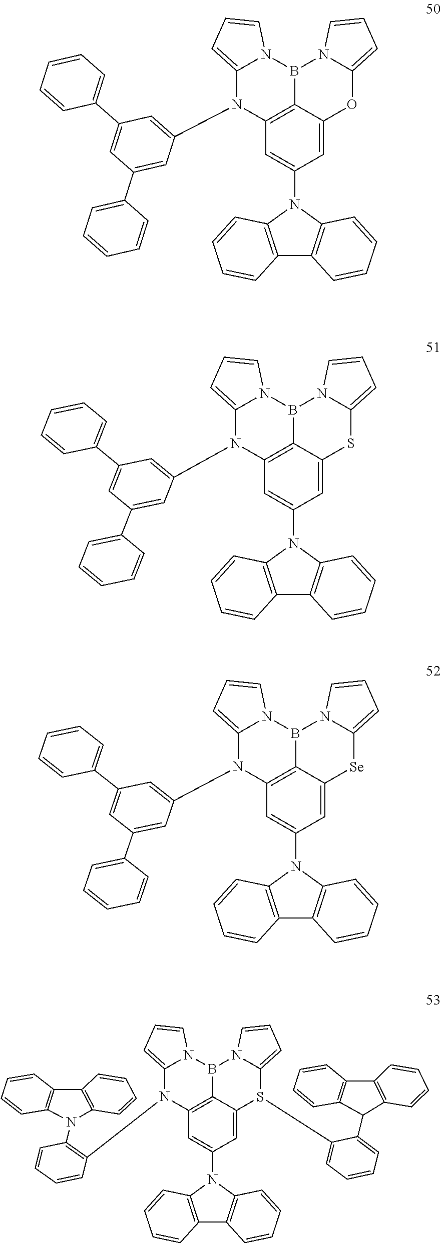

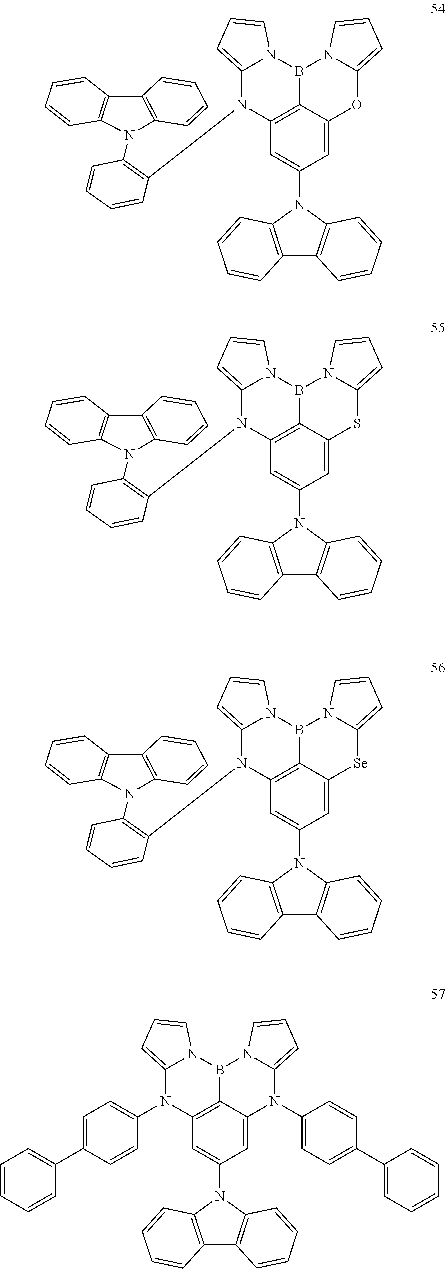 [SMILES: c1ccc(-n2c3ccccc3c3ccccc32)c(N2c3cc(-n4c5ccccc5c5ccccc54)cc4c3B(n3cccc3O4)n3cccc32)c1 ; c1ccc(-n2c3ccccc3c3ccccc32)c(N2c3cc(-n4c5ccccc5c5ccccc54)cc4c3B(n3cccc3S4)n3cccc32)c1 ; c1ccc(-n2c3ccccc3c3ccccc32)c(N2c3cc(-n4c5ccccc5c5ccccc54)cc4c3B(n3cccc3[Se]4)n3cccc32)c1 ; c1ccc(-c2ccc(N3c4cc(-n5c6ccccc6c6ccccc65)cc5c4B(n4cccc43)n3cccc3N5c3ccc(-c4ccccc4)cc3)cc2)cc1]

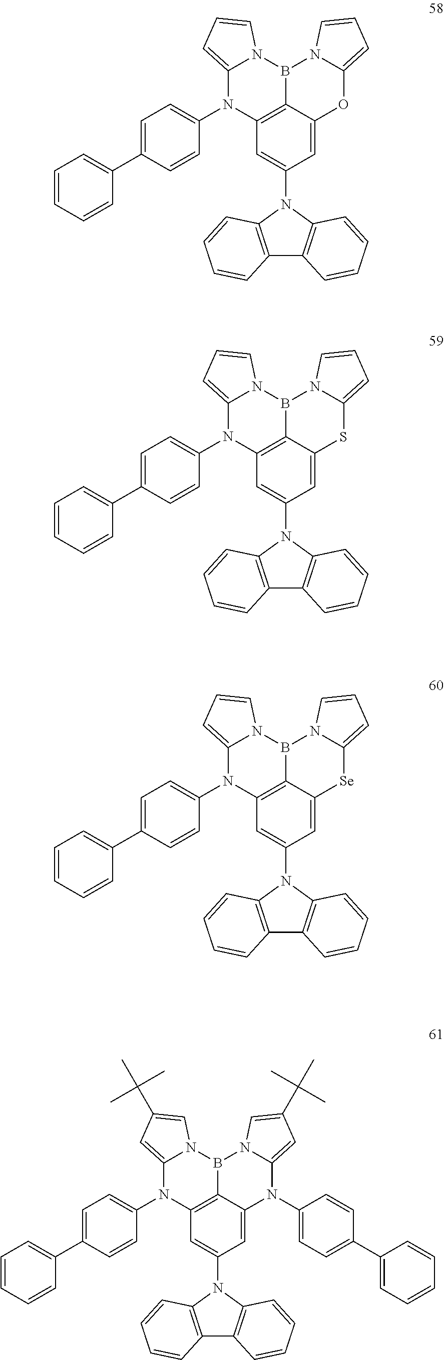 [SMILES: c1ccc(-c2ccc(N3c4cc(-n5c6ccccc6c6ccccc65)cc5c4B(n4cccc4O5)n4cccc43)cc2)cc1 ; c1ccc(-c2ccc(N3c4cc(-n5c6ccccc6c6ccccc65)cc5c4B(n4cccc4S5)n4cccc43)cc2)cc1 ; c1ccc(-c2ccc(N3c4cc(-n5c6ccccc6c6ccccc65)cc5c4B(n4cccc4[Se]5)n4cccc43)cc2)cc1 ; CC(C)(C)c1cc2n(c1)B1c3c(cc(-n4c5ccccc5c5ccccc54)cc3N(c3ccc(-c4ccccc4)cc3)c3cc(C(C)(C)C)cn31)N2c1ccc(-c2ccccc2)cc1]

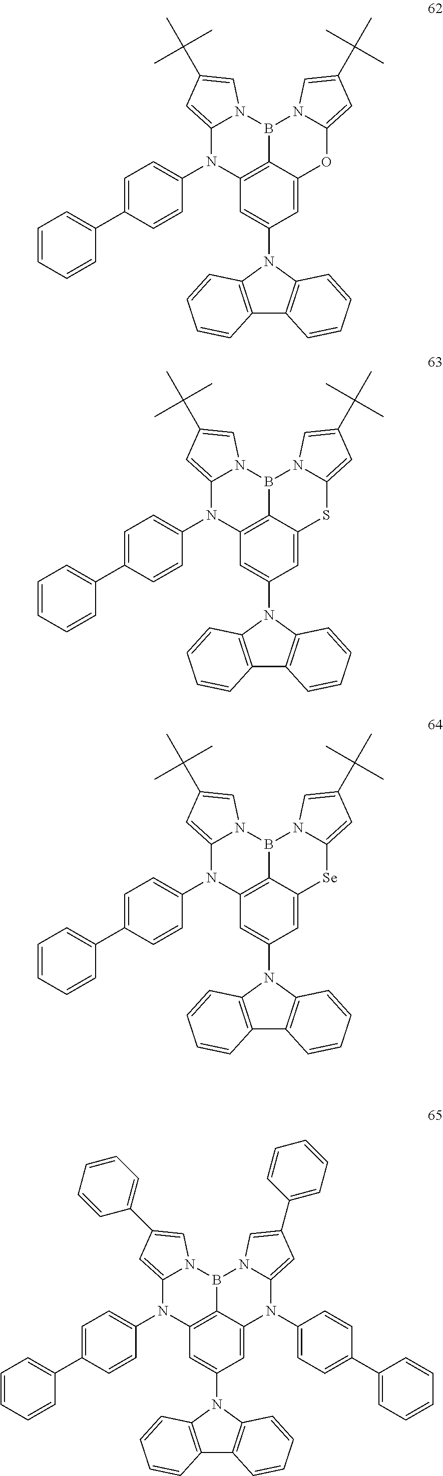 [SMILES: CC(C)(C)c1cc2n(c1)B1c3c(cc(-n4c5ccccc5c5ccccc54)cc3N(c3ccc(-c4ccccc4)cc3)c3cc(C(C)(C)C)cn31)O2 ; CC(C)(C)c1cc2n(c1)B1c3c(cc(-n4c5ccccc5c5ccccc54)cc3N(c3ccc(-c4ccccc4)cc3)c3cc(C(C)(C)C)cn31)S2 ; CC(C)(C)c1cc2n(c1)B1c3c(cc(-n4c5ccccc5c5ccccc54)cc3N(c3ccc(-c4ccccc4)cc3)c3cc(C(C)(C)C)cn31)[Se]2 ; c1ccc(-c2ccc(N3c4cc(-n5c6ccccc6c6ccccc65)cc5c4B(n4cc(-c6ccccc6)cc43)n3cc(-c4ccccc4)cc3N5c3ccc(-c4ccccc4)cc3)cc2)cc1]

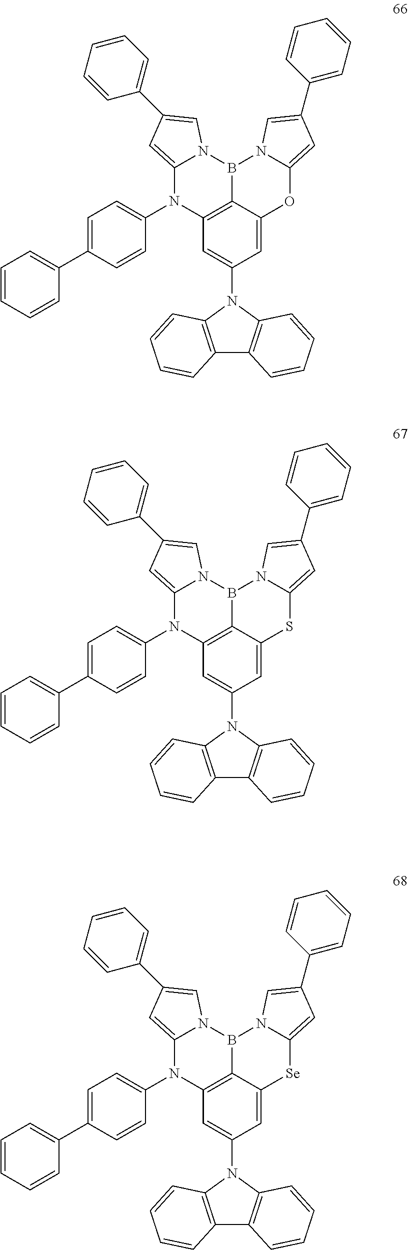 [SMILES: c1ccc(-c2ccc(N3c4cc(-n5c6ccccc6c6ccccc65)cc5c4B(n4cc(-c6ccccc6)cc4O5)n4cc(-c5ccccc5)cc43)cc2)cc1 ; c1ccc(-c2ccc(N3c4cc(-n5c6ccccc6c6ccccc65)cc5c4B(n4cc(-c6ccccc6)cc4S5)n4cc(-c5ccccc5)cc43)cc2)cc1 ; c1ccc(-c2ccc(N3c4cc(-n5c6ccccc6c6ccccc65)cc5c4B(n4cc(-c6ccccc6)cc4[Se]5)n4cc(-c5ccccc5)cc43)cc2)cc1]

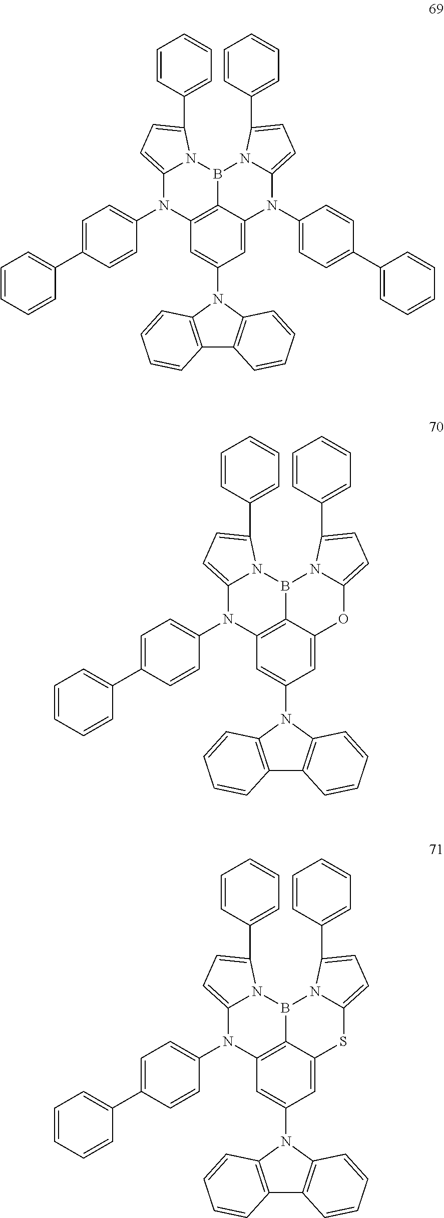 [SMILES: c1ccc(-c2ccc(N3c4cc(-n5c6ccccc6c6ccccc65)cc5c4B(n4c(-c6ccccc6)ccc43)n3c(-c4ccccc4)ccc3N5c3ccc(-c4ccccc4)cc3)cc2)cc1 ; c1ccc(-c2ccc(N3c4cc(-n5c6ccccc6c6ccccc65)cc5c4B(n4c(ccc4-c4ccccc4)O5)n4c(-c5ccccc5)ccc43)cc2)cc1 ; c1ccc(-c2ccc(N3c4cc(-n5c6ccccc6c6ccccc65)cc5c4B(n4c(ccc4-c4ccccc4)S5)n4c(-c5ccccc5)ccc43)cc2)cc1]

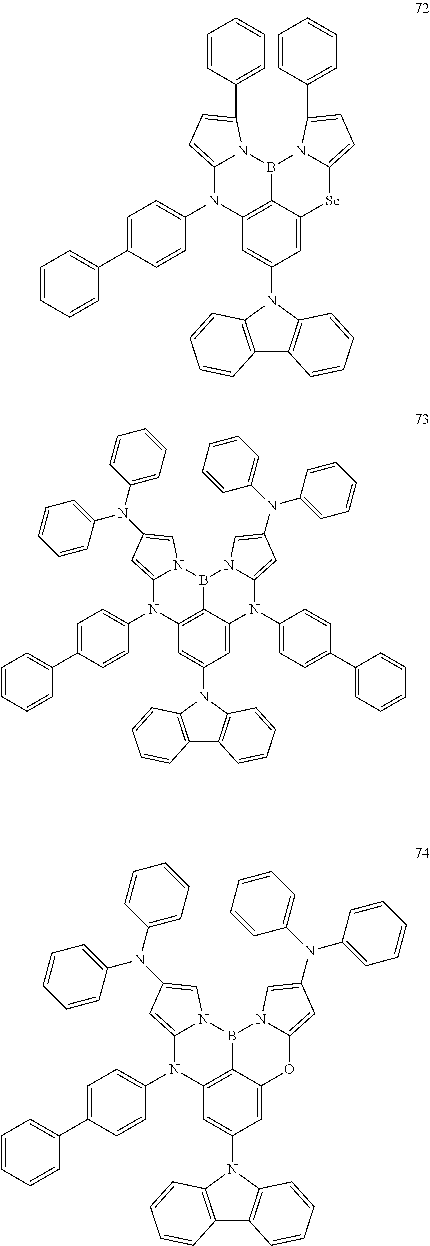 [SMILES: c1ccc(-c2ccc(N3c4cc(-n5c6ccccc6c6ccccc65)cc5c4B(n4c(ccc4-c4ccccc4)[Se]5)n4c(-c5ccccc5)ccc43)cc2)cc1 ; c1ccc(-c2ccc(N3c4cc(-n5c6ccccc6c6ccccc65)cc5c4B(n4cc(N(c6ccccc6)c6ccccc6)cc43)n3cc(N(c4ccccc4)c4ccccc4)cc3N5c3ccc(-c4ccccc4)cc3)cc2)cc1 ; c1ccc(-c2ccc(N3c4cc(-n5c6ccccc6c6ccccc65)cc5c4B(n4cc(N(c6ccccc6)c6ccccc6)cc4O5)n4cc(N(c5ccccc5)c5ccccc5)cc43)cc2)cc1]

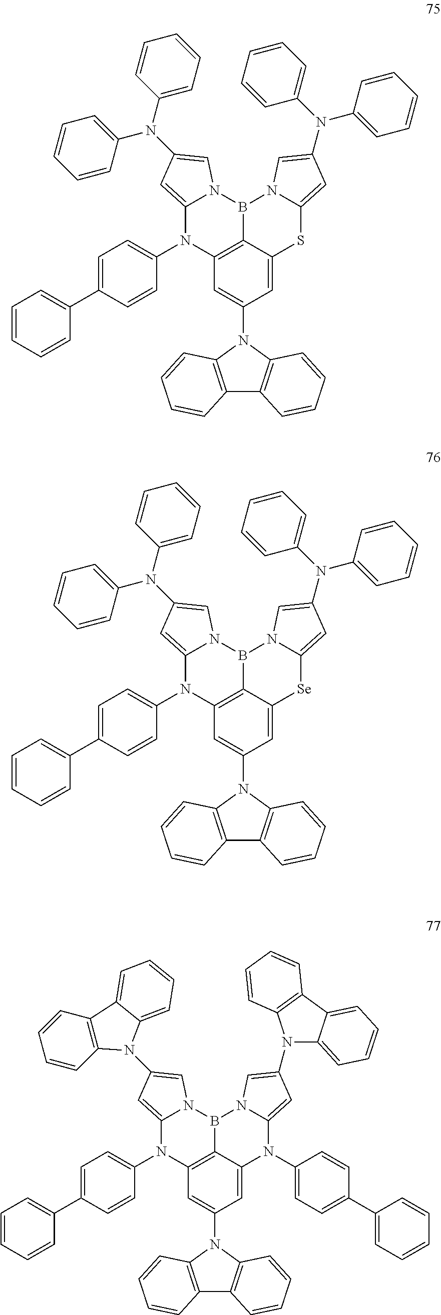 [SMILES: c1ccc(-c2ccc(N3c4cc(-n5c6ccccc6c6ccccc65)cc5c4B(n4cc(N(c6ccccc6)c6ccccc6)cc4S5)n4cc(N(c5ccccc5)c5ccccc5)cc43)cc2)cc1 ; c1ccc(-c2ccc(N3c4cc(-n5c6ccccc6c6ccccc65)cc5c4B(n4cc(N(c6ccccc6)c6ccccc6)cc4[Se]5)n4cc(N(c5ccccc5)c5ccccc5)cc43)cc2)cc1 ; c1ccc(-c2ccc(N3c4cc(-n5c6ccccc6c6ccccc65)cc5c4B(n4cc(-n6c7ccccc7c7ccccc76)cc43)n3cc(-n4c6ccccc6c6ccccc64)cc3N5c3ccc(-c4ccccc4)cc3)cc2)cc1]

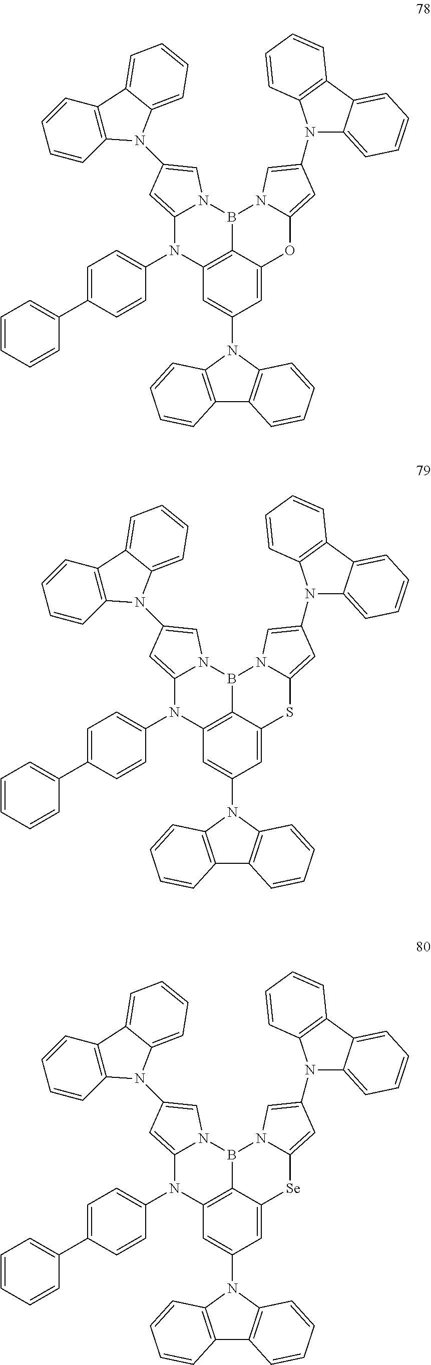 [SMILES: c1ccc(-c2ccc(N3c4cc(-n5c6ccccc6c6ccccc65)cc5c4B(n4cc(-n6c7ccccc7c7ccccc76)cc4O5)n4cc(-n5c6ccccc6c6ccccc65)cc43)cc2)cc1 ; c1ccc(-c2ccc(N3c4cc(-n5c6ccccc6c6ccccc65)cc5c4B(n4cc(-n6c7ccccc7c7ccccc76)cc4S5)n4cc(-n5c6ccccc6c6ccccc65)cc43)cc2)cc1 ; c1ccc(-c2ccc(N3c4cc(-n5c6ccccc6c6ccccc65)cc5c4B(n4cc(-n6c7ccccc7c7ccccc76)cc4[Se]5)n4cc(-n5c6ccccc6c6ccccc65)cc43)cc2)cc1]

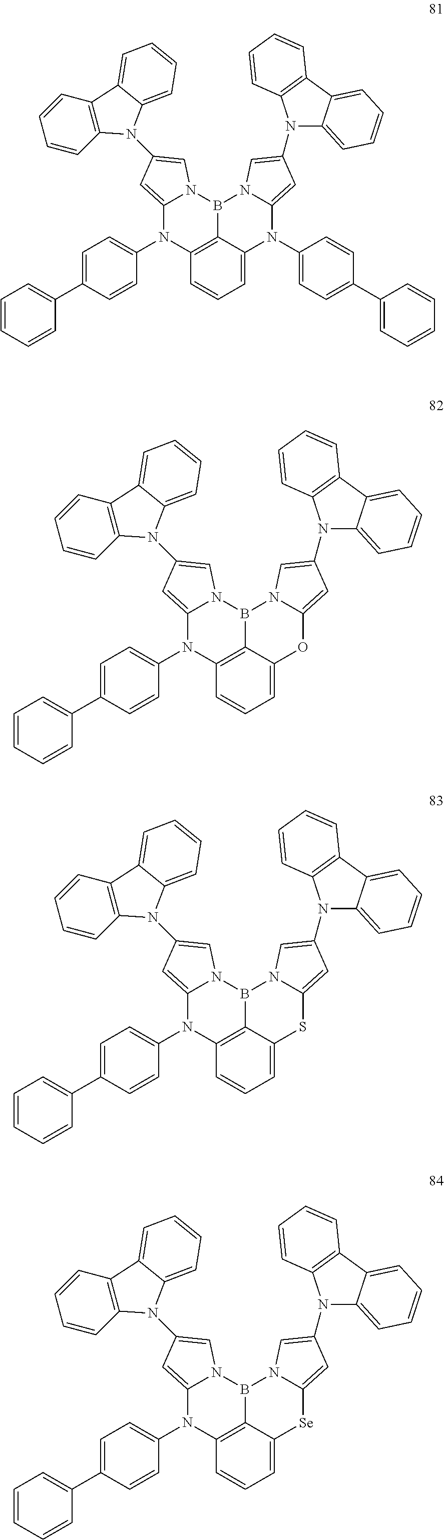 [SMILES: c1ccc(-c2ccc(N3c4cccc5c4B(n4cc(-n6c7ccccc7c7ccccc76)cc43)n3cc(-n4c6ccccc6c6ccccc64)cc3N5c3ccc(-c4ccccc4)cc3)cc2)cc1 ; c1ccc(-c2ccc(N3c4cccc5c4B(n4cc(-n6c7ccccc7c7ccccc76)cc4O5)n4cc(-n5c6ccccc6c6ccccc65)cc43)cc2)cc1 ; c1ccc(-c2ccc(N3c4cccc5c4B(n4cc(-n6c7ccccc7c7ccccc76)cc4S5)n4cc(-n5c6ccccc6c6ccccc65)cc43)cc2)cc1 ; c1ccc(-c2ccc(N3c4cccc5c4B(n4cc(-n6c7ccccc7c7ccccc76)cc4[Se]5)n4cc(-n5c6ccccc6c6ccccc65)cc43)cc2)cc1]

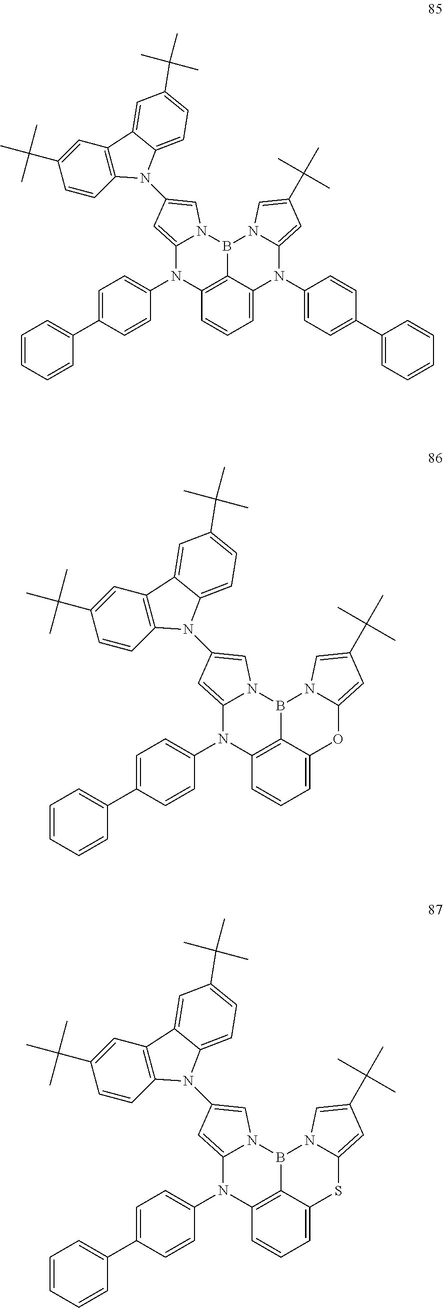

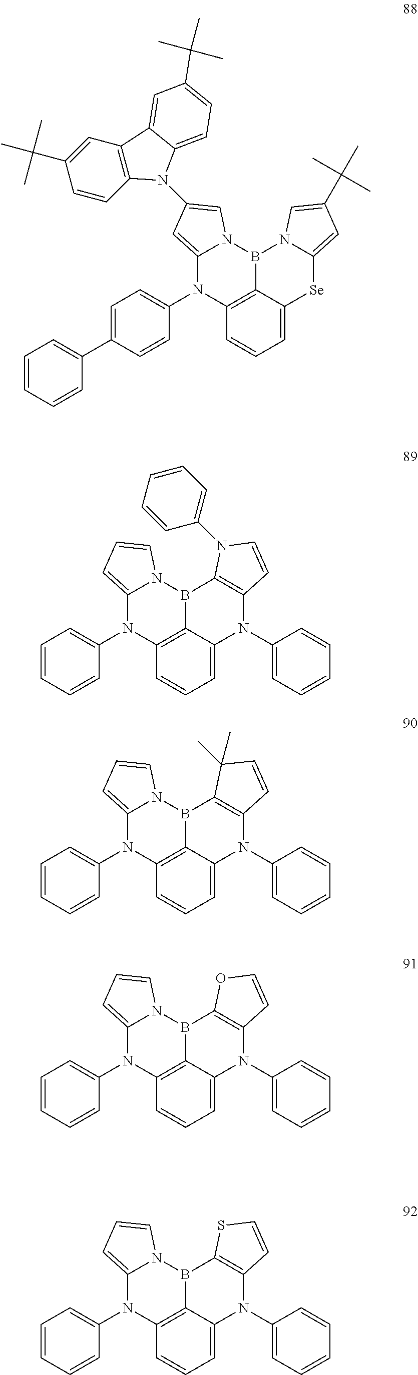 [SMILES: CC(C)(C)c1ccc2c(c1)c1cc(C(C)(C)C)ccc1n2-c1cc2n(c1)B1c3c(cccc3N2c2ccc(-c3ccccc3)cc2)[Se]c2cc(C(C)(C)C)cn21 ; c1ccc(N2c3cccc4c3B(c3c2ccn3-c2ccccc2)n2cccc2N4c2ccccc2)cc1 ; CC1(C)C=CC2=C1B1c3c(cccc3N(c3ccccc3)c3cccn31)N2c1ccccc1 ; c1ccc(N2c3ccoc3B3c4c2cccc4N(c2ccccc2)c2cccn23)cc1 ; c1ccc(N2c3ccsc3B3c4c2cccc4N(c2ccccc2)c2cccn23)cc1]

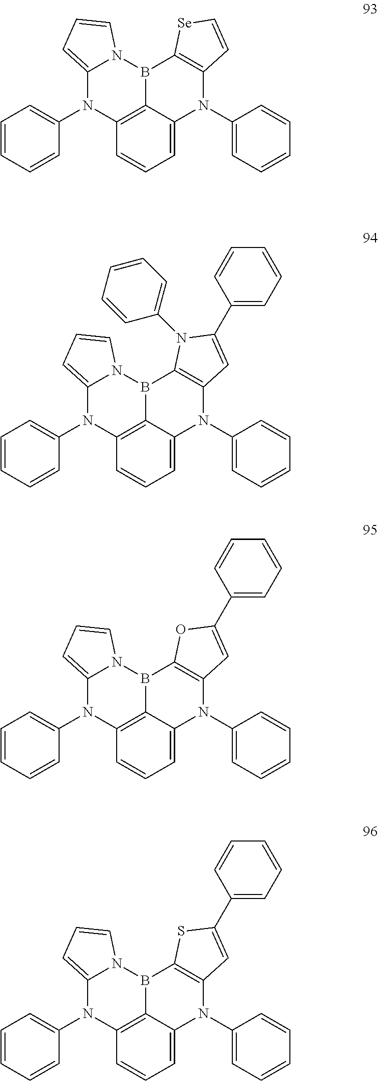 [SMILES: c1ccc(N2c3cc[se]c3B3c4c2cccc4N(c2ccccc2)c2cccn23)cc1 ; c1ccc(-c2cc3c(n2-c2ccccc2)B2c4c(cccc4N(c4ccccc4)c4cccn42)N3c2ccccc2)cc1 ; c1ccc(-c2cc3c(o2)B2c4c(cccc4N(c4ccccc4)c4cccn42)N3c2ccccc2)cc1 ; c1ccc(-c2cc3c(s2)B2c4c(cccc4N(c4ccccc4)c4cccn42)N3c2ccccc2)cc1]

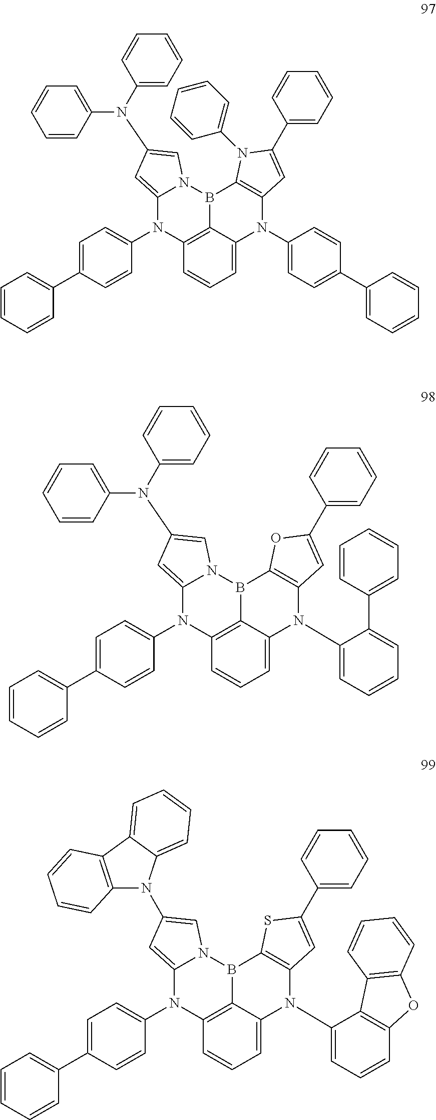 [SMILES: c1ccc(-c2ccc(N3c4cccc5c4B(c4c3cc(-c3ccccc3)n4-c3ccccc3)n3cc(N(c4ccccc4)c4ccccc4)cc3N5c3ccc(-c4ccccc4)cc3)cc2)cc1 ; c1ccc(-c2ccc(N3c4cccc5c4B(c4oc(-c6ccccc6)cc4N5c4ccccc4-c4ccccc4)n4cc(N(c5ccccc5)c5ccccc5)cc43)cc2)cc1 ; c1ccc(-c2ccc(N3c4cccc5c4B(c4sc(-c6ccccc6)cc4N5c4cccc5oc6ccccc6c45)n4cc(-n5c6ccccc6c6ccccc65)cc43)cc2)cc1]

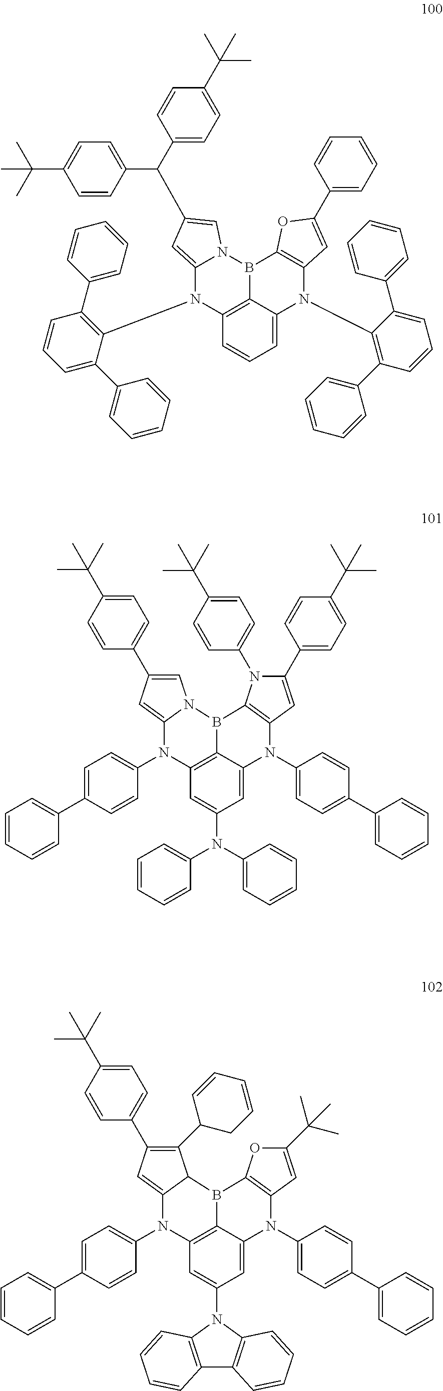 [SMILES: CC(C)(C)c1ccc(C(c2ccc(C(C)(C)C)cc2)c2cc3n(c2)B2c4oc(-c5ccccc5)cc4N(c4c(-c5ccccc5)cccc4-c4ccccc4)c4cccc(c42)N3c2c(-c3ccccc3)cccc2-c2ccccc2)cc1 ; CC(C)(C)c1ccc(-c2cc3n(c2)B2c4c(cc(N(c5ccccc5)c5ccccc5)cc4N3c3ccc(-c4ccccc4)cc3)N(c3ccc(-c4ccccc4)cc3)c3cc(-c4ccc(C(C)(C)C)cc4)n(-c4ccc(C(C)(C)C)cc4)c32)cc1 ; CC(C)(C)c1ccc(C2=C(C3C=CC=CC3)C3B4c5oc(C(C)(C)C)cc5N(c5ccc(-c6ccccc6)cc5)c5cc(-n6c7ccccc7c7ccccc76)cc(c54)N(c4ccc(-c5ccccc5)cc4)C3=C2)cc1]

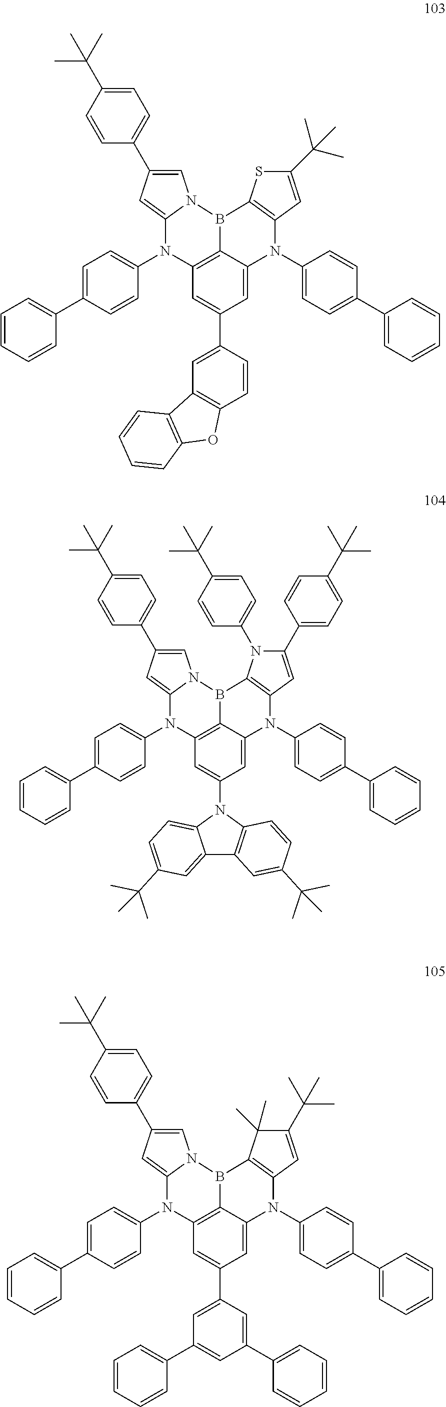 [SMILES: CC(C)(C)c1ccc(-c2cc3n(c2)B2c4sc(C(C)(C)C)cc4N(c4ccc(-c5ccccc5)cc4)c4cc(-c5ccc6oc7ccccc7c6c5)cc(c42)N3c2ccc(-c3ccccc3)cc2)cc1 ; CC(C)(C)c1ccc(-c2cc3n(c2)B2c4c(cc(-n5c6ccc(C(C)(C)C)cc6c6cc(C(C)(C)C)ccc65)cc4N3c3ccc(-c4ccccc4)cc3)N(c3ccc(-c4ccccc4)cc3)c3cc(-c4ccc(C(C)(C)C)cc4)n(-c4ccc(C(C)(C)C)cc4)c32)cc1 ; CC(C)(C)C1=CC2=C(B3c4c(cc(-c5cc(-c6ccccc6)cc(-c6ccccc6)c5)cc4N(c4ccc(-c5ccccc5)cc4)c4cc(-c5ccc(C(C)(C)C)cc5)cn43)N2c2ccc(-c3ccccc3)cc2)C1(C)C]

15. A light emitting diode, comprising:
a first electrode;
a second electrode on the first electrode; and
at least one functional layer between the first electrode and the second electrode,
wherein the at least one functional layer comprises at least one selected from among a compound represented by Formula E-2b and a polycyclic compound represented by Formula 1: 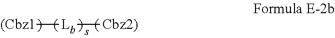
in Formula E-2b, Cbz1 and Cbz2 are each independently a substituted or unsubstituted carbazole group,
L_{b} is a direct linkage, a substituted or unsubstituted arylene group of 6 to 30 ring-forming carbon atoms, or a substituted or unsubstituted heteroarylene group of 2 to 30 ring-forming carbon atoms, and
s is an integer of 0 to 10: 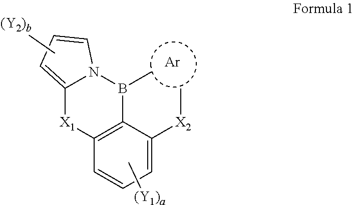
in Formula 1, Ar is a substituted or unsubstituted aromatic ring,
X₁ and X₂ are each independently CR₁R₂, NR₃, O, S, or Se,
Y₁ and Y₂ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring,
a and b are each independently an integer of 0 to 3, and
R₁ to R₃ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring.

16. The light emitting diode of claim 15, wherein the at least one functional layer further comprises a compound represented by Formula M-b: 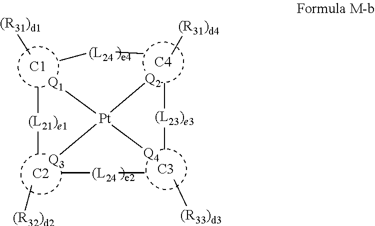
in Formula M-b, Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₂₁ to L₂₄ are each independently a direct linkage, 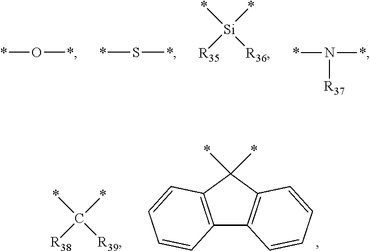
a substituted or unsubstituted divalent alkyl group of 1 to 30 carbon atoms, a substituted or unsubstituted arylene group of 6 to 50 ring-forming carbon atoms, or a substituted or unsubstituted heteroarylene group of 2 to 50 ring-forming carbon atoms,
e1 to e4 are each independently 0 or 1,
R₃₁ to R₃₉ are each independently a hydrogen atom, a deuterium atom, a halogen atom, a cyano group, a substituted or unsubstituted amine group, a substituted or unsubstituted alkyl group of 1 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring, and
d1 to d4 are each independently an integer of 0 to 4.

17. The light emitting diode of claim 15, wherein the polycyclic compound represented by Formula 1 is represented by Formula 2-1 or Formula 2-2: 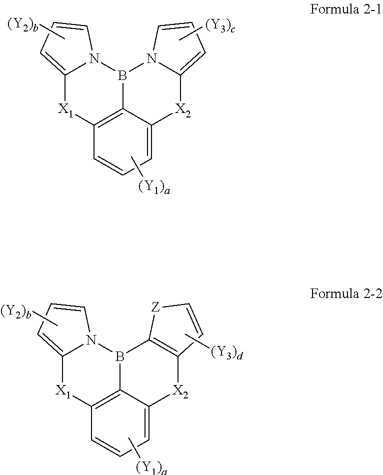
in Formula 2-1 and Formula 2-2, Z is CR₄R₅, NR₆, O, S, or Se,
Y₃, and R₄ to R₆ are each independently a hydrogen atom, a deuterium atom, a halogen atom, a cyano group, a substituted or unsubstituted thio group, a substituted or unsubstituted oxy group, a substituted or unsubstituted silyl group, a substituted or unsubstituted amine group, a substituted or unsubstituted alkyl group of 1 to 30 carbon atoms, a substituted or unsubstituted alkenyl group of 2 to 30 carbon atoms, a substituted or unsubstituted aryl group of 6 to 50 ring-forming carbon atoms, or a substituted or unsubstituted heteroaryl group of 2 to 50 ring-forming carbon atoms, or combined with an adjacent group to form a ring,
c is an integer of 0 to 3,
d is an integer of 0 to 2, and
X₁, X₂, Y₁, Y₂, a, and b are the same as defined with respect to Formula 1.

18. The light emitting diode of claim 17, wherein the polycyclic compound represented by Formula 2-1 is represented by Formula 3-1 or Formula 3-2: 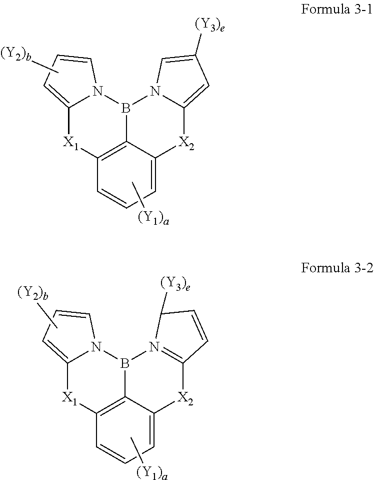
in Formula 3-1 and Formula 3-2, e is 0 or 1, and
X₁, X₂, Y₁ to Y₃, a, and b are the same as defined with respect to Formula 1 and Formula 2-1.

19. The light emitting diode of claim 15, wherein the polycyclic compound represented by Formula 1 is represented by Formula 4-1 or Formula 4-2: 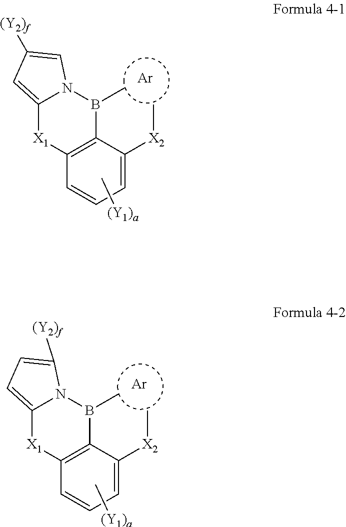
in Formula 4-1 and Formula 4-2, f is 0 or 1, and
X₁, X₂, Y₁, Y₂, and a are the same as defined with respect to Formula 1.

20. The light emitting diode of claim 15, wherein X₁ and X₂ are each independently NR₃, O, S, or Se.
